(19) United States
(12) Patent Application Publication
(10) Pub. No.: US 2024/0099122 A1
(43) Pub. Date: Mar. 21, 2024

(54) ORGANIC ELECTROLUMINESCENT DEVICE AND APPLICATION THEREOF

(71) Applicant: BEIJING SUMMER SPROUT TECHNOLOGY CO., LTD., Beijing (CN)

(72) Inventors: Chi Yuen Raymond Kwong, Beijing (CN); Wei Cai, Beijing (CN); Liang Gao, Beijing (CN); Jing Wang, Beijing (CN); Zheng Wang, Beijing (CN); Hongbo Li, Beijing (CN); Zhen Wang, Beijing (CN); Chuanjun Xia, Beijing (CN)

(73) Assignee: BEIJING SUMMER SPROUT TECHNOLOGY CO., LTD., Beijing (CN)

(21) Appl. No.: 18/237,539

(22) Filed: Aug. 24, 2023

(30) Foreign Application Priority Data
Aug. 25, 2022 (CN) 202211022169.8

(51) Int. Cl. H10K 85/30; C09K 11/06; H10K 85/60

(52) U.S. Cl. CPC H10K 85/342; C09K 11/06; H10K 85/622; H10K 85/654; H10K 85/6572; H10K 85/6574; H10K 85/6576; H10K 2101/30

(57) ABSTRACT

Provided are an organic electroluminescent device and a use thereof. The organic electroluminescent device comprises a metal complex having particular spectral characteristics (that is, satisfying requirements on D and AR), and the metal complex can better approach the commercially pursued BT.2020 luminescence. Compared with a metal complex that does not satisfy the requirements on D and AR, the metal complex is applied to the organic electroluminescent device to make the obtained organic electroluminescent device have higher device efficiency and more saturated green light emission, can better satisfy the BT.2020 luminescence requirement of the market, and can still maintain high device performance, especially device efficiency, when approaching the BT.2020 luminescence, and the metal complex basically reaches maximum efficiency of the device. The organic electroluminescent device comprising the preceding metal complex has a broad commercial application prospect and can achieve more saturated luminescence. Further provided is an electronic assembly comprising the organic electroluminescent device.

### CROSS-REFERENCE TO RELATED APPLICATION(S)

This application claims priority to Chinese Patent Application No. 202211022169.8 filed on Aug. 25, 2022, the disclosure of which is incorporated herein by reference in its entirety.

### TECHNICAL FIELD

The present disclosure relates to organic electronic devices, for example, organic electroluminescent devices. More particularly, the present disclosure relates to an organic electroluminescent device containing a metal complex having particular spectral characteristics, a display assembly comprising the organic electroluminescent device, and a use of the metal complex in an organic optoelectronic device.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which includes an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may include multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may include one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

At present, full-color displays are widely applied to our work and life, such as a display of a mobile phone, a display of a computer, and an advertising display in a shopping mall, and the displays are mainly used for displaying texts, graphics, animations, videos, and other information. To identify the quality of a full-color display, color reproduction is one of the most important characteristics in addition to flatness, brightness, a viewing angle, a white balance effect, and other characteristics. The color reproduction generally refers to a color that can be exhibited by RGB subpixels in the display. BT.2020 is a current color gamut requirement with the highest color reproduction. The higher the BT.2020 coverage of the full-color display, the higher the color reproduction of the full-color display. In 2012, the International Telecommunication Union (ITU) announced a new UHDTV color gamut standard, Broadcast Service Television 2020 (BT.2020). Although the color gamut specification of BT.2020 is higher, the three primary colors of BT.2020 are too saturated, which is difficult for general devices to achieve.

The color coordinates of the red, green, and blue primary colors are required to be (0.708, 0.292), (0.131, 0.046), and (0.170, 0.797) in BT.2020, respectively. Red light devices and blue light devices in OLED display panels commonly used at present can be basically satisfy the color gamut requirements, but the OLED display panels are mainly limited by green light devices whose performance has not satisfied the color gamut requirement. To achieve such BT.2020 coverage, the color coordinates of a green light device need to be adjusted to approach the requirement of BT.2020. Monochromatic laser light sources can be used to achieve the color gamut requirements of BT.2020 but can only be used for projection-type television displays.

Additionally, due to relatively large physical dimensions and relatively high manufacturing costs, the monochromatic laser light sources are hardly possible to be used for high-resolution small and medium active matrix displays. Another potential candidate for achieving the color gamut requirements of BT.2020 is quantum dots (QD). The QD have received extensive researches due to a relatively narrow luminescence spectrum. However, quantum dot light-emitting diodes using the QD as self-luminous components still have a stability problem and cannot be commercialized. Additionally, an LED chip prepared on a semiconductor epitaxial wafer is peeled off and transferred to a display backplane and is electrically connected (bonded) to a backplane circuit through micro LED technology, which becomes a research hotspot of new display technology. Micro LEDs and LEDs have the same characteristics of a narrow spectrum and high color saturation, and the desired emission spectrum can be obtained by selecting an appropriate semiconductor material. However, the chip of micro LEDs has reduced efficiency as the dimensions decrease. In conjunction with the immaturity of the current “mass transfer” technology, the use of the micro LEDs as display components of a mobile device such as the mobile phone has not been commercialized.

Organic light-emitting diode (OLED) displays have been widely applied to displays of various sizes, such as mobile phones, tablets, laptops, AR glasses, and VR glasses. Some studies have shown that OLEDs may have 37% lower power consumption than LED-backlit liquid crystal displays. Therefore, another potential candidate for achieving the color gamut requirements of BT.2020 is OLED technology. However, it is relatively difficult for current OLED devices to achieve ideal BT.2020 color gamut coverage. The BT.2020 coverage of OLED products of major screen manufacturers and terminal manufacturers is generally less than 80%. Therefore, how to improve the display color of OLED devices or OLED display products to reach the requirements of BT.2020 is an urgent technical problem to be solved in the industry.

### SUMMARY

The present disclosure aims to provide an organic electroluminescent device to solve at least part of the preceding problems. The organic electroluminescent device comprises a metal complex having particular spectral characteristics. The metal complex can better approach the commercially pursued BT.2020 luminescence and, when approaching the BT.2020 luminescence, can still maintain high device performance, especially device efficiency, basically reaching the maximum efficiency of the device. The organic electroluminescent device comprising the preceding metal complex has a broad commercial application prospect and can achieve more saturated luminescence.

According to an embodiment of the present disclosure, an organic electroluminescent device is disclosed, which comprises a cathode, an anode, and an organic layer disposed between the cathode and the anode; wherein
the organic layer comprises a metal complex comprising a metal M and at least one C\hat{ }N bidentate ligand Lₐ coordinated to the metal M;
the metal M is selected from a metal with a relative atomic mass greater than 40;
an area ratio of a photoluminescence spectrum of the metal complex at room temperature is AR, wherein AR≤0.331;
in a top-emitting device comprising the metal complex, when the top-emitting device reaches maximum current efficiency, the corresponding color coordinates are measured as CIE (x, y); and a distance between the CIE (x, y) and color coordinates CIE (0.170, 0.797) is calculated as D; wherein CIEy≥0.797 or D≤0.0320.

According to another embodiment of the present disclosure, a display assembly is further disclosed. The display assembly comprises the organic electroluminescent device in the preceding embodiment.

The organic electroluminescent device according to the present disclosure uses the metal complex having particular spectral characteristics (that is, satisfying the requirements on D and AR), and the metal complex can better approach the commercially pursued BT.2020 luminescence. Compared with a metal complex that does not satisfy the requirements on D and AR, the metal complex according to the present application when applied to an organic electroluminescent device allows the obtained organic electroluminescent device have higher device efficiency and more saturated green light emission and can better satisfy the requirement of the market for BT.2020 luminescence. The device can still maintain high device performance, especially device efficiency, basically reaching the maximum efficiency of the device, when approaching the BT.2020 luminescence. The organic electroluminescent device comprising the preceding metal complex has a broad commercial application prospect and can achieve more saturated luminescence.

### BRIEF DESCRIPTION OF DRAWINGS

FIG. 1 is a schematic diagram of an organic electroluminescent device disclosed herein.

FIG. 2 is a schematic diagram of another organic electroluminescent device disclosed herein.

FIG. 3 is a structural diagram of a typical top-emitting OLED device.

FIG. 4 is a structural diagram of a device for simulation.

FIG. 5 is a schematic diagram for the calculation of an area ratio of an emission spectrum.

### DETAILED DESCRIPTION

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

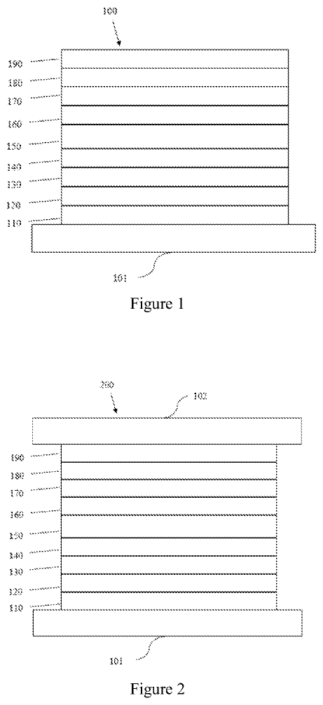

An OLED can be encapsulated by a bather layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

As used herein, the term “color coordinates” refers to the corresponding coordinates in the CIE 1931 color space.

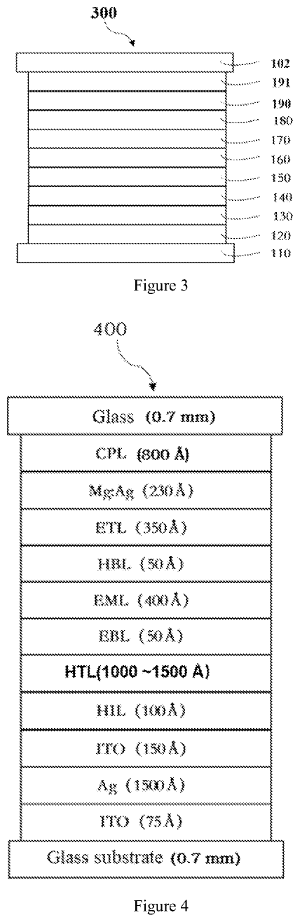

The structure of a typical top-emitting OLED device is shown in FIG. 3. An OLED device 300 includes an anode 110, a hole injection layer (HIL) 120, a hole transporting layer (HTL) 130, an electron blocking layer (EBL) 140 (also referred to as a prime layer), an emissive layer (EML) 150, a hole blocking layer (HBL) 160 (optional), an electron transporting layer (ETL) 170, an electron injection layer (EIL) 180, a cathode 190 a capping layer 191, and an encapsulation layer 102. The anode 110 is a material or a combination of materials having a high reflectivity, including, but not limited to, Ag, Al, Ti, Cr, Pt, Ni, TiN, and a combination of the above materials with ITO and/or MoOx (molybdenum oxide). Generally, the reflectivity of the anode is greater than 50%; preferably, the reflectivity of the anode is greater than 70%; more preferably, the reflectivity of the anode is greater than 80%. The cathode 190 should be a translucent or transparent conductive material, including, but not limited to, a MgAg alloy, MoOx, Yb, Ca, ITO, IZO, or a combination thereof, and the average transmittance of the cathode for light having a wavelength in a visible light region is greater than 15%; preferably, the average transmittance of the cathode for light having a wavelength in the visible light region is greater than 20%; more preferably, the average transmittance of the cathode for light having a wavelength in the visible light region is greater than 25%. The hole injection layer 120 may be a single material layer such as commonly used HATCN. The hole injection layer 120 may also be a hole transporting material doped with a certain proportion of conductive p-type doping material, where the doping proportion is generally not higher than 5% and commonly between 1% and 3%. The EBL 140 is optional. However, to better match an energy level of a host material, a device structure with the EBL is generally adopted. The thickness of the hole transporting layer is generally between 100 nm and 200 nm. Since the top-emitting device has a microcavity effect, the microcavity of the device is usually adjusted by adjusting the thickness of the hole transporting layer or the electron blocking layer. For example, to achieve the best microcavity effect of the top-emitting OLED device, that is, to achieve a highest value of current efficiency, the thickness of the EBL may be fixed, and then the microcavity may be adjusted by adjusting the thickness of the HTL. Apparently, those skilled in the art can understand that when two top-emitting devices differ only in that different materials are used in one organic layer, for example, different organic materials are only used in the EML (other functional layers use the same materials), since the different organic materials in the EML may have slightly different refractive indexes, the optimal microcavity lengths of the two top-emitting devices may be slightly different. That is, to achieve the same setting condition (such as CEmax, CIEx coordinate, or EQEmax), the optimal microcavity lengths of different top-emitting devices may be slightly different.

As used herein, the term “simulation” refers to the simulation performed by optical simulation software only through the refractive index curves and thicknesses of various layers of materials, excluding electrical simulation. The simulation software used in the present disclosure is Setfos 5.0 semiconductor thin-film optical simulation software developed by FLUXiM. The device structure used for the simulation is a device 400 shown in FIG. 4. Specifically, on a glass substrate with a thickness of 0.7 mm, a first electrode (i.e., an anode) adopts a three-layer structure of ITO (75 Å)/Ag (1500 Å)/ITO (150 Å), a hole injection layer (HIL) is formed of Compound HT and Compound PD (with a weight ratio of 97:3) and has a thickness of 100 Å; a hole transporting layer (HTL) is formed of Compound HT, and since the HTL is a microcavity adjustment layer, the thickness of the HTL is an optimized thickness, where the microcavity is adjusted within a range of 1000 to 1500 Å so that the top-emitting device meets the requirements; on the HTL, the electron blocking layer (EBL) is formed of Compound PH-23 and has a thickness of 50 Å; on the EBL, the emissive layer (EML) is formed of Compound PH-1, Compound H-40, and an organic light-emitting doping material (with a weight ratio of 48:48:4) and has a thickness of 400 Å; on the EML, the hole blocking layer (HBL) is formed of Compound H-2 and has a thickness of 50 Å; on the HBL, the electron transporting layer (ETL) is formed of Compound ET and Compound Liq (with a weight ratio of 40:60) and has a thickness of 350 Å; on the ETL, a second electrode (i.e., a cathode) is formed of an alloy of Mg and Ag (with a weight ratio of 9:1) and has a thickness of 230 Å; a capping layer (CPL) with a thickness of 800 Å is formed on the cathode; glass is used as an encapsulation layer on the CPL. The specific structures of the above compounds are shown in the device examples below. Since Setfos 5.0 is optical simulation software, only the thicknesses and refractive indexes of layers in the device structure need to be determined during the simulation (the refractive index of each organic layer is the corresponding refractive index when the thickness of the material is 300 Å). Therefore, the materials of the above layers are only examples and are not limiting. The PL spectrum data of the organic light-emitting doping material used in the EML are inputted into the simulation software so that performance changes of the device caused by organic light-emitting doping materials with different PL spectra can be simulated. Additionally, the recombination position of the EML is set to be the middle position of the EML in the software.

As used herein, the refractive index of an organic material is tested by the following method: in the Angstrom Engineering evaporator, a material with a thickness of 30 nm is deposited on a silicon wafer and tested by an ellipsometer from BEIJING ELLITOP to obtain a curve of the refractive index at a wavelength of 400 nm to 800 nm.

As used herein, the PL spectrum of the organic light-emitting doping material is tested by the following method: the PL spectrum and full width at half maximum (FWHM) data of a material to be tested are tested using a fluorescence spectrophotometer F98 produced by SHANGHAI LENGGUANG TECHNOLOGY CO., LTD.; specifically, a sample of the material to be tested is prepared into a solution with a concentration of 1×10⁻⁶ mol/L with HPLC-grade toluene, the prepared solution is deoxygenated through nitrogen introduction for 5 minutes and then excited by light with a wavelength of 500 nm at room temperature (298 K), the emission spectrum is measured, and the FWHM is directly read from the spectrum.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy— as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted. 5 Alkylsilyl—as used herein, contemplates a silyl group substituted with an alkyl group.

Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyl diethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzonlquinoxaline, dibenzonlquinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, a substituted hydroxyl group, a substituted sulfanyl group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, amino, acyl, carbonyl, a carboxylic acid group, an ester group, hydroxyl group, sulfanyl group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl having 6 to 20 carbon atoms, unsubstituted alkylgermanyl having 3 to 20 carbon atoms, unsubstituted arylgermanyl group having 6 to 20 carbon atoms, unsubstituted amino having 0 to carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen can also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitution (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

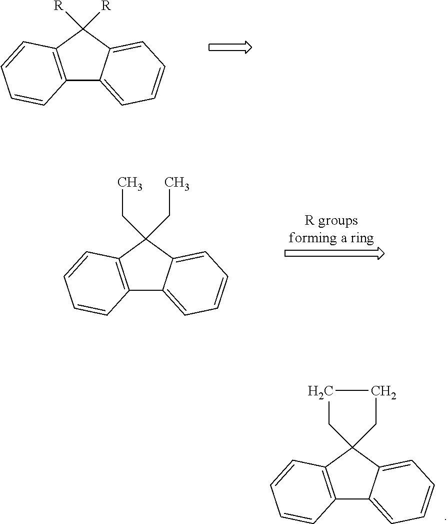

The expression that adjacent substituents can be optionally joined to form a ring is also intended to mean that two substituents bonded to carbon atoms which are directly bonded to each other are joined to each other via a chemical bond to form a ring, which can be exemplified by the following formula:

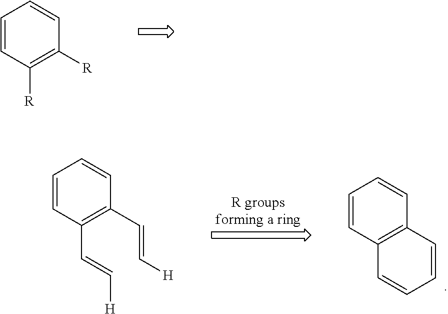

The expression that adjacent substituents can be optionally joined to form a ring is also intended to mean that two substituents bonded to a further distant carbon atom are joined to each other via a chemical bond to form a ring, which can be exemplified by the following formula:

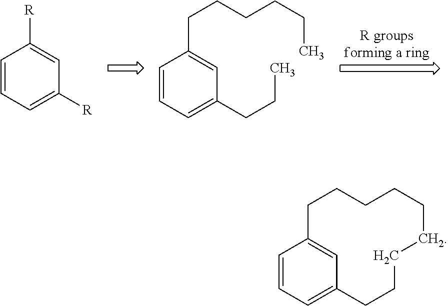

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

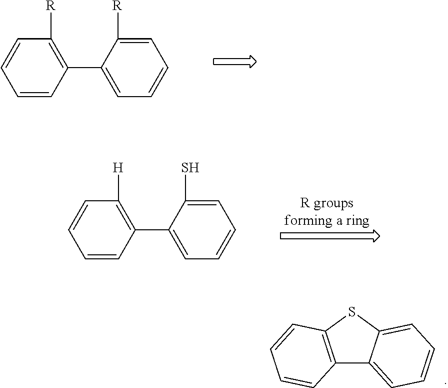

According to an embodiment of the present disclosure, an organic electroluminescent device is disclosed, which comprises a cathode, an anode, and an organic layer disposed between the cathode and the anode; wherein
the organic layer comprises a metal complex comprising a metal M and at least one C\hat{ }N bidentate ligand Lₐ coordinated to the metal M;
the metal M is selected from a metal with a relative atomic mass greater than 40; an area ratio of a photoluminescence spectrum of the metal complex at room temperature is AR, wherein AR≤0.331;
in a top-emitting device comprising the metal complex, when the top-emitting device reaches maximum current efficiency, the corresponding color coordinates are measured as CIE (x, y); and a distance between the CIE (x, y) and color coordinates CIE (0.170, 0.797) is calculated as D; wherein CIEy≥0.797 or D≤0.0320.

Herein, the distance between CIE (x, y) and color coordinates CIE (0.170, 0.797) is D, and D is calculated by the following formula:

D=\sqrt{(CIEx−0.170)²+(0.797−CIEy)²}.

Herein, the “top-emitting device” in the expression that “the metal complex corresponds to color coordinates CIE (x, y) when having maximum current efficiency in a top-emitting device” refers to any device emitting light in an opposite direction of a substrate. The top-emitting device includes, but is not limited to, the following top-emitting device used in the present application: ITO 75 Å/Ag 1500 Å/ITO 150 Å are sequentially deposited as a anode; Compound HT and Compound PD are deposited as an HIL (at a weight ratio of 97:3) with a thickness of 100 Å; Compound HT is deposited as an HTL, and a microcavity is adjusted within a range of 1000 to 1500 Å; Compound PH-23 is deposited as an EBL; the metal complex, Compound PH-1, and Compound H-40 are deposited as an EML (where the weight ratio of Compound PH-1, Compound H-40, and the metal complex is 48:48:4) with a thickness of 400 Å; Compound H-2 is deposited as an HBL with a thickness of 50 Å; Compound ET and Liq are deposited as an ETL (at a weight ratio of 40:60) with a thickness 350 Å; a metal Yb is deposited as an EIL with a thickness of 10 Å; a metal Ag and a metal Mg are deposited as a cathode (at a weight ratio of 9:1) with a thickness of 140 Å; Compound CP is deposited as a capping layer with a thickness of 800 Å. The specific structures of the above compounds are shown in the device examples below. The above specific top-emitting device is only exemplary, and those skilled in the art can adjust the thickness of any layer, select a suitable material combination and collocation for any layer, or even increase or decrease some functional layers to adjust the top-emitting device as long as CIEy≥0.797 or D≤0.0320 is achieved in a certain top-emitting device and the area ratio of the photoluminescence spectrum of the metal complex included in the top-emitting device at room temperature is AR≤0.331. That is, all metal complexes satisfying the above requirements belongs to the present application. The use of the metal complex in which device is not limited in the present application, and the use of the metal complex in particular top-emitting and bottom-emitting devices is only exemplarily illustrated in the examples of the present application. Those skilled in the art can adjust the devices illustrated in the present application based on an understanding of the devices or apply the metal complex to other devices such as a stacked device.

The structure of a complete top-emitting device is substrate/anode/hole transporting region/light-emitting layer/electron transporting region/cathode/capping layer/encapsulation layer, wherein the hole transporting region may comprise a hole injection layer (HIL), a hole transporting layer (HTL), and an electron blocking layer (EBL), and the electron transporting region may comprise a hole blocking layer (HBL), an electron transporting layer (ETL), and an electron injection layer (EIL). The HBL and/or the EBL may exist selectively due to different device structures, and the preceding functional layers may also comprise one or more layers due to different device structures. The device structure of the top-emitting device and the device structure of the bottom-emitting device have different requirements on electrodes due to different light emission directions of the bottom-emitting device and the top-emitting device. The top-emitting device emits light from the cathode of the device, so the cathode is required to have a high light transmittance and the anode is usually a material or a combination of materials with a high reflectivity. For a detailed description of the top-emitting device, reference may be made to the preceding description of the typical top-emitting device shown in FIG. 3.

According to an embodiment of the present disclosure, a maximum emission wavelength and a full width at half maximum of an electroluminescence spectrum of the metal complex are λₘₐₓ and FWHM, wherein 490 nm≤λₘₐₓ≤524 nm and FWHM≤35 nm.

Herein, the “electroluminescence spectrum” in the “electroluminescence spectrum of the metal complex” refers to a luminescence spectrum of any bottom-emitting device comprising the metal complex, wherein the “bottom-emitting device” includes, but is not limited to, the following bottom-emitting device used in the present application: 80 nm thick ITO is deposited as an anode; Compound HI is used as an HIL with a thickness of 100 Å; Compound HT is used as an HTL with a thickness of 350 Å; Compound PH-23 is used as an EBL with a thickness of 50 Å; the metal complex, Compound PH-23, and Compound H-40 (with a weight ratio of 6:56:38) are co-deposited as an EML with a thickness of 400 Å; Compound H-2 is deposited as an HBL with a thickness of 50 Å; Compound ET and Liq (with a weight ratio of 40:60) are co-deposited as an ETL with a thickness of 350 Å; Liq is deposited as an EIL with a thickness of 1 nm; and aluminum was deposited as a cathode with a thickness of 120 nm. The specific structures of the above compounds are shown in the device examples below. The above specific bottom-emitting device is only exemplary, and those skilled in the art can adjust the thickness of any layer, select a suitable material combination and collocation, and even increase or decrease some functional layers as required to adjust the bottom-emitting device.

According to an embodiment of the present disclosure, the maximum emission wavelength and the full width at half maximum of the electroluminescence spectrum of the metal complex are λₘₐₓ and FWHM, wherein 500 nm≤λₘₐₓ≤524 nm and FWHM≤34 nm.

According to an embodiment of the present disclosure, D≤0.0280.

According to an embodiment of the present disclosure, a highest occupied molecular orbital energy level (E_{HOMO}) of the metal complex is less than or equal to −5.05 eV.

According to an embodiment of the present disclosure, the highest occupied molecular orbital energy level (E_{HOMO}) of the metal complex is less than or equal to −5.10 eV.

According to an embodiment of the present disclosure, the highest occupied molecular orbital energy level (E_{HOMO}) of the metal complex is less than or equal to −5.20 eV.

According to an embodiment of the present disclosure, a lowest unoccupied molecular orbital energy level (E_{LUMO}) of the metal complex is less than or equal to −2.1 eV.

According to an embodiment of the present disclosure, the lowest unoccupied molecular orbital energy level (E_{LUMO}) of the metal complex is less than or equal to −2.2 eV.

According to an embodiment of the present disclosure, the lowest unoccupied molecular orbital energy level (E_{LUMO}) of the metal complex is less than or equal to −2.3 eV.

According to an embodiment of the present disclosure, the organic layer further comprises a first compound.

According to an embodiment of the present disclosure, a lowest unoccupied molecular orbital energy level (E_{LUMO-H1}) of the first compound is less than or equal to −2.70 eV.

According to an embodiment of the present disclosure, the lowest unoccupied molecular orbital energy level (E_{LUMO-H1}) of the first compound is less than or equal to −2.80 eV.

According to an embodiment of the present disclosure, the organic layer further comprises a first compound and a second compound.

According to an embodiment of the present disclosure, a highest occupied molecular orbital energy level (E_{HOMO-H2}) of the second compound is greater than or equal to −5.60 eV.

According to an embodiment of the present disclosure, the highest occupied molecular orbital energy level (E_{HOMO-H2}) of the second compound is greater than or equal to −5.50 eV.

According to an embodiment of the present disclosure, the first compound and/or the second compound comprise at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

According to an embodiment of the present disclosure, the metal complex is doped in the first compound and the second compound, and the weight of the metal complex accounts for 1% to 30% of the total weight of the organic layer.

According to an embodiment of the present disclosure, the metal complex is doped in the first compound and the second compound, and the weight of the metal complex accounts for 3% to 13% of the total weight of the organic layer.

According to an embodiment of the present disclosure, the organic electroluminescent device is a top-emitting device.

According to an embodiment of the present disclosure, the organic electroluminescent device is a top-emitting device, and a maximum emission wavelength of the top-emitting device is λₘₐₓ; and 500 nm≤λₘₐₓ≤540 nm.

According to an embodiment of the present disclosure, the top-emitting device is a single-layer device or a stacked device.

According to an embodiment of the present disclosure, the organic electroluminescent device is a bottom-emitting device.

According to an embodiment of the present disclosure, the organic electroluminescent device is a stacked device.

According to an embodiment of the present disclosure, the organic electroluminescent device is a stacked device, and the stacked device emits white light.

According to an embodiment of the present disclosure, the metal complex has a general formula of M(Lₐ)ₘ(L_{b})ₙ(L_{c})_{q}; wherein
Lₐ, L_{b}, and L_{c} are a first ligand, a second ligand, and a third ligand coordinated to the metal M, respectively, and Lₐ, L_{b}, and L_{c} are the same or different; wherein Lₐ, L_{b}, and Lₑ can be optionally joined to form a tetradentate ligand or a multidentate ligand;
the metal M is, at each occurrence identically or differently, selected from the group consisting of Cu, Ag, Au, Ru, Rh, Pd, Os, Ir, and Pt;
m is selected from 1, 2, or 3, n is selected from 0, 1, or 2, q is selected from 0, 1, or 2, and m+n+q equals the oxidation state of M; when m is 2 or 3, multiple Lₐ may be the same or different; when n is 2, two L_{b} may be the same or different; when q is 2, two L e may be the same or different;
Lₐ has a structure of A-E, wherein
A is, at each occurrence identically or differently, selected from a substituted or unsubstituted heteroaromatic ring having 5 to 6 ring atoms, wherein the heteroaromatic ring comprises at least one nitrogen atom, and A attaches to the metal via the nitrogen atom in the heteroaromatic ring to form a metal-nitrogen bond or a metal-G-nitrogen bond;
E is, at each occurrence identically or differently, selected from a substituted or unsubstituted aromatic ring having 13 to 30 ring atoms or a substituted or unsubstituted heteroaromatic ring having 13 to 30 ring atoms, wherein the aromatic ring or the heteroaromatic ring is a fused structure having at least three rings, and the at least three rings at least comprise two six-membered rings and one five-membered ring; and E attaches to the metal through a carbon atom in the aromatic ring or the heteroaromatic ring to form a metal-carbon bond or a metal-G-carbon bond;
L_{b} and L_{c} have, at each occurrence identically or differently, a structure of C-L-D, wherein
C and D are, at each occurrence identically or differently, selected from a substituted or unsubstituted aromatic ring having 6 to 30 ring atoms, a substituted or unsubstituted heteroaromatic ring having 5 to 30 ring atoms, or a combination thereof, and C and D are, at each occurrence identically or differently, attaches to the metal via a carbon atom or a nitrogen atom in the aromatic ring or the heteroaromatic ring to form a metal-carbon bond, a metal-nitrogen bond, a metal-G-carbon bond, or a metal-G-nitrogen bond;
L is, at each occurrence identically or differently, selected from the group consisting of: a single bond, BR_{L}, CR_{L} R_{L}, NR_{L}, SiR_{L} R_{L}, PR_{L}, GeR_{L} R_{L}, O, S, Se, substituted or unsubstituted vinylene, ethynylene, substituted or unsubstituted arylene having 5 to 30 carbon atoms, substituted or unsubstituted heteroarylene having 5 to 30 carbon atoms, and combinations thereof; when two R_{L} are present at the same time, the two R_{L} are the same or different;
R_{L} represents, at each occurrence identically or differently, hydrogen or a substituent;
G is, at each occurrence identically or differently, selected from a single bond, O, or S; and
adjacent substituents can be optionally joined to form a ring.

According to an embodiment of the present disclosure, the metal M is, at each occurrence identically or differently, selected from Pt or Ir.

According to an embodiment of the present disclosure, the organic layer comprising the metal complex is a light-emitting layer.

According to another object of the present disclosure, a display assembly is further disclosed. The display assembly comprises the organic electroluminescent device in any one of the preceding embodiments.

According to another object of the present disclosure, an embodiment about the metal complex is disclosed separately, where the embodiment discloses a metal complex having a general formula of M(Lₐ)ₘ(L_{b})ₙ(L_{c})_{q}; wherein
Lₐ, L_{b}, and L_{c} are a first ligand, a second ligand, and a third ligand coordinated to the metal M, respectively, and Lₐ, L_{b}, and L_{c} are the same or different; wherein Lₐ, L_{b}, and L_{c} can be optionally joined to form a tetradentate ligand or a multidentate ligand;
m is selected from 1, 2, or 3, n is selected from 0, 1, or 2, q is selected from 0, 1, or 2, and m+n+q equals the oxidation state of M; when m is 2 or 3, multiple Lₐ may be the same or different; when n is 2, two L_{b} may be the same or different; when q is 2, two L_{c} may be the same or different;
the metal complex comprises the metal M and at least one C\hat{ }N bidentate ligand Lₐ coordinated to the metal M;
the metal M is selected from a metal with a relative atomic mass greater than 40;
L_{b} and L_{c} are, at each occurrence identically or differently, selected from a monoanionic bidentate ligand;
an area ratio of a photoluminescence spectrum of the metal complex at room temperature is AR, wherein AR≤0.331;
in a top-emitting device comprising the metal complex, when the top-emitting device reaches maximum current efficiency, the corresponding color coordinates are measured as CIE (x, y); and a distance between the CIE (x, y) and color coordinates CIE (0.170, 0.797) is calculated as D; wherein CIEy≥0.797 or D≤0.0320.

According to an embodiment of the present disclosure, the metal complex has a structure represented by Formula 1 or Formula 2:

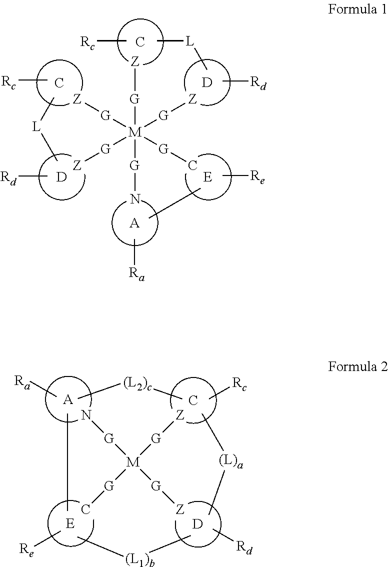

wherein
the metal M is selected from a metal with a relative atomic mass greater than 40;
the ring A is, at each occurrence identically or differently, selected from a nitrogen-containing heteroaromatic ring having 5 to 6 ring atoms;
the ring E is, at each occurrence identically or differently, selected from an aromatic ring or a heteroaromatic ring having 13 to 30 ring atoms and being a fused structure having at least three rings, wherein the at least three rings at least comprise two six-membered rings and one five-membered ring;
the ring C and the ring D are, at each occurrence identically or differently, selected from an aromatic ring having 6 to 30 carbon atoms, a heteroaromatic ring having 3 to 30 carbon atoms, or a combination thereof;
Z is, at each occurrence identically or differently, selected from C or N;
G is, at each occurrence identically or differently, selected from a single bond, O, or S;
L, L₁, and L₂ are, at each occurrence identically or differently, selected from the group consisting of: a single bond, BR_{L}, CR_{L}R_{L}, NR_{L}, SiR_{L}R_{L}, PR_{L}, GeR_{L}R_{L}, O, S, Se, substituted or unsubstituted vinylene, ethynylene, substituted or unsubstituted arylene having 5 to 30 carbon atoms, substituted or unsubstituted heteroarylene having 5 to 30 carbon atoms, and combinations thereof; when two R_{L} are present at the same time, the two R_{L} are the same or different;
a, b, and c are, at each occurrence identically or differently, selected from 0 or 1;
Rₐ, Rₑ, R_{c}, and R_{d} represent, at each occurrence identically or differently, mono-substitution, multiple substitutions, or non-substitution;
Rₐ, Rₑ, R_{c}, R_{d}, and R_{L} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfanyl group, a sulfonyl group, a phosphino group, and combinations thereof; and
adjacent substituents Rₐ, Rₑ, R_{c}, R_{d}, and R_{L} can be optionally joined to form a ring.

Herein, the expression that “adjacent substituents Rₐ, Rₑ, R_{c}, R_{d}, and R_{L} can be optionally joined to form a ring” is intended to mean that any one or more of groups of adjacent substituents, such as two substituents Rₐ, two substituents Rₑ, two substituents R_{c}, two substituents R_{d}, two substituents R_{L}, substituents Rₐ and Rₑ, substituents R_{c} and R_{d}, substituents R_{c} and R_{L}, substituents R_{d} and R_{L}, substituents Rₐ and R_{L}, and substituents Rₑ and R_{L}, can be joined to form a ring. Obviously, it is also possible that none of these substituents are joined to form a ring.

According to an embodiment of the present disclosure, L_{b} and L_{c} are, at each occurrence identically or differently, selected from the group consisting of Formula a to Formula m:

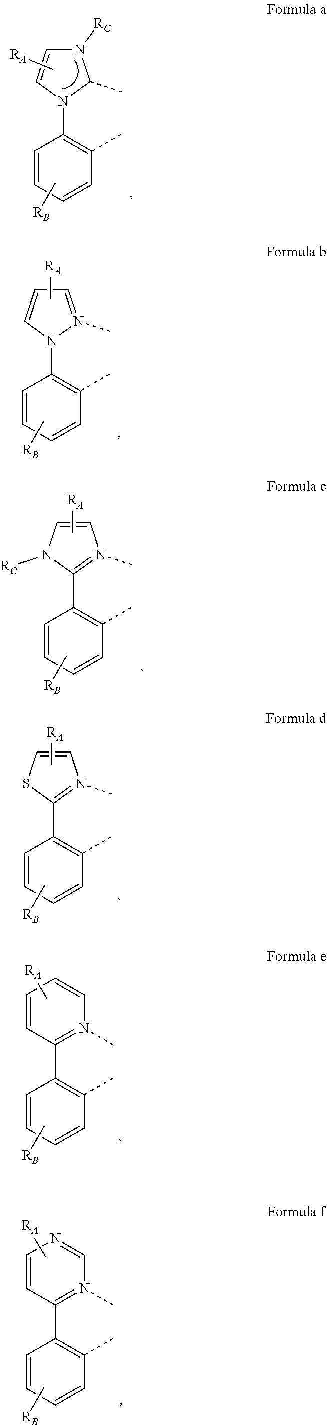

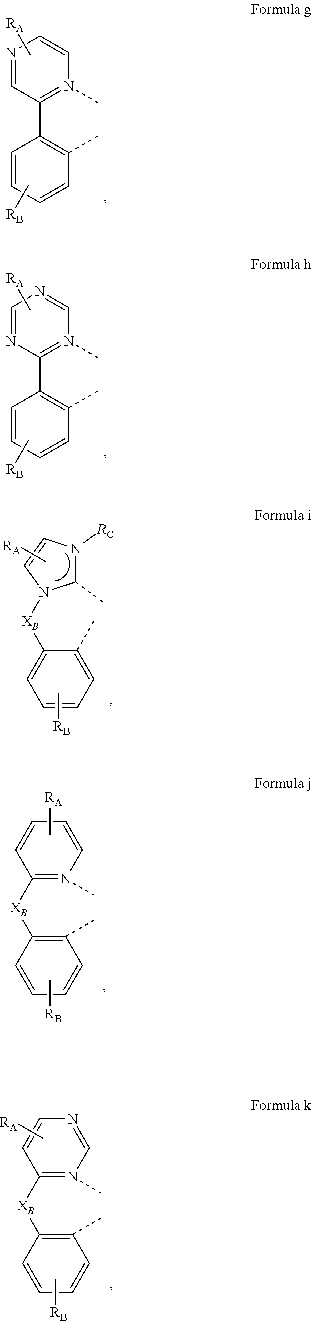

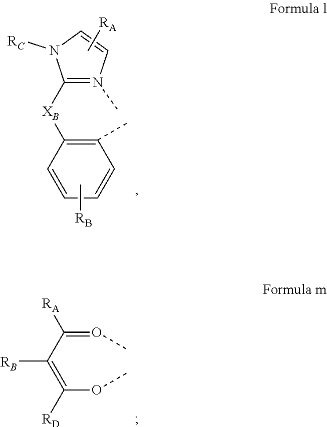

wherein
R_{A} and R_{B} represent, at each occurrence identically or differently, mono-substitution, multiple substitutions, or non-substitution;
X_{B} is, at each occurrence identically or differently, selected from the group consisting of: O, S, Se, NR_{N1}, and CR_{C1}R_{C2};
R_{A}, R_{B}, R_{C}, R_{D}, R_{N1}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfanyl group, a sulfonyl group, a phosphino group, and combinations thereof; and
adjacent substituents R_{A}, R_{B}, R_{C}, R_{D}, R_{N1}, R_{C1}, and R_{C2} can be optionally joined to form a ring.

Herein, the expression that “adjacent substituents R_{A}, R_{B}, R_{C}, R_{D}, R_{N1}, R_{C1}, and R_{C2} can be optionally joined to form a ring” is intended to mean that any one or more of groups of adjacent substituents, such as two substituents R_{A}, two substituents R_{B}, substituents R_{A} and R_{B}, substituents R_{A} and R_{C}, substituents R_{B} and R_{C}, substituents R_{A} and R_{N1}, substituents R_{B} and R_{N1}, substituents R_{A} and R_{C1}, substituents R_{A} and R_{C2}, substituents R_{B} and R_{C1}, substituents R_{B} and R_{C2}, and substituents R_{C1} and R_{C2}, can be joined to form a ring. Obviously, it is also possible that none of these substituents are joined to form a ring. For example, adjacent substituents R_{A} and R_{B} in

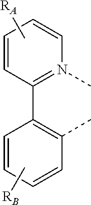

can be optionally joined to form a ring. When R_{A} are optionally joined to form a ring,

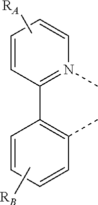

may form a structure of

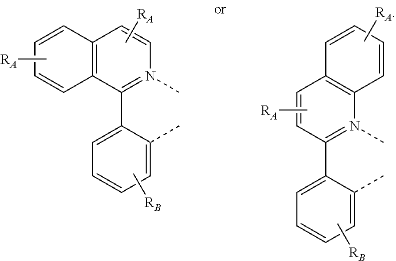

According to an embodiment of the present disclosure, Lₐ has, at each occurrence identically or differently, a structure represented by Formula 3, and L_{b} has, at each occurrence identically or differently, a structure represented by Formula 4:

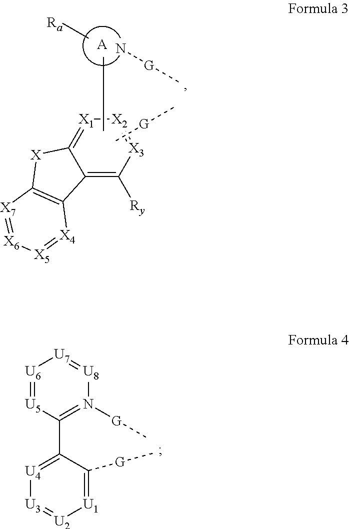

wherein
A is, at each occurrence identically or differently, selected from a nitrogen-containing heteroaromatic ring having 5 to 6 ring atoms;
X is selected from the group consisting of O, S, Se, NW, CR′R′, and SiR′R; wherein when two R′ are present at the same time, the two R′ are the same or different;
U₁ to U₈ are, at each occurrence identically or differently, selected from CRᵤ or N;
G is, at each occurrence identically or differently, selected from a single bond, O, or S;
X₁ to X₇ are, at each occurrence identically or differently, selected from C, N, or CRₓ, and one of X₁, X₂, and X₃ is selected from C and joined to A;
one of X₁, X₂, and X₃ is selected from N and joined to the metal through a metal-nitrogen bond; or one of X₁, X₂, and X₃ is selected from C and joined to the metal through G;
at least one of X₁ to X₇ is selected from CRₓ, and Rₓ is cyano or fluorine;
Rₐ represents, at each occurrence identically or differently, mono-substitution, multiple substitutions, or non-substitution;
R′, R u, Rₓ, and R_{d} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
R_{y} is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₓ can be optionally joined to form a ring;
adjacent substituents Rₐ can be optionally joined to form a ring; and
adjacent substituents Rᵤ can be optionally joined to form a ring.

Herein, the expression that “adjacent substituents Rₓ can be optionally joined to form a ring” is intended to mean that any one or more of groups of any two adjacent substituents Rₓ can be joined to form a ring. Obviously, it is also possible that none of these groups of substituents are joined to form a ring.

Herein, the expression that “adjacent substituents Rₐ can be optionally joined to form a ring” is intended to mean that any one or more of groups of any two adjacent substituents Rₐ can be joined to form a ring. Obviously, it is also possible that none of these groups of substituents are joined to form a ring.

Herein, the expression that “adjacent substituents Rᵤ can be optionally joined to form a ring” is intended to mean that any one or more of groups of any two adjacent substituents Rᵤ can be joined to form a ring. Obviously, it is also possible that none of these groups of substituents are joined to form a ring.

According to an embodiment of the present disclosure,

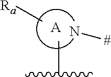

in Formula 3 is, at each occurrence identically or differently, selected from any one of the following structures:

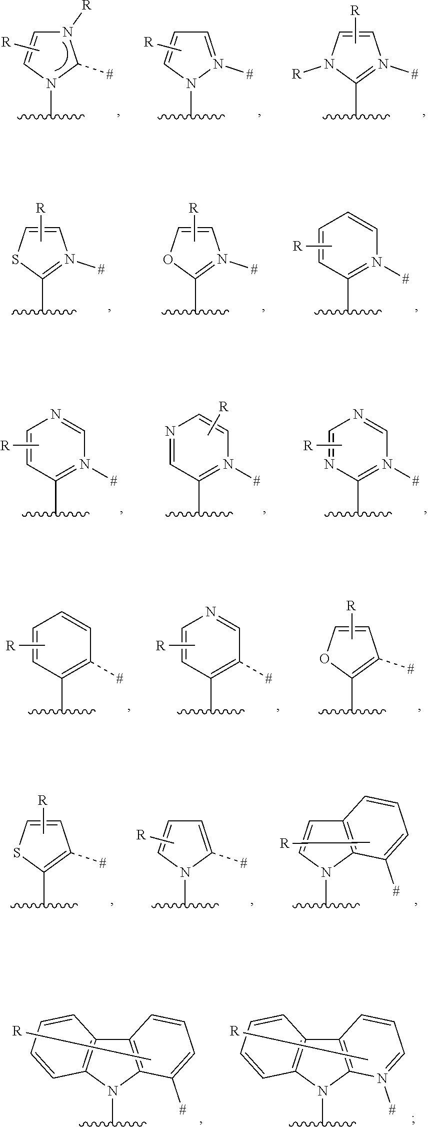

wherein
R represents, at each occurrence identically or differently, mono-substitution, multiple substitutions, or non-substitution; when multiple R are present at the same time in any structure, the multiple R are the same or different;
R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R can be optionally joined to form a ring; and
“#” represents a position where G is joined, and

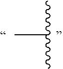

represents a position where X₁, X₂, or X₃ is joined.

Herein, the expression that “adjacent substituents R can be optionally joined to form a ring” is intended to mean that any one or more of groups of any two adjacent substituents R can be joined to form a ring. Obviously, it is also possible that none of these groups of substituents are joined to form a ring.

According to an embodiment of the present disclosure, the metal complex has a general formula of Ir(Lₐ)ₘ(L_{b})₃₋ₘ and has a structure represented by Formula 5:

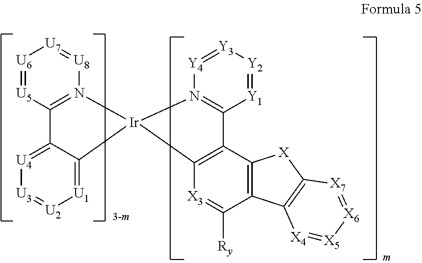

wherein
m is selected from 1 or 2; when m=1, two L_{b} are the same or different; when m=2, two Lₐ are the same or different;
X is selected from the group consisting of O, S, Se, NW, CR′R′, SiR′R′, and GeR′R′; wherein when two R′ are present at the same time, the two R′ are the same or different;
Y₁ to Y₄ are, at each occurrence identically or differently, selected from CR_{Y} or N;
U₁ to U₈ are, at each occurrence identically or differently, selected from CRᵤ or N;
X₃ to X₇ are, at each occurrence identically or differently, selected from CRₓ or N;
at least one of X₃ to X₇ is selected from CRₓ, and Rₓ is cyano or fluorine;
R′, Rₓ, R_{Y}, and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfanyl group, a sulfonyl group, a phosphino group, and combinations thereof;
R_{y} is, at each occurrence identically or differently, selected from the group consisting of: fluorine, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted alkylsilyl having 3 to 20 carbon atoms, substituted or unsubstituted alkylgermanyl having 3 to 20 carbon atoms, and combinations thereof;
adjacent substituents R_{y} can be optionally joined to form a ring; and
adjacent substituents Rᵤ can be optionally joined to form a ring.

Herein, the expression that “adjacent substituents R_{y} can be optionally joined to form a ring” is intended to mean that any one or more of groups of any two adjacent substituents R_{y} can be joined to form a ring. Obviously, it is also possible that none of these groups of substituents are joined to form a ring.

According to another embodiment of the present disclosure, X is, at each occurrence identically or differently, selected from O or S.

According to another embodiment of the present disclosure, X is O.

According to an embodiment of the present disclosure, at least one of X₄ to X₇ is selected from CRₓ, and Rₓ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, at least one of X₄ to X₇ is selected from CRₓ, and Rₓ is, at each occurrence identically or differently, selected from substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, fluorine, cyano, or a combination thereof.

According to an embodiment of the present disclosure, at least one of X₄ to X₇ is selected from CRₓ, and Rₓ is fluorine or cyano.

According to an embodiment of the present disclosure, X₆ is selected from CRₓ, and Rₓ is fluorine or cyano.

According to an embodiment of the present disclosure, X₇ is selected from CRₓ, and Rₓ is, at each occurrence identically or differently, selected from substituted or unsubstituted aryl having 6 to 30 carbon atoms, substituted or unsubstituted heteroaryl having 3 to 30 carbon atoms, fluorine, cyano, or a combination thereof.

According to an embodiment of the present disclosure, at least one or at least two of U₁ to U₈ are selected from CRᵤ, Rᵤ is selected from substituted or unsubstituted alkyl having 1 to 20 carbon atoms, substituted or unsubstituted cycloalkyl having 3 to 20 ring carbon atoms, or a combination thereof, and the total number of carbon atoms in all of Rᵤ is at least 4.

According to an embodiment of the present disclosure, at least one or at least two of U₅ to U₈ are selected from CRᵤ, Rᵤ is selected from substituted or unsubstituted alkyl having 1 to 20 carbon atoms, substituted or unsubstituted cycloalkyl having 3 to 20 ring carbon atoms, or a combination thereof, and the total number of carbon atoms in all of Rᵤ is at least 4.

According to an embodiment of the present disclosure, at least one or at least two of U₁ to U₄ are selected from CRᵤ, Rᵤ is selected from substituted or unsubstituted alkyl having 1 to 20 carbon atoms, substituted or unsubstituted cycloalkyl having 3 to 20 ring carbon atoms, or a combination thereof, and the total number of carbon atoms in all of Rᵤ is at least 4.

According to an embodiment of the present disclosure, at least one or at least two of U₁ to U₄ are selected from CRᵤ, Rᵤ is selected from substituted or unsubstituted alkyl having 1 to 20 carbon atoms, substituted or unsubstituted cycloalkyl having 3 to 20 ring carbon atoms, or a combination thereof, and the total number of carbon atoms in all of Rᵤ is at least 4; meanwhile, at least one or at least two of U₅ to U₈ are selected from CRᵤ, Rᵤ is selected from substituted or unsubstituted alkyl having 1 to 20 carbon atoms, substituted or unsubstituted cycloalkyl having 3 to 20 ring carbon atoms, or a combination thereof, and the total number of carbon atoms in all of Rᵤ is at least 4.

According to an embodiment of the present disclosure, U₂ or U₃ is selected from CRᵤ, and Rᵤ is selected from substituted or unsubstituted alkyl having 1 to 20 carbon atoms, substituted or unsubstituted cycloalkyl having 3 to 20 ring carbon atoms, or a combination thereof.

According to an embodiment of the present disclosure, U₂ or U₃ is selected from CRᵤ, and Rᵤ is selected from substituted or unsubstituted alkyl having 4 to 20 carbon atoms, substituted or unsubstituted cycloalkyl having 4 to 20 ring carbon atoms, or a combination thereof.

According to an embodiment of the present disclosure, at least one of U₁ to U₄ is selected from CRᵤ, at least one of Y i to Y₄ is selected from CR, and Rᵤ and R are selected from substituted or unsubstituted alkyl having 1 to 20 carbon atoms, substituted or unsubstituted cycloalkyl having 3 to 20 ring carbon atoms, or a combination thereof; and the total number of Rᵤ and R is greater than or equal to 2.

According to an embodiment of the present disclosure, at least one of U₅ to U₈ is selected from CRᵤ, at least one of Y₁ to Y₄ is selected from CR, and Rᵤ and R are selected from substituted or unsubstituted alkyl having 1 to 20 carbon atoms, substituted or unsubstituted cycloalkyl having 3 to 20 ring carbon atoms, or a combination thereof; and the total number of Rᵤ and R is greater than or equal to 2.

According to an embodiment of the present disclosure, at least one of U₁ to U₄ is selected from CRᵤ, at least one of U₅ to U₈ is selected from CRᵤ, and Rᵤ is selected from substituted or unsubstituted alkyl having 1 to 20 carbon atoms, substituted or unsubstituted cycloalkyl having 3 to 20 ring carbon atoms, or a combination thereof; and the total number of

Rᵤ is greater than or equal to 2.

According to an embodiment of the present disclosure, the metal complex has a general formula of Ir(Lₐ)ₘ(L_{b})₃₋ₘ and has a structure represented by Formula 5-1:

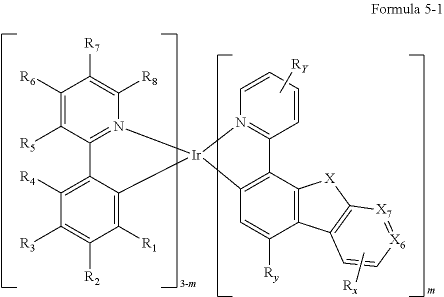

wherein
m is selected from 1 or 2; when m=1, two L_{b} are the same or different; when m=2, two Lₐ are the same or different;
X is selected from the group consisting of O, S, Se, NR′, CR′R′, SiR′R′, and GeR′R′; wherein when two R′ are present at the same time, the two R′ are the same or different;
X₆ to X₇ are, at each occurrence identically or differently, selected from CRₓ or N;
Rₓ and R_{Y} represent, at each occurrence identically or differently, mono-substitution, multiple substitutions, or non-substitution;
at least one W is cyano or fluorine;
R′, Rₓ, R_{Y}, and R₁ to R₈ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfanyl group, a sulfonyl group, a phosphino group, and combinations thereof;
R_{y} is, at each occurrence identically or differently, selected from the group consisting of: fluorine, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted alkylsilyl having 3 to 20 carbon atoms, substituted or unsubstituted alkylgermanyl having 3 to 20 carbon atoms, and combinations thereof;
adjacent substituents R_{Y} can be optionally joined to form a ring; and
adjacent substituents R₁ to R₈ can be optionally joined to form a ring.

According to an embodiment of the present disclosure, R_{y} is, at each occurrence, selected from the group consisting of: substituted or unsubstituted alkyl having 1 to 20 carbon atoms and substituted or unsubstituted cycloalkyl having 3 to 20 ring carbon atoms.

According to an embodiment of the present disclosure, R_{y} is, at each occurrence, selected from the group consisting of substituted or unsubstituted alkyl having 4 to 20 carbon atoms.

According to an embodiment of the present disclosure, R_{y} is selected from the group consisting of the following substituents that are substituted or unsubstituted:

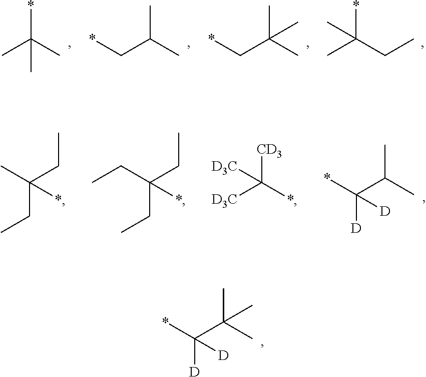

and combinations thereof; optionally, hydrogens in the above groups are partially or fully deuterated;
wherein “*” represents a position where the substituent is joined to carbon.

According to an embodiment of the present disclosure, at least one or at least two of R₁ to R₈ are selected from substituted or unsubstituted alkyl having 1 to 20 carbon atoms, substituted or unsubstituted cycloalkyl having 3 to 20 ring carbon atoms, or a combination thereof; and the total number of carbon atoms in all of R₁ to R₄ and/or R₅ to R₈ is at least 4.

According to an embodiment of the present disclosure, at least one or at least two of

R₅ to R₈ are selected from substituted or unsubstituted alkyl having 1 to 20 carbon atoms, substituted or unsubstituted cycloalkyl having 3 to 20 ring carbon atoms, or a combination thereof, and the total number of carbon atoms in all of the substituents R₅ to R₈ is at least 4.

According to an embodiment of the present disclosure, at least one or at least two of R₁ to R₄ are selected from substituted or unsubstituted alkyl having 1 to 20 carbon atoms, substituted or unsubstituted cycloalkyl having 3 to 20 ring carbon atoms, or a combination thereof, and the total number of carbon atoms in all of the substituents R₁ to R₄ is at least 4.

According to an embodiment of the present disclosure, at least one or at least two of R₁ to R₄ are selected from substituted or unsubstituted alkyl having 1 to 20 carbon atoms, substituted or unsubstituted cycloalkyl having 3 to 20 ring carbon atoms, or a combination thereof, and the total number of carbon atoms in all of the substituents R₁ to R₄ is at least 4;

meanwhile, at least one or at least two of R₅ to R₈ are selected from substituted or unsubstituted alkyl having 1 to 20 carbon atoms, substituted or unsubstituted cycloalkyl having 3 to 20 ring carbon atoms, or a combination thereof, and the total number of carbon atoms in all of the substituents R₅ to R₈ is at least 4.

According to an embodiment of the present disclosure, R₂ or R₃ is selected from substituted or unsubstituted alkyl having 1 to 20 carbon atoms, substituted or unsubstituted cycloalkyl having 3 to 20 ring carbon atoms, or a combination thereof.

According to an embodiment of the present disclosure, R₂ or R₃ is selected from substituted or unsubstituted alkyl having 4 to 20 carbon atoms, substituted or unsubstituted cycloalkyl having 4 to 20 ring carbon atoms, or a combination thereof.

According to an embodiment of the present disclosure, the metal M is, at each occurrence identically or differently, selected from the group consisting of Cu, Ag, Au, Ru, Rh, Pd, Os, Ir, and Pt.

According to an embodiment of the present disclosure, the metal M is, at each occurrence identically or differently, selected from Pt or Ir.

According to an embodiment of the present disclosure, A is, at each occurrence identically or differently, selected from an N-containing heteroaromatic ring having 6 ring atoms and unsubstituted or substituted with one or more Rₐ.

According to an embodiment of the present disclosure, A is, at each occurrence identically or differently, selected from pyridine unsubstituted or substituted with one or more Rₐ, pyrimidine unsubstituted or substituted with one or more Rₐ, or triazine unsubstituted or substituted with one or more Rₐ.

According to an embodiment of the present disclosure, E is, at each occurrence identically or differently, selected from an aromatic or heteroaromatic ring unsubstituted or substituted with one or more Rₑ and having a structure of a six-membered ring fused to a five-membered ring fused to a six-membered ring.

According to an embodiment of the present disclosure, E is, at each occurrence identically or differently, selected from the following groups unsubstituted or substituted with one or more Rₑ: dibenzothiophene, dibenzofuran, dibenzoselenophene, carbazole, fluorene, silafluorene, germafluorene, aza-dibenzothiophene, azadibenzofuran, aza-dibenzoselenophene, azacarbazole, azafluorene, azasilafluorene, and aza-germafluorene.

According to an embodiment of the present disclosure, C is, at each occurrence identically or differently, selected from an aromatic ring having 6 to 20 ring atoms and unsubstituted or substituted with one or more R_{c}, a heteroaromatic ring having 5 to 20 ring atoms and unsubstituted or substituted with one or more R_{c}, or a combination thereof.

According to an embodiment of the present disclosure, C is, at each occurrence identically or differently, selected from an aromatic ring having 6 to 12 ring atoms and unsubstituted or substituted with one or more R_{c}, a heteroaromatic ring having 5 to 12 ring atoms and unsubstituted or substituted with one or more R_{c}, or a combination thereof.

According to an embodiment of the present disclosure, C is, at each occurrence identically or differently, selected from a benzene ring unsubstituted or substituted with one or more R_{c}, a heteroaromatic ring having 5 to 6 ring atoms and unsubstituted or substituted with one or more R_{c}, or a combination thereof.

According to an embodiment of the present disclosure, D is, at each occurrence identically or differently, selected from an aromatic ring having 6 to 20 ring atoms and unsubstituted or substituted with one or more R_{d}, a heteroaromatic ring having 5 to 20 ring atoms and unsubstituted or substituted with one or more R_{d}, or a combination thereof.

According to an embodiment of the present disclosure, D is, at each occurrence identically or differently, selected from an aromatic ring having 6 to 12 ring atoms and unsubstituted or substituted with one or more R_{d}, a heteroaromatic ring having 5 to 12 ring atoms and unsubstituted or substituted with one or more R_{d}, or a combination thereof.

According to an embodiment of the present disclosure, D is, at each occurrence identically or differently, selected from a benzene ring unsubstituted or substituted with one or more R_{d}, a heteroaromatic ring having 5 to 6 ring atoms and unsubstituted or substituted with one or more R_{d}, or a combination thereof.

According to an embodiment of the present disclosure, C is, at each occurrence identically or differently, selected from the following groups unsubstituted or substituted with one or more R_{c}: a benzene ring, a pyridine ring, a pyrimidine ring, a pyrazine ring, a pyridazine ring, a triazine ring, an imidazole ring, an imidazolecarbene ring, a pyrazole ring, a thiazole ring, and an oxazole ring; and C is joined to the metal through a metal-nitrogen bond.

According to an embodiment of the present disclosure, C is, at each occurrence identically or differently, selected from a pyridine ring unsubstituted or substituted with one or more R_{c}.

According to an embodiment of the present disclosure, D is, at each occurrence identically or differently, selected from the following groups unsubstituted or substituted with one or more R_{d}: a benzene ring, a pyridine ring, a pyrimidine ring, a pyrazine ring, a pyridazine ring, a triazine ring, an imidazole ring, an imidazolecarbene ring, a pyrazole ring, a thiazole ring, and an oxazole ring; and D is joined to the metal through a metal-carbon bond.

According to an embodiment of the present disclosure, D is, at each occurrence identically or differently, selected from a benzene ring unsubstituted or substituted with one or more R_{d}.

According to an embodiment of the present disclosure, at least one of Rₐ, Rₑ, R_{c}, and R_{d} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfanyl group, a sulfonyl group, a phosphino group, and combinations thereof.

According to an embodiment of the present disclosure, at least one of Rₐ, Rₑ, R_{c}, and R_{d} is selected from the group consisting of: halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, cyano, and combinations thereof.

According to an embodiment of the present disclosure, at least one of Rₐ, Rₑ, R_{c}, and R_{d} is selected from the group consisting of: fluorine, substituted or unsubstituted alkyl having 1 to 10 carbon atoms, substituted or unsubstituted aryl having 6 to 18 carbon atoms, substituted or unsubstituted heteroaryl having 3 to 18 carbon atoms, substituted or unsubstituted alkylsilyl having 3 to 12 carbon atoms, cyano, and combinations thereof.

According to an embodiment of the present disclosure, at least one R_{c} and/or at least one R_{d} are selected from the group consisting of: substituted or unsubstituted alkyl having 1 to 20 carbon atoms and substituted or unsubstituted cycloalkyl having 3 to 20 ring carbon atoms.

According to an embodiment of the present disclosure, at least one R_{c} and/or at least one R_{d} are selected from the group consisting of: substituted or unsubstituted alkyl having 4 to 10 carbon atoms and substituted or unsubstituted cycloalkyl having 4 to 10 ring carbon atoms.

According to an embodiment of the present disclosure, one R_{c} is selected from the group consisting of: substituted or unsubstituted alkyl having 4 to 10 carbon atoms and substituted or unsubstituted cycloalkyl having 4 to 10 ring carbon atoms; and one R_{d} is selected from the group consisting of: substituted or unsubstituted alkyl having 4 to 10 carbon atoms and substituted or unsubstituted cycloalkyl having 4 to 10 ring carbon atoms.

According to an embodiment of the present disclosure, at least one Rₑ is selected from For CN.

According to an embodiment of the present disclosure, at least one Rₑ is selected from F or CN, and at least another one Rₑ is selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, and combinations thereof.

According to an embodiment of the present disclosure, at least one Rₑ is selected from F or CN, and at least another one Rₑ is selected from the group consisting of: substituted or unsubstituted alkyl having 1 to 20 carbon atoms, substituted or unsubstituted aryl having 6 to 30 carbon atoms, and combinations thereof.

According to another embodiment of the present disclosure, L_{b} and L_{c} are, at each occurrence identically or differently, selected from the group consisting of:

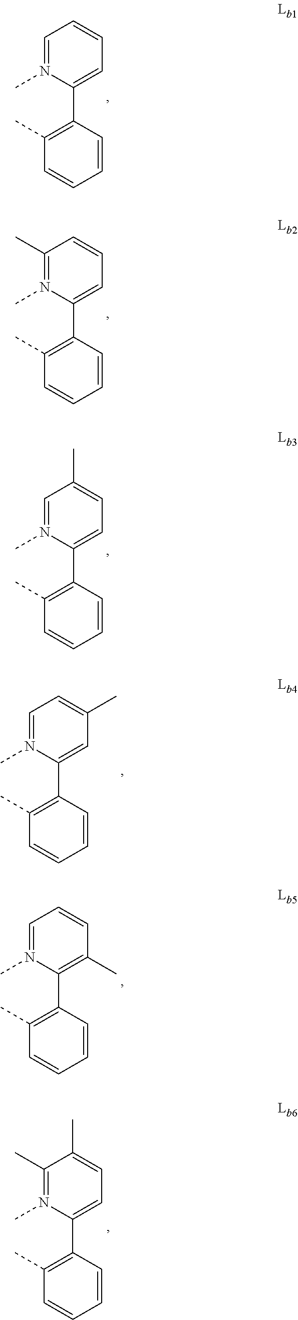

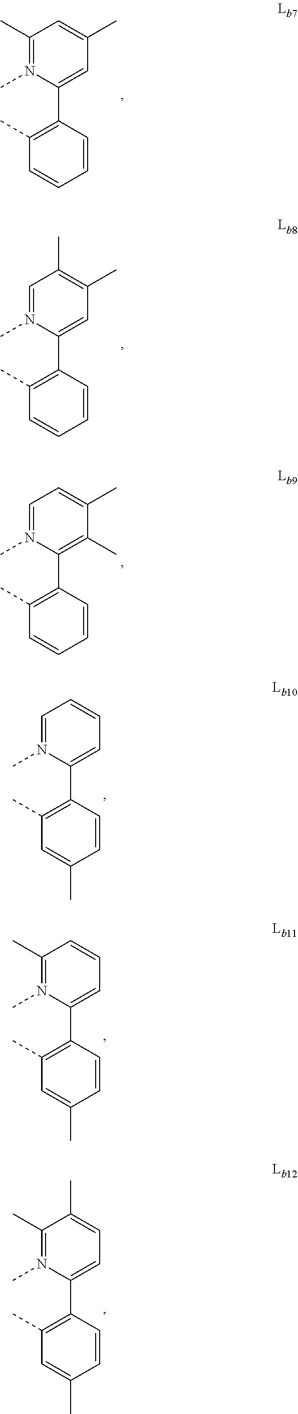

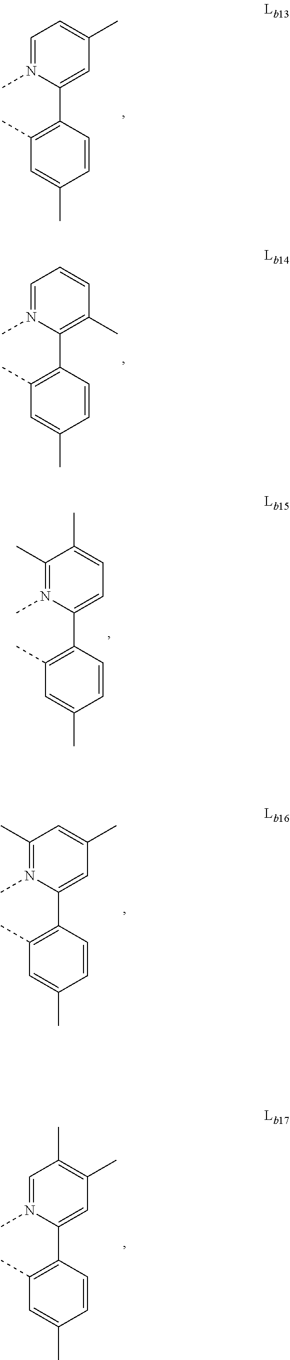

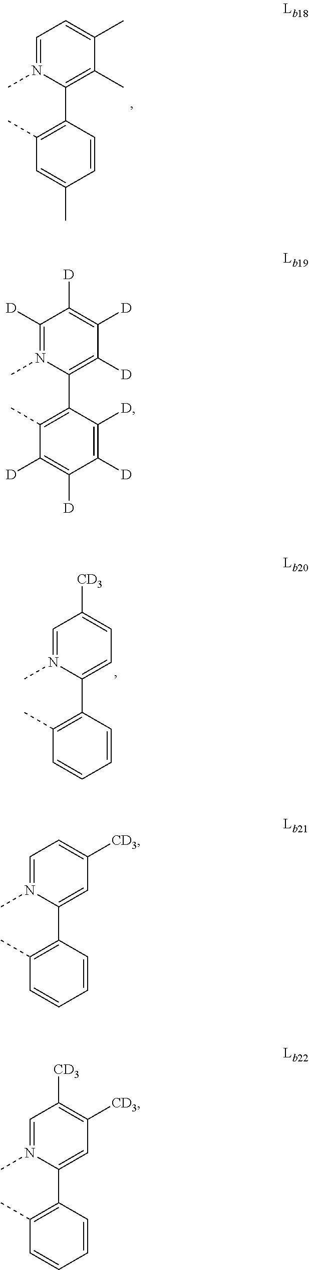

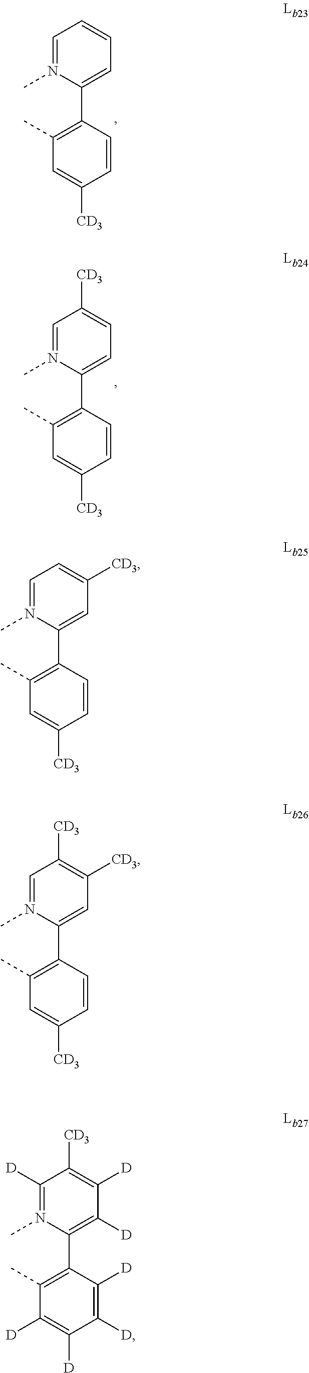

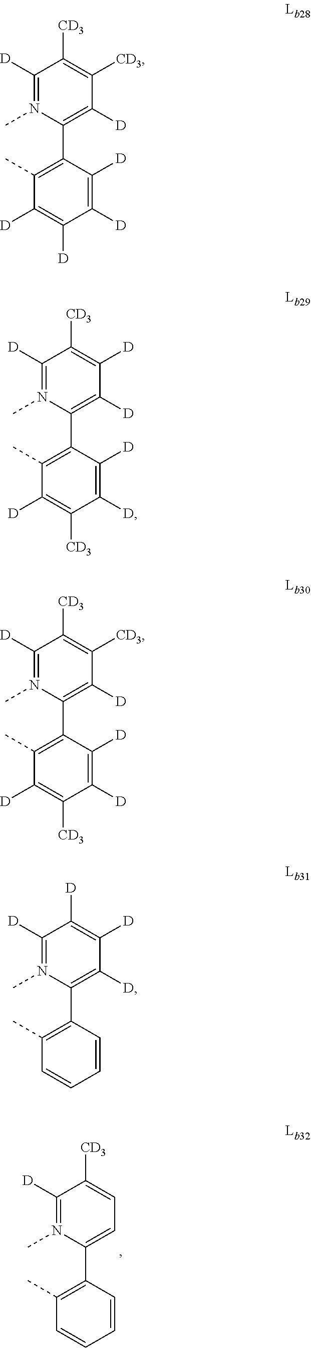

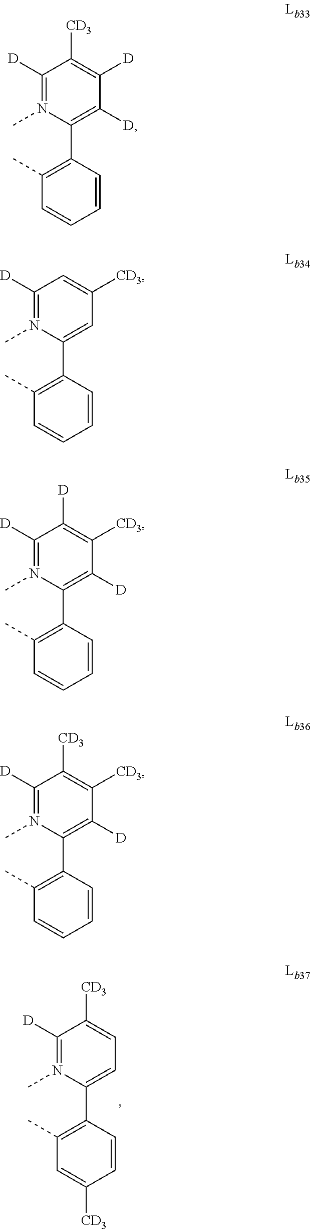

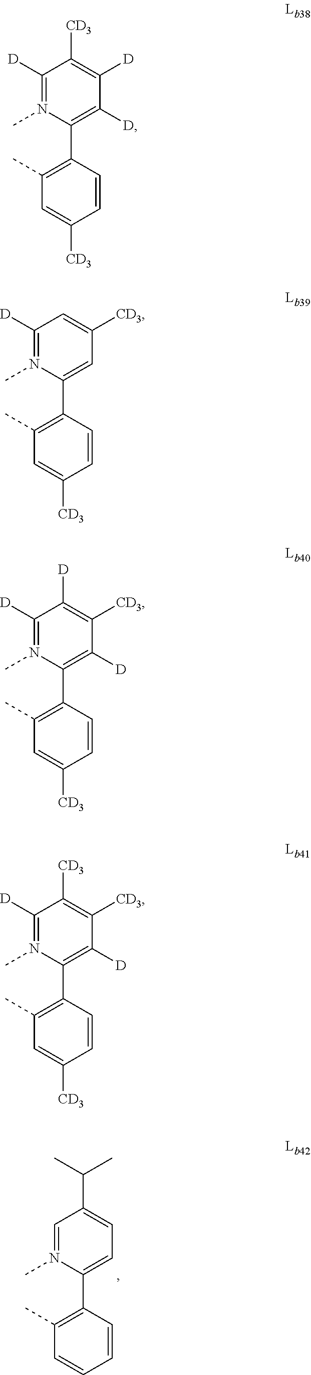

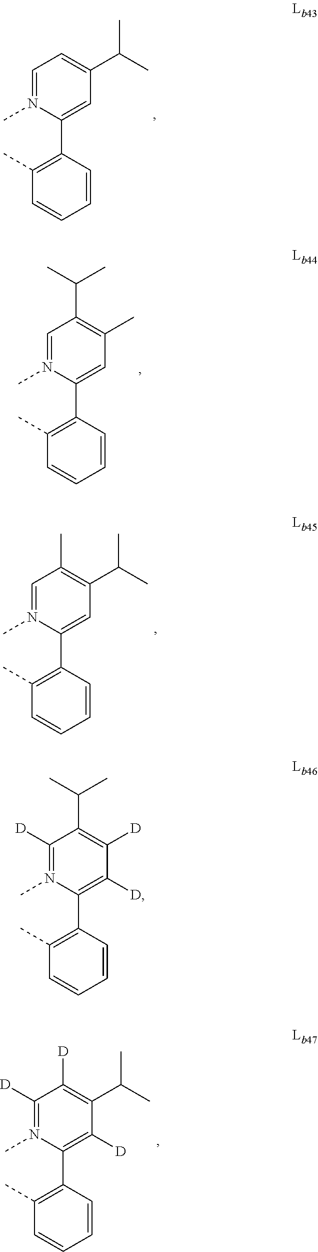

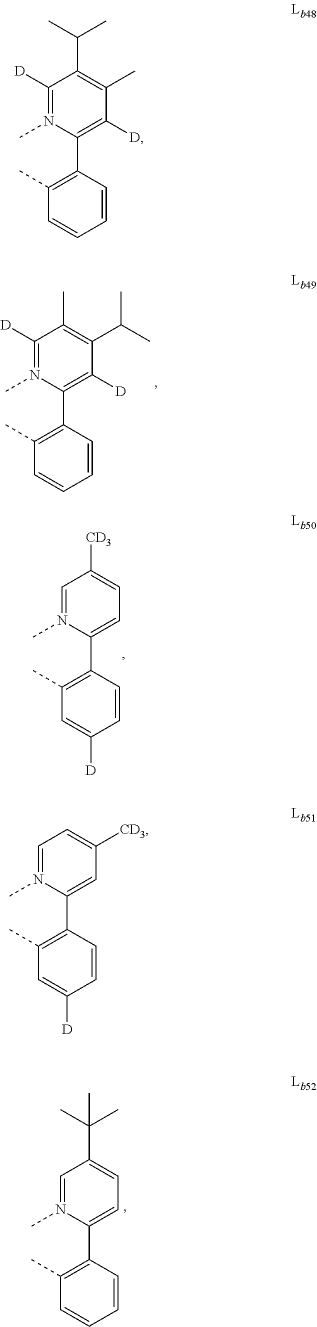

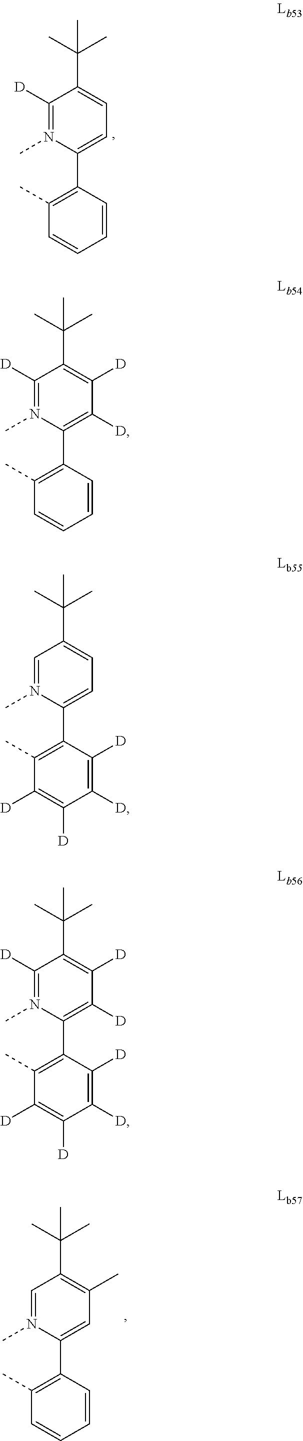

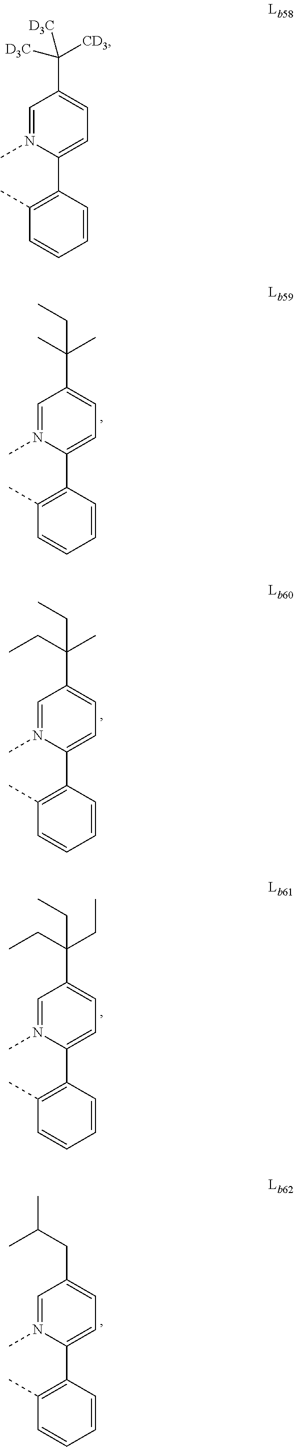

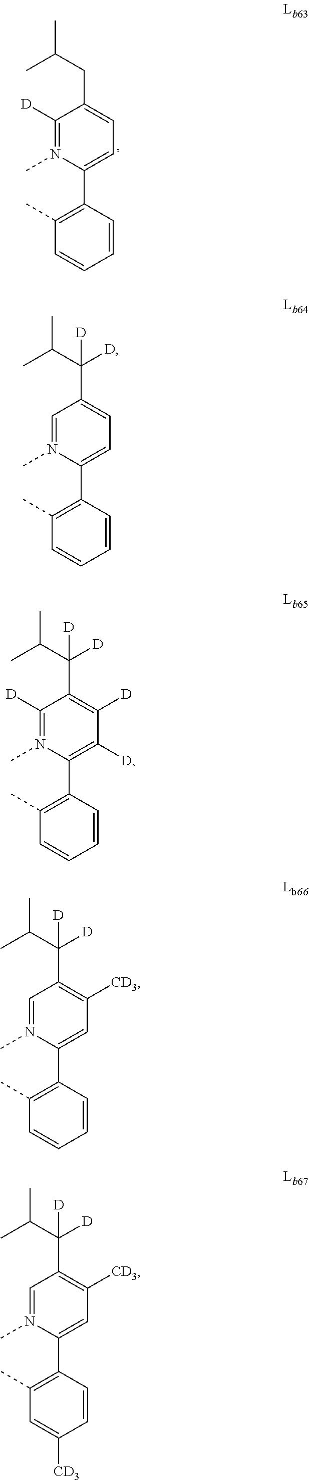

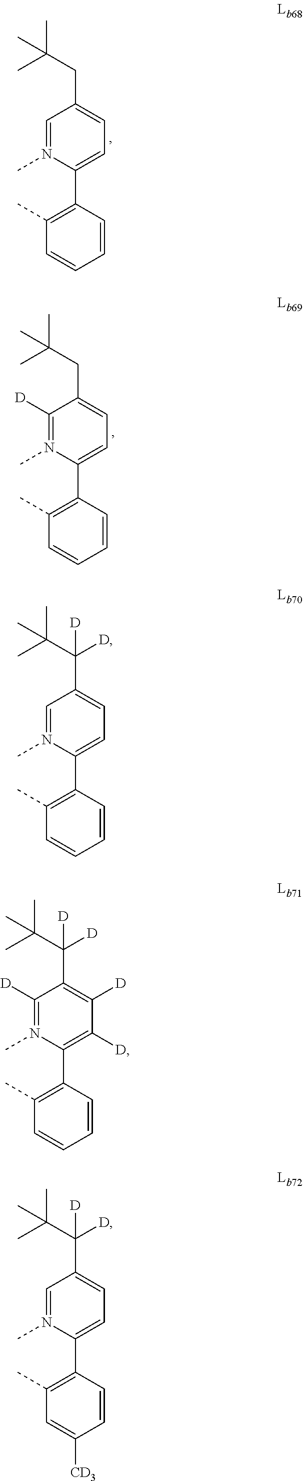

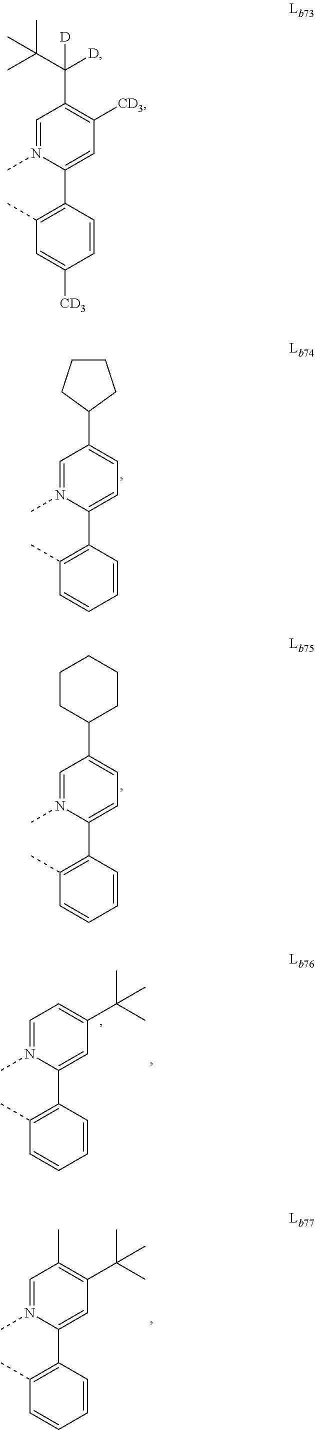

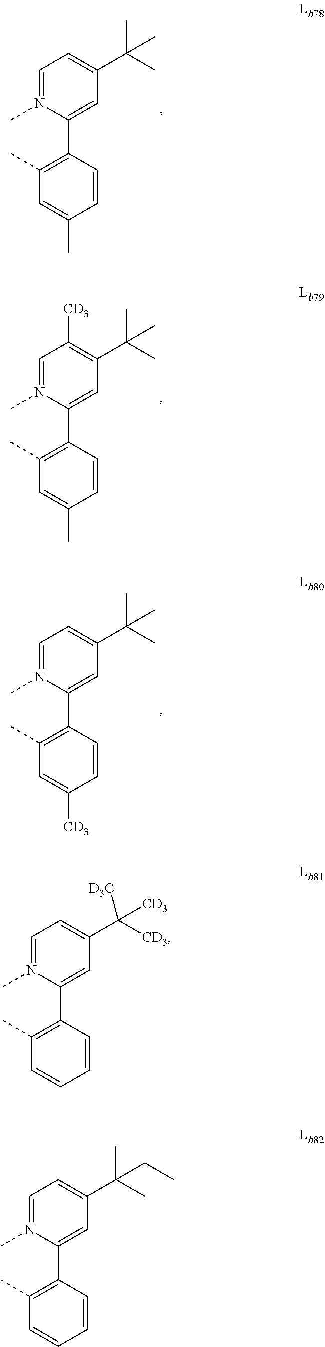

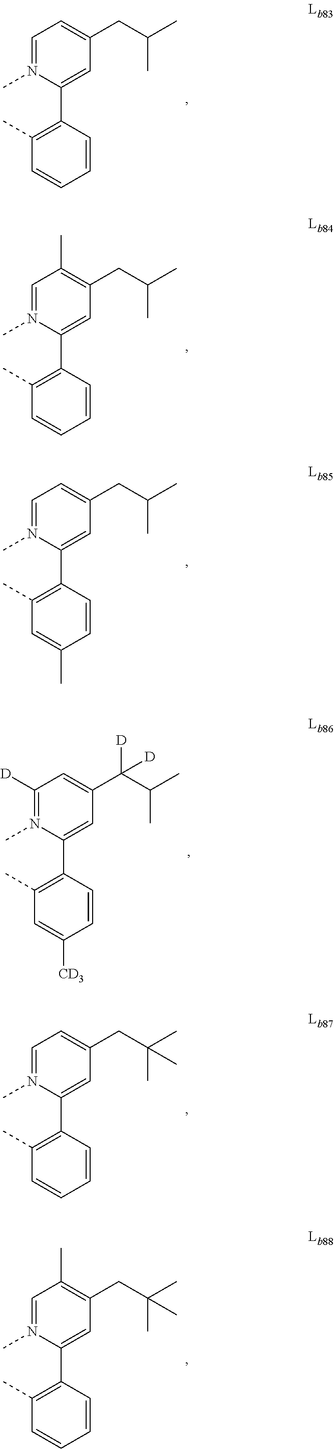

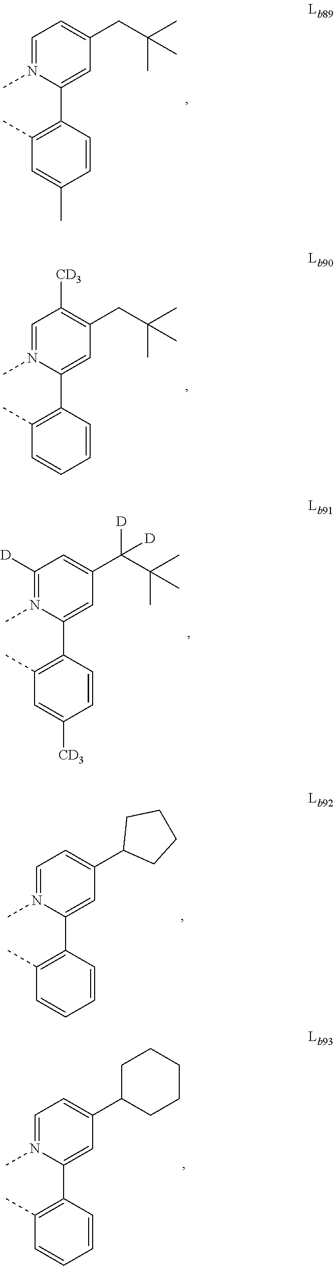

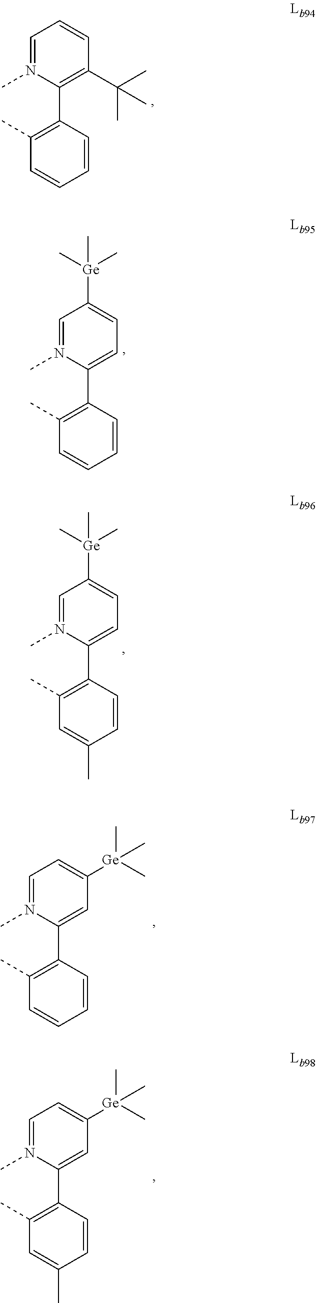

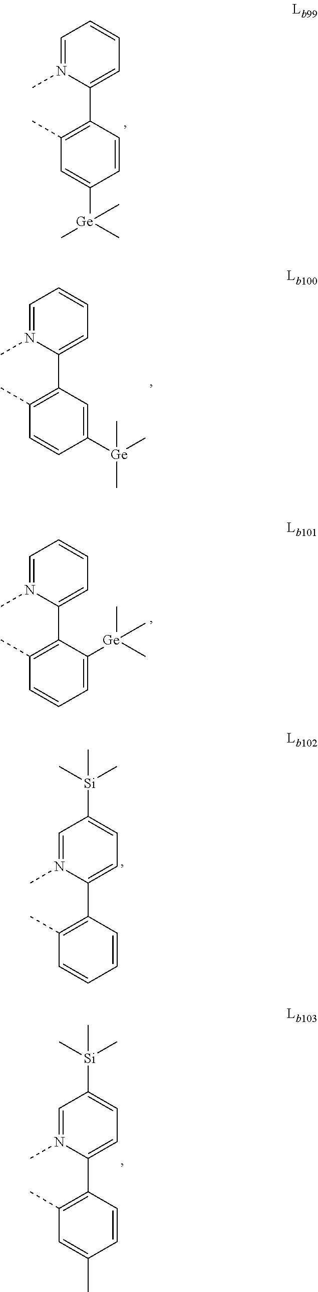

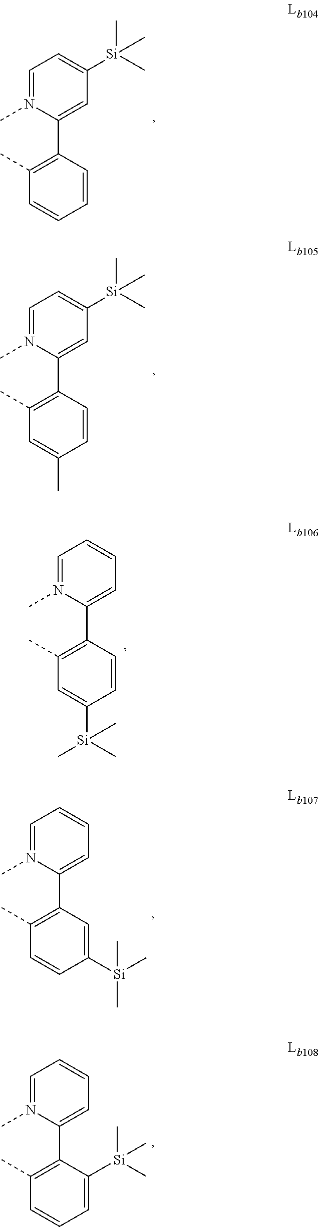

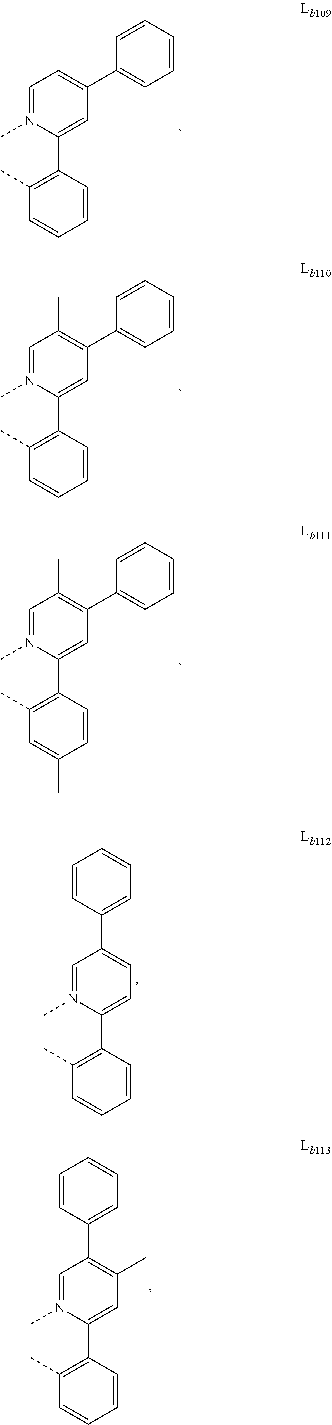

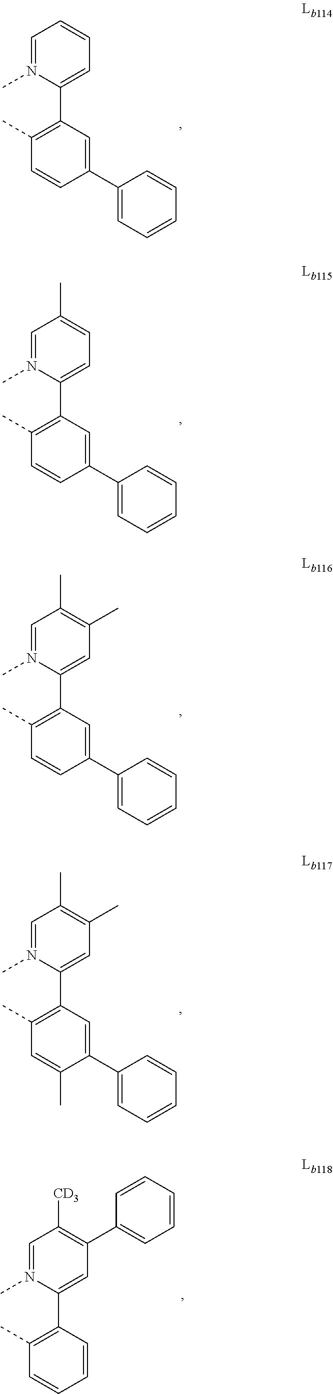

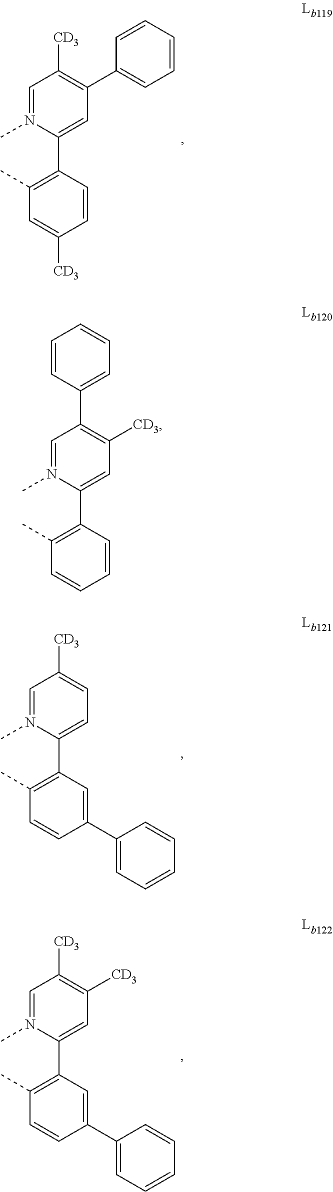

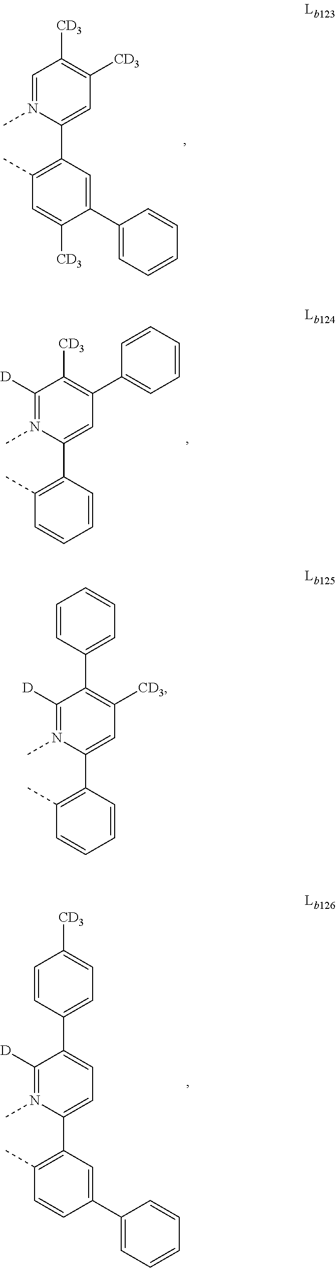

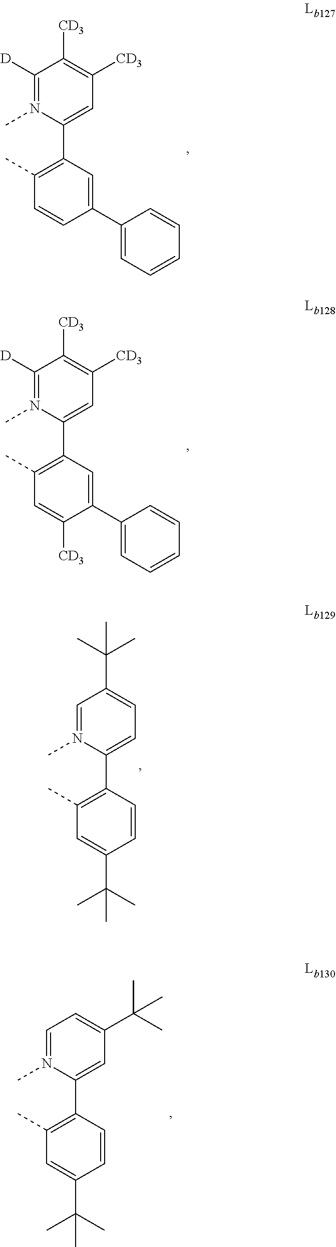

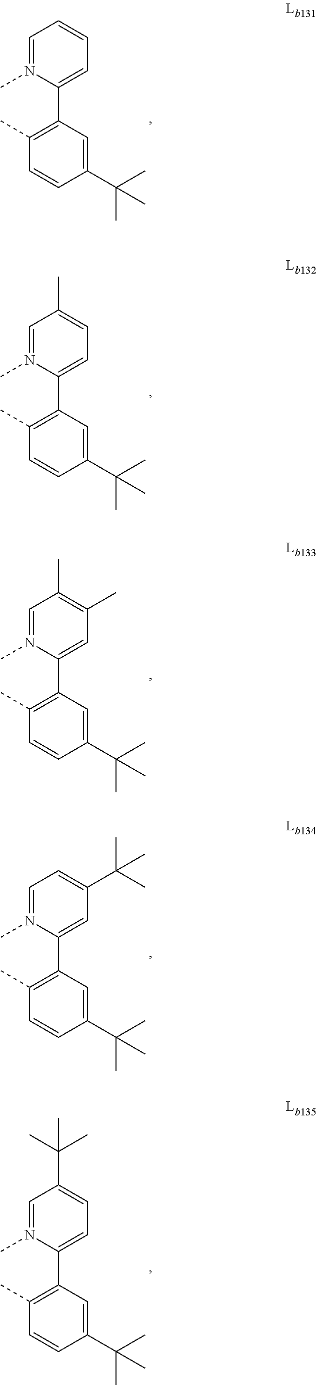

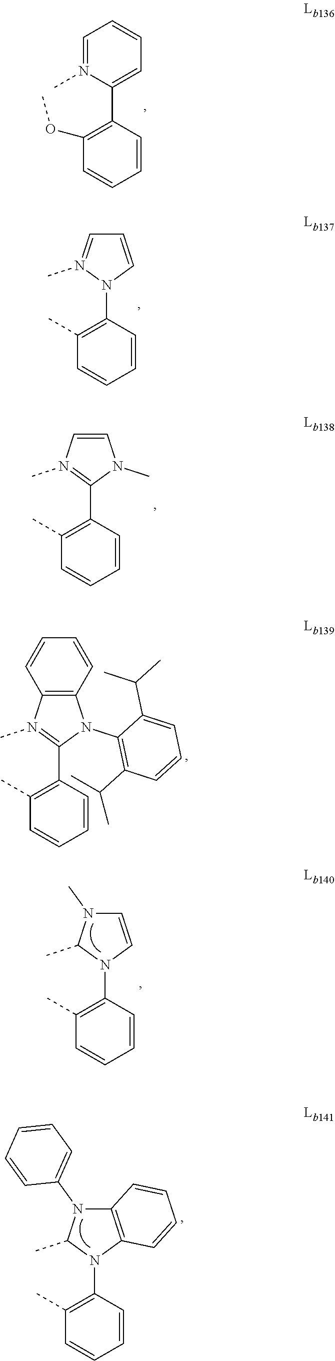

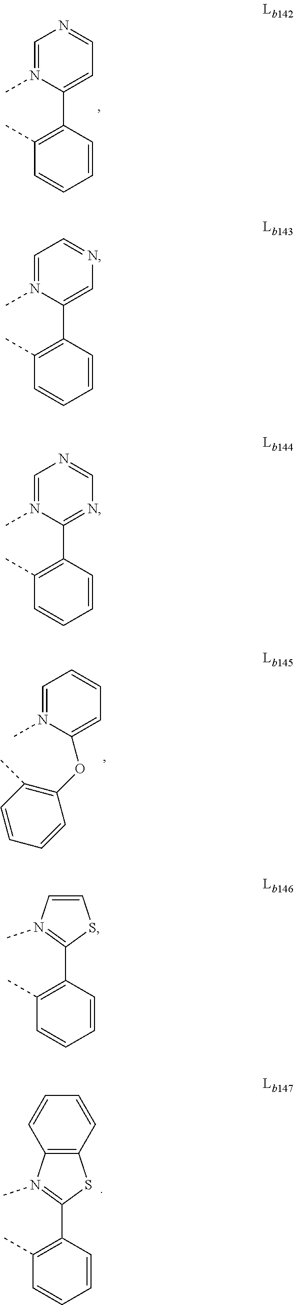

According to an embodiment of the present disclosure, hydrogens in the above L_{b1} to L_{b147} can be partially or fully deuterated.

According to an embodiment of the present disclosure, the metal complex is, at each occurrence identically or differently, selected from the group consisting of Metal Complex 1 to Metal Complex 61:

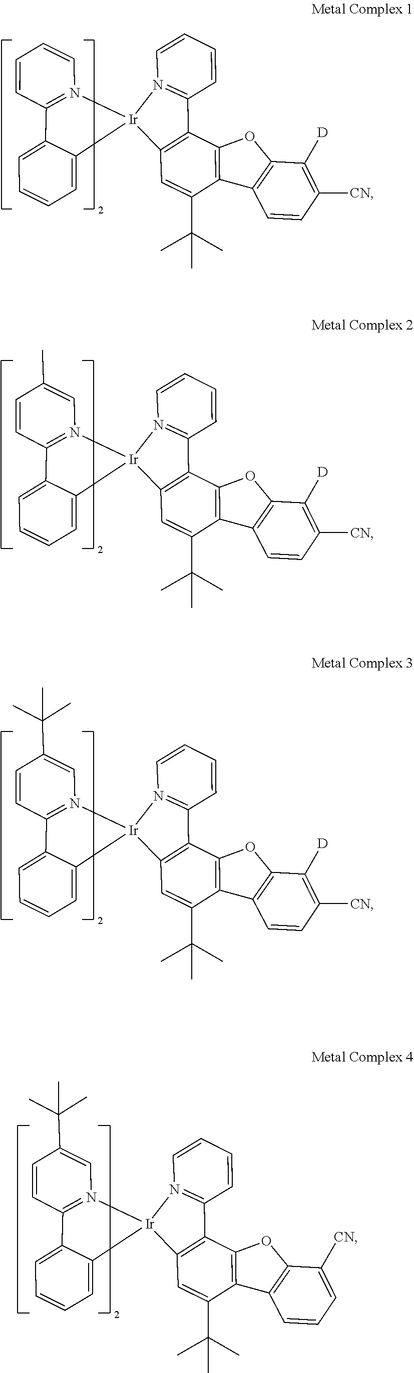

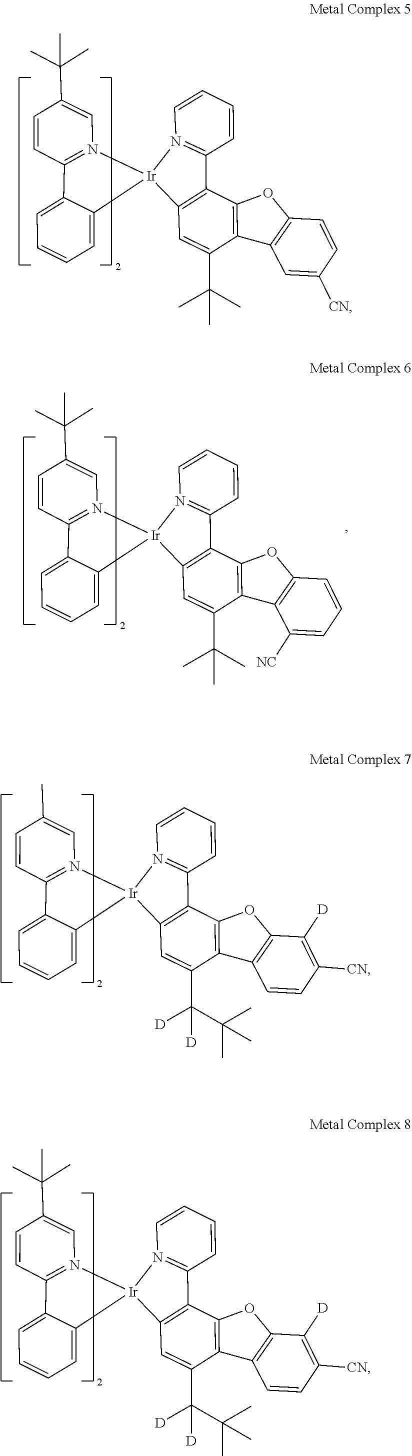

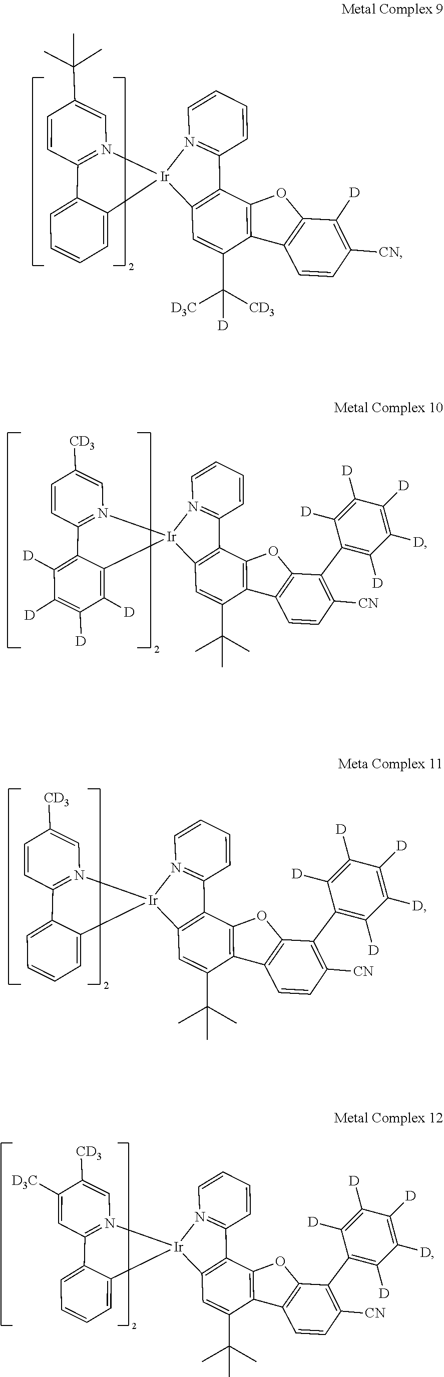

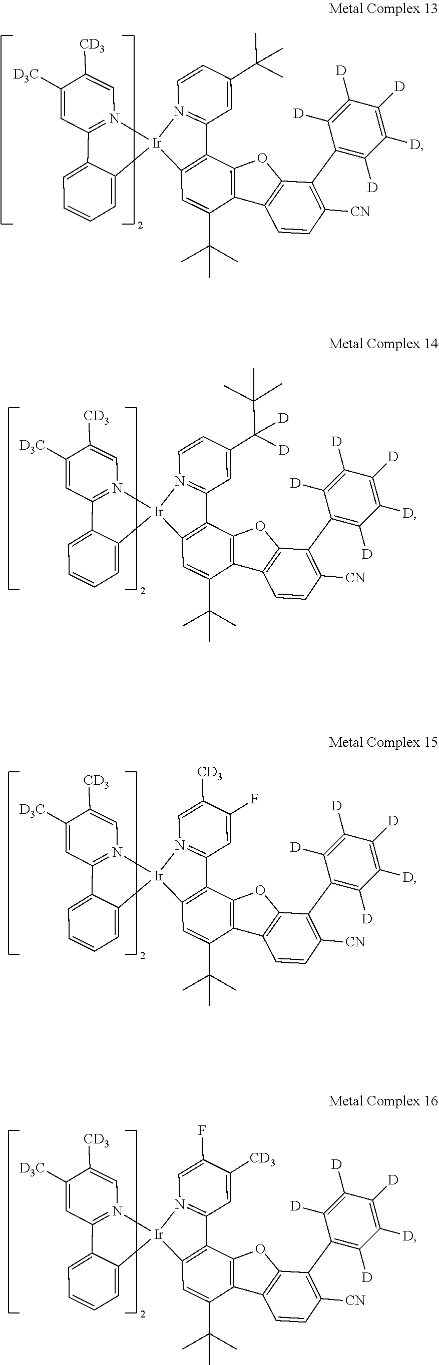

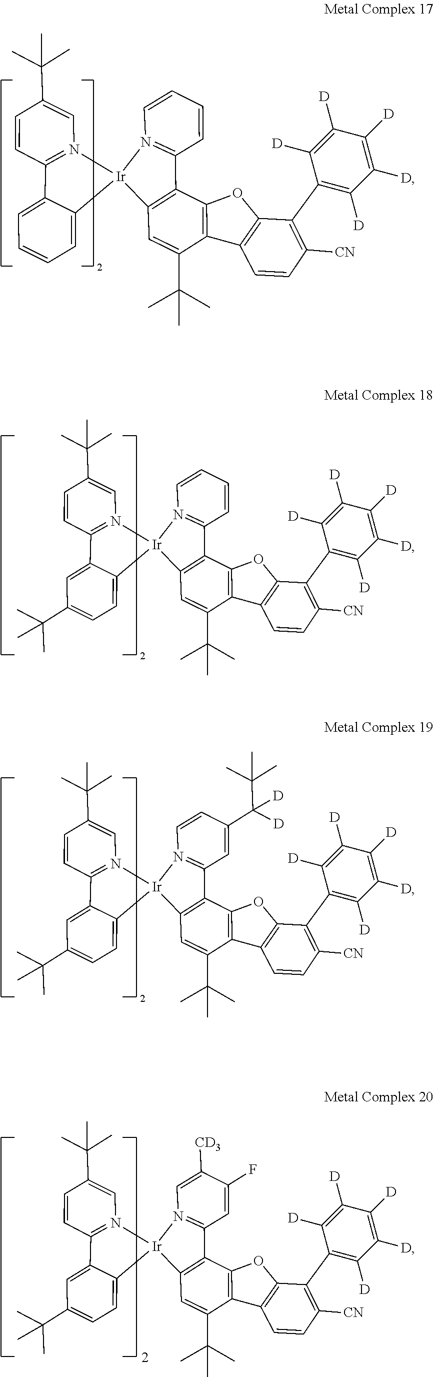

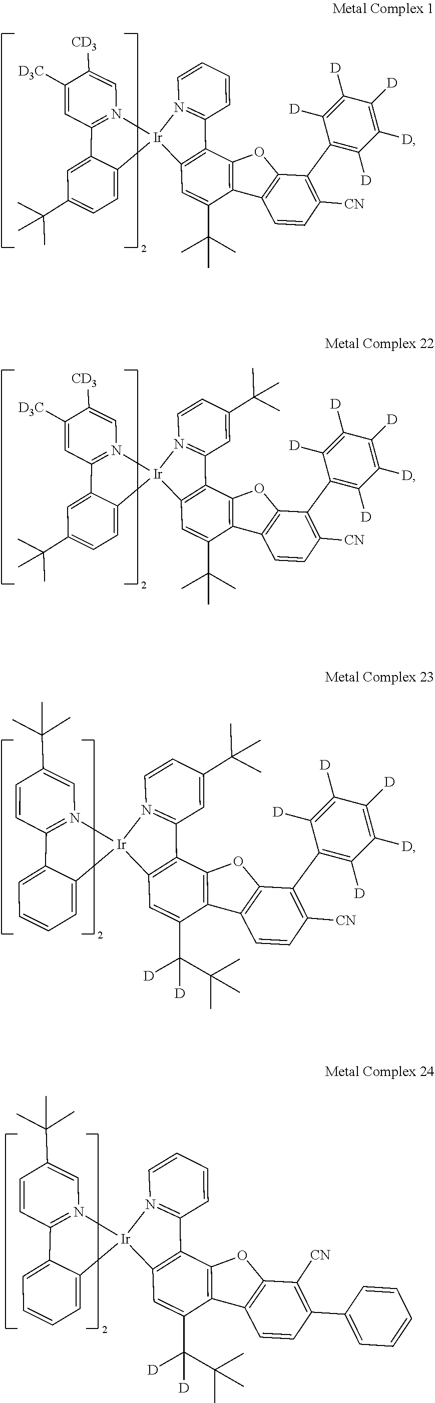

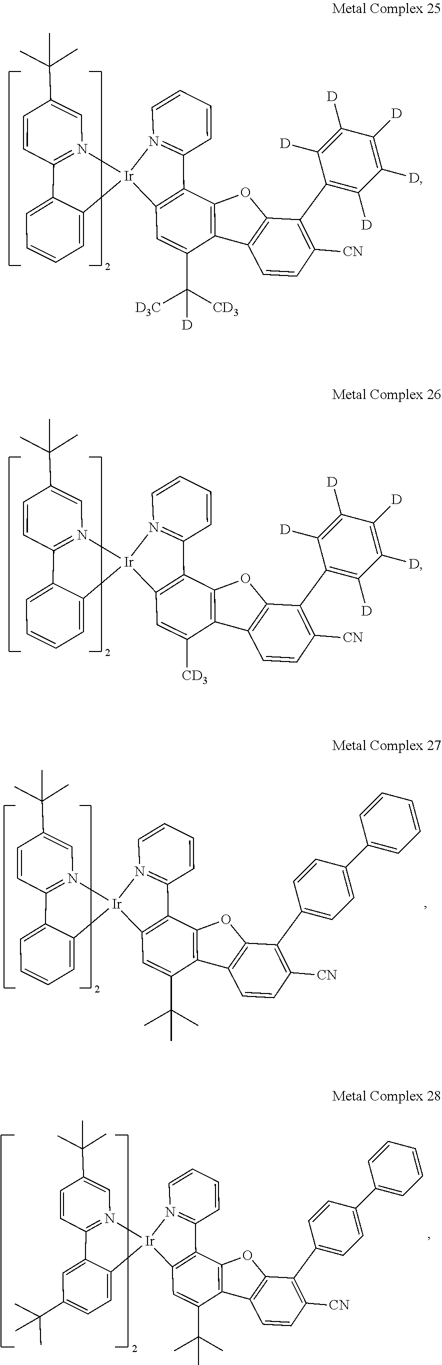

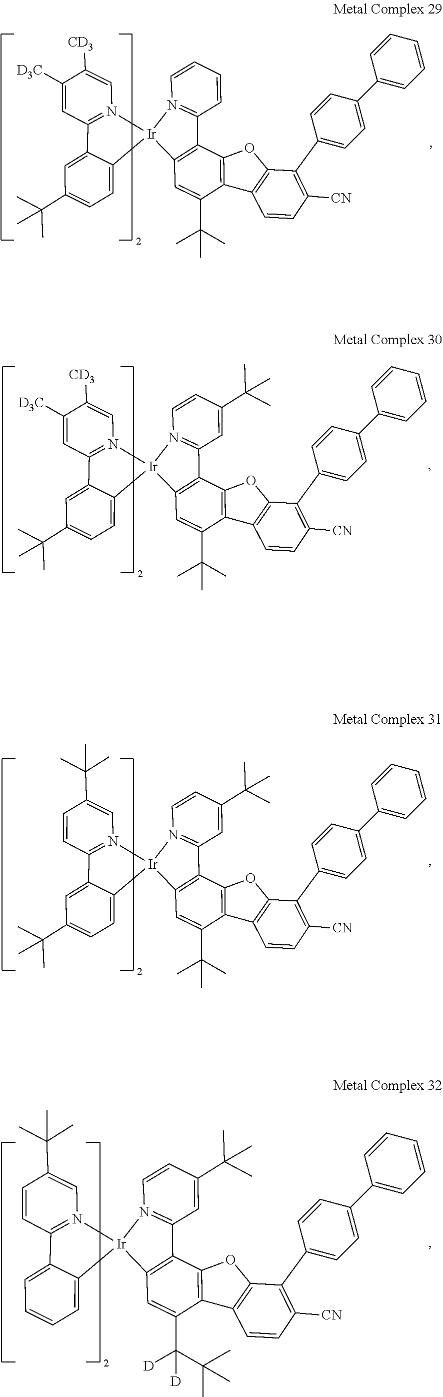

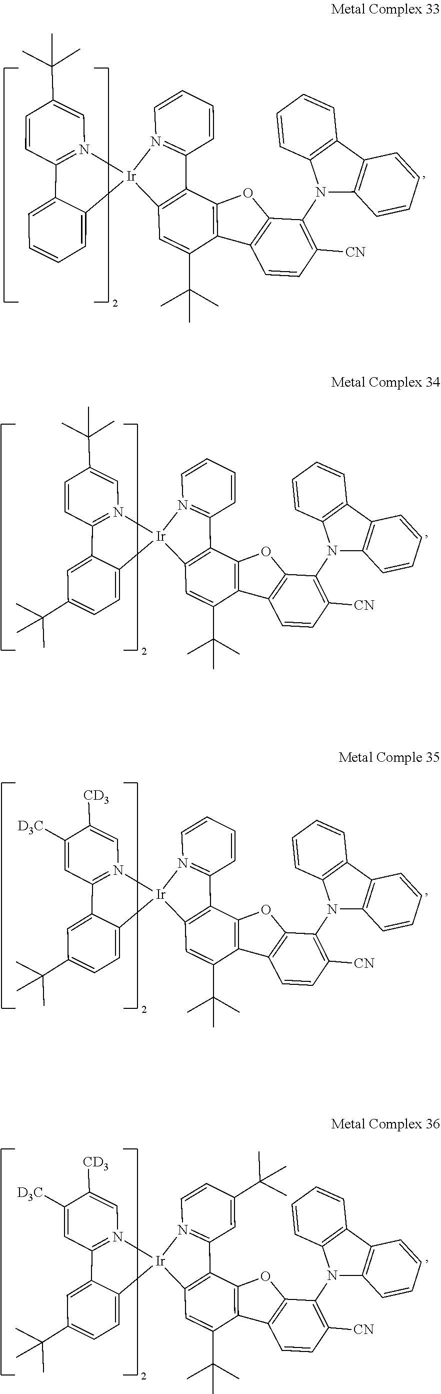

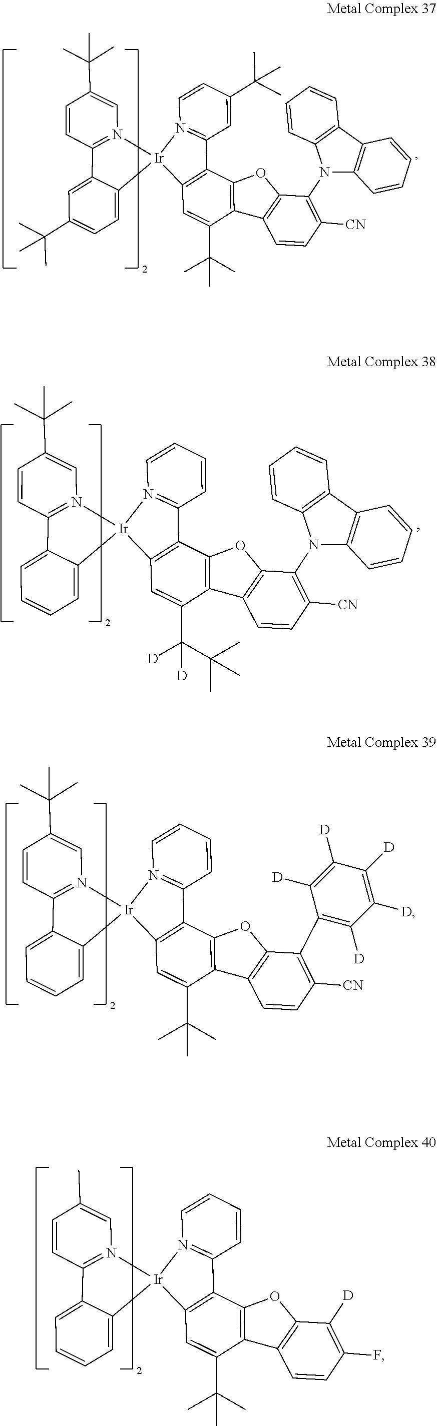

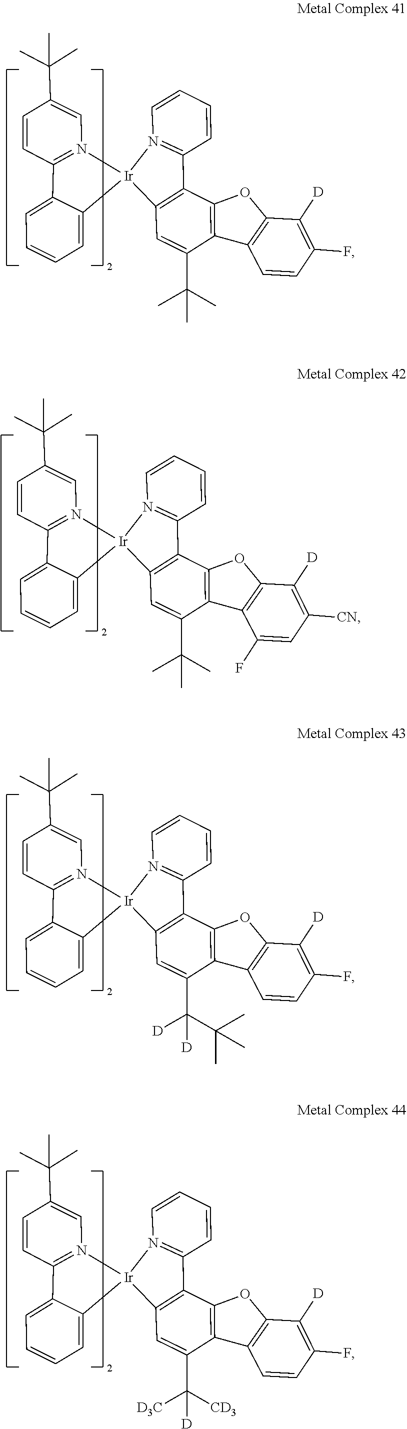

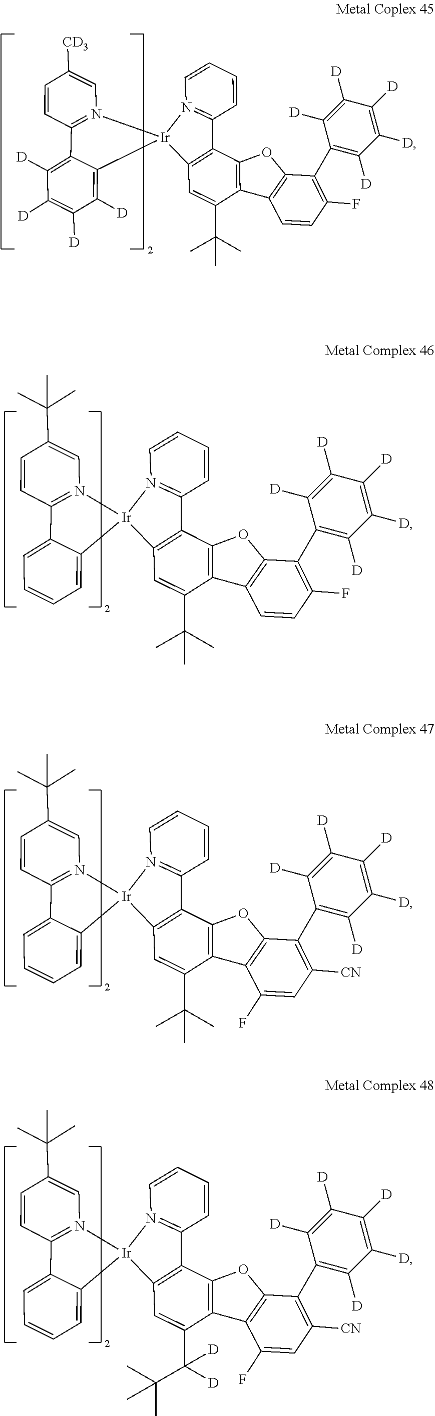

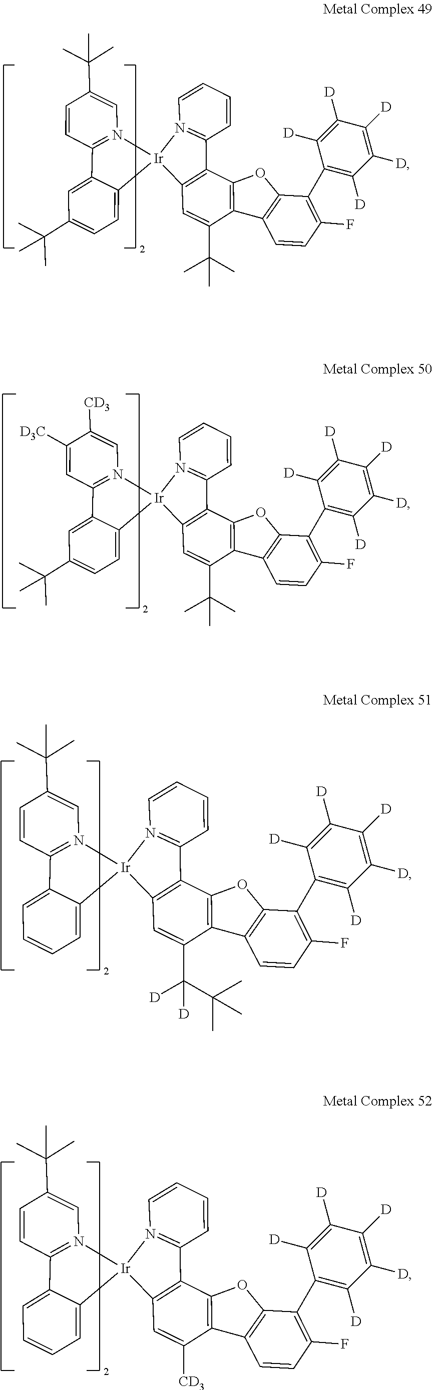

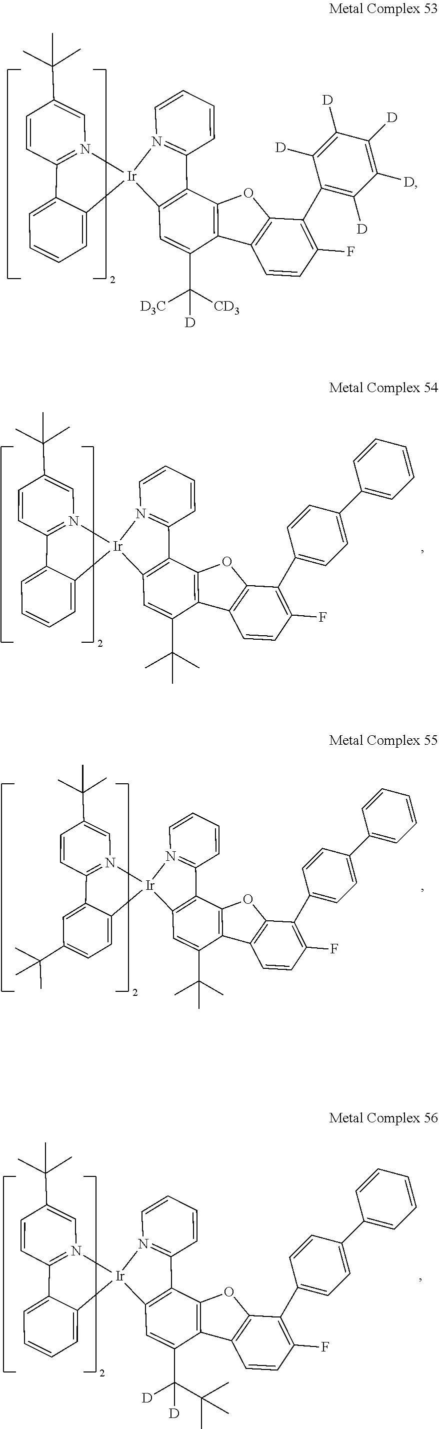

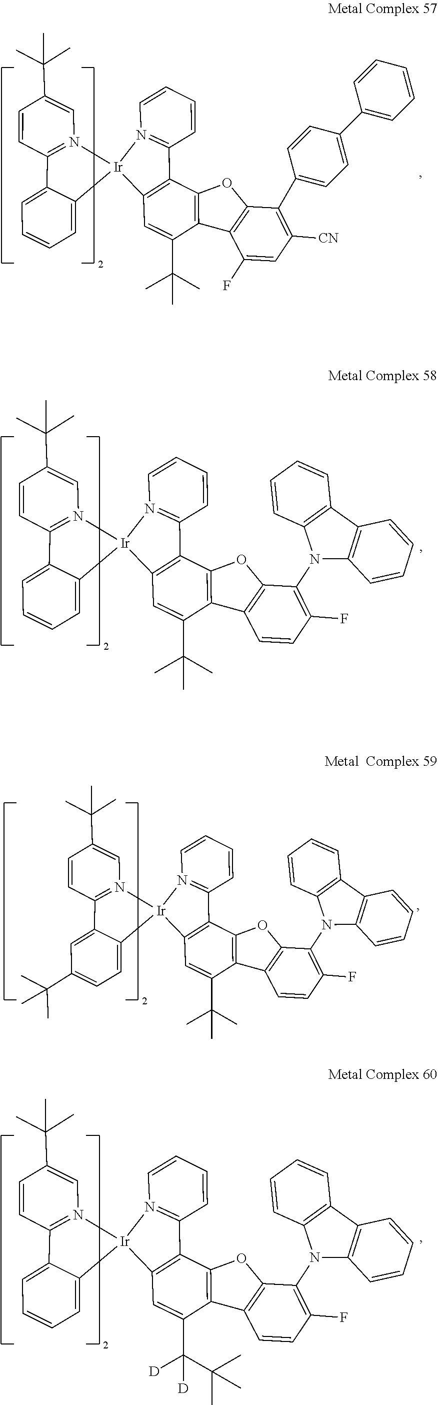

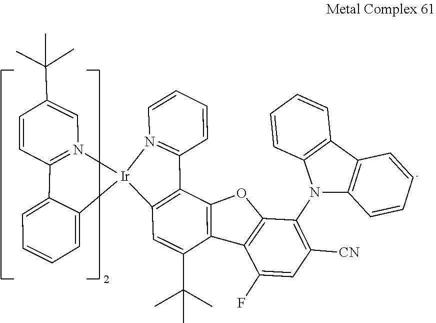

According to an embodiment of the present disclosure, hydrogens in Metal Complex 1 to Metal Complex 61 can be partially or fully deuterated.

According to another object of the present disclosure, a use of a metal complex in an optoelectronic device is further disclosed; for the metal complex, refer to any one of the preceding embodiments.

According to an embodiment of the present disclosure, the first compound has a structure represented by Formula 6:

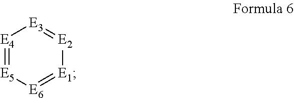

wherein
E₁ to E₆ are, at each occurrence identically or differently, selected from C, CR_{E}, or N, at least two of E₁ to E₆ are N, and at least one of E₁ to E₆ is C and joined to Formula A:

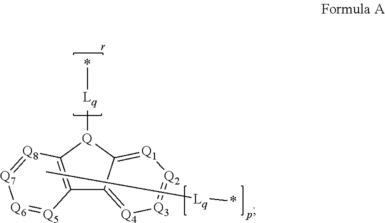

wherein
Q is, at each occurrence identically or differently, selected from the group consisting of O, S, Se, N, NR_{Q}, CR_{Q} R_{Q}, SiR_{Q} R_{Q}, GeR_{Q} R_{Q}, and R_{Q} C═CR_{Q}; when two R_{Q} are present at the same time, the two R_{Q} may be the same or different;
p is 0 or 1; r is 0 or 1;
when Q is selected from N, p is 0 and r is 1;
when Q is selected from the group consisting of O, S, Se, NR_{Q}, CR_{Q} R_{Q}, SiR_{Q} R_{Q}, GeR_{Q} R_{Q}, and R_{Q} C=CR_{Q}, p is 1 and r is 0;
L_{q} is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof;
Q₁ to Q₈ are, at each occurrence identically or differently, selected from C, CR_{q}, or N;
R_{E}, R_{Q}, and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfanyl group, a sulfonyl group, a phosphino group, and combinations thereof;
“*” represents a position where Formula A is joined to Formula 6; and
adjacent substituents R_{E}, R_{Q}, R_{q} can be optionally joined to form a ring.

Herein, the expression that “adjacent substituents R_{E}, R_{Q}, R_{q} can be optionally joined to form a ring” is intended to mean that any one or more of groups of adjacent substituents, such as two substituents R_{E}, two substituents R_{Q}, two substituents R_{q}, and two substituents R_{Q} and R_{q}, can be joined to form a ring. Obviously, it is also possible that none of these substituents are joined to form a ring.

According to an embodiment of the present disclosure, the first compound is selected from the group consisting of the following compounds:

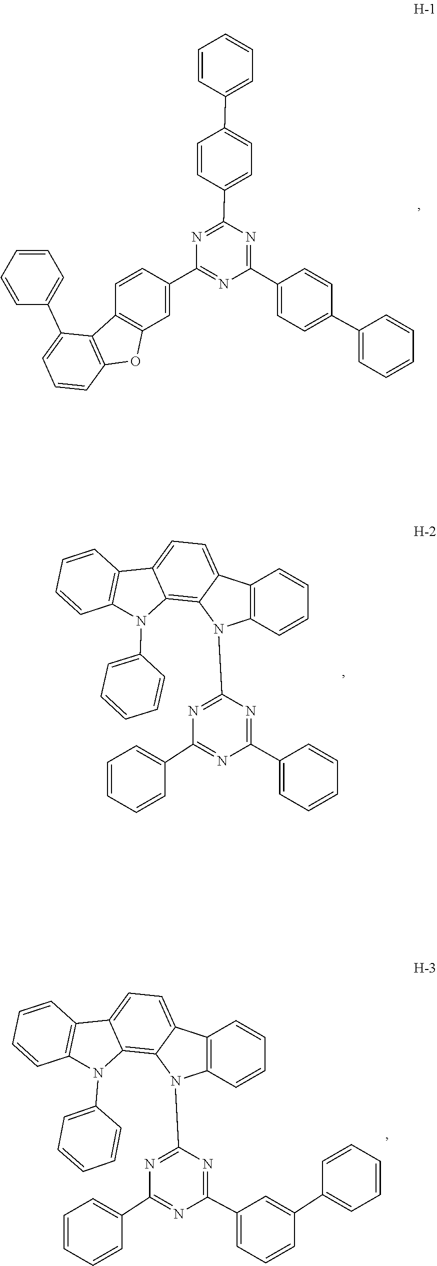 [SMILES: c1ccc(-c2ccc(-c3nc(-c4ccc(-c5ccccc5)cc4)nc(-c4ccc5c(c4)oc4cccc(-c6ccccc6)c45)n3)cc2)cc1 ; c1ccc(-c2nc(-c3ccccc3)nc(-n3c4ccccc4c4ccc5c6ccccc6n(-c6ccccc6)c5c43)n2)cc1 ; c1ccc(-c2cccc(-c3nc(-c4ccccc4)nc(-n4c5ccccc5c5ccc6c7ccccc7n(-c7ccccc7)c6c54)n3)c2)cc1]

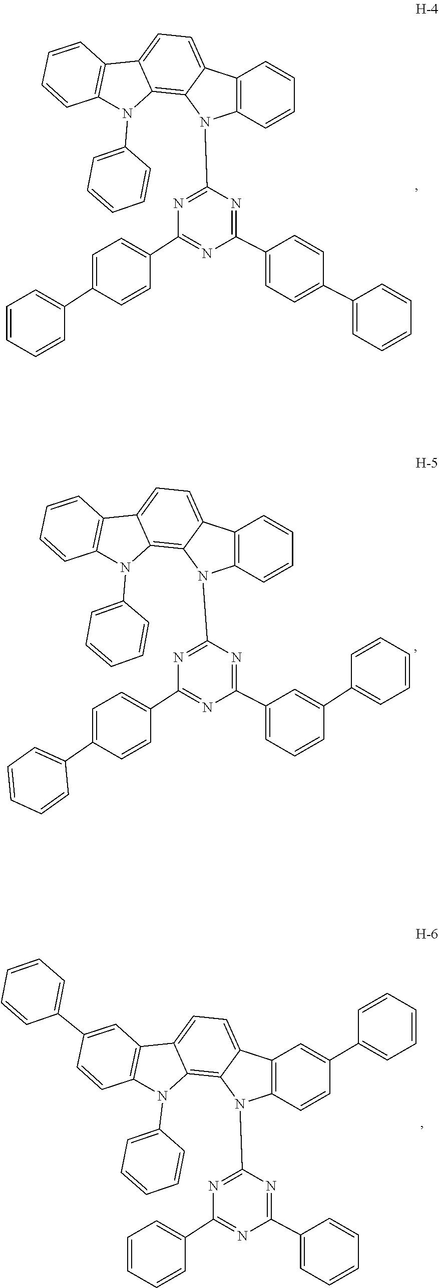 [SMILES: c1ccc(-c2ccc(-c3nc(-c4ccc(-c5ccccc5)cc4)nc(-n4c5ccccc5c5ccc6c7ccccc7n(-c7ccccc7)c6c54)n3)cc2)cc1 ; c1ccc(-c2ccc(-c3nc(-c4cccc(-c5ccccc5)c4)nc(-n4c5ccccc5c5ccc6c7ccccc7n(-c7ccccc7)c6c54)n3)cc2)cc1 ; c1ccc(-c2ccc3c(c2)c2ccc4c5cc(-c6ccccc6)ccc5n(-c5nc(-c6ccccc6)nc(-c6ccccc6)n5)c4c2n3-c2ccccc2)cc1]

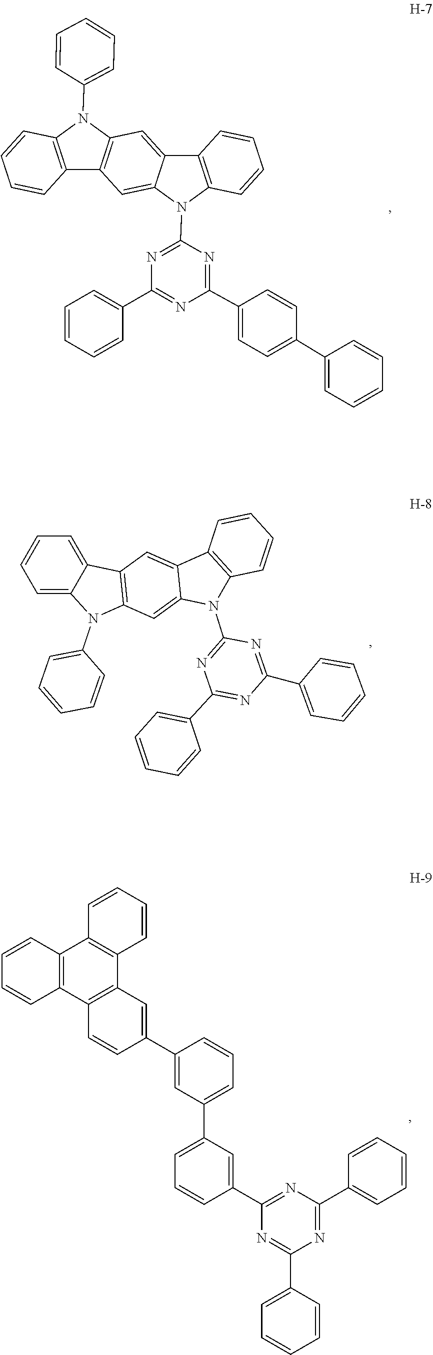 [SMILES: c1ccc(-c2ccc(-c3nc(-c4ccccc4)nc(-n4c5ccccc5c5cc6c(cc54)c4ccccc4n6-c4ccccc4)n3)cc2)cc1 ; c1ccc(-c2nc(-c3ccccc3)nc(-n3c4ccccc4c4cc5c6ccccc6n(-c6ccccc6)c5cc43)n2)cc1 ; c1ccc(-c2nc(-c3ccccc3)nc(-c3cccc(-c4cccc(-c5ccc6c7ccccc7c7ccccc7c6c5)c4)c3)n2)cc1]

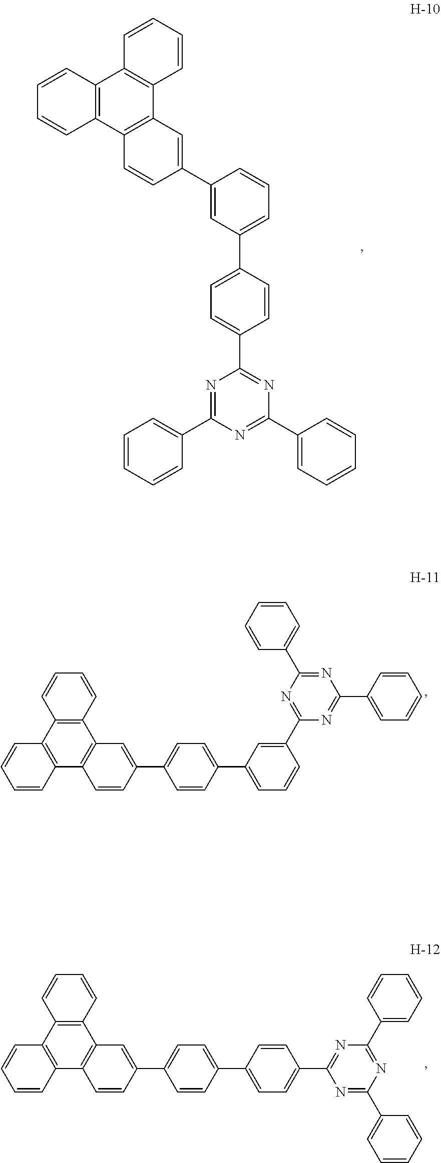 [SMILES: c1ccc(-c2nc(-c3ccccc3)nc(-c3ccc(-c4cccc(-c5ccc6c7ccccc7c7ccccc7c6c5)c4)cc3)n2)cc1 ; c1ccc(-c2nc(-c3ccccc3)nc(-c3cccc(-c4ccc(-c5ccc6c7ccccc7c7ccccc7c6c5)cc4)c3)n2)cc1 ; c1ccc(-c2nc(-c3ccccc3)nc(-c3ccc(-c4ccc(-c5ccc6c7ccccc7c7ccccc7c6c5)cc4)cc3)n2)cc1]

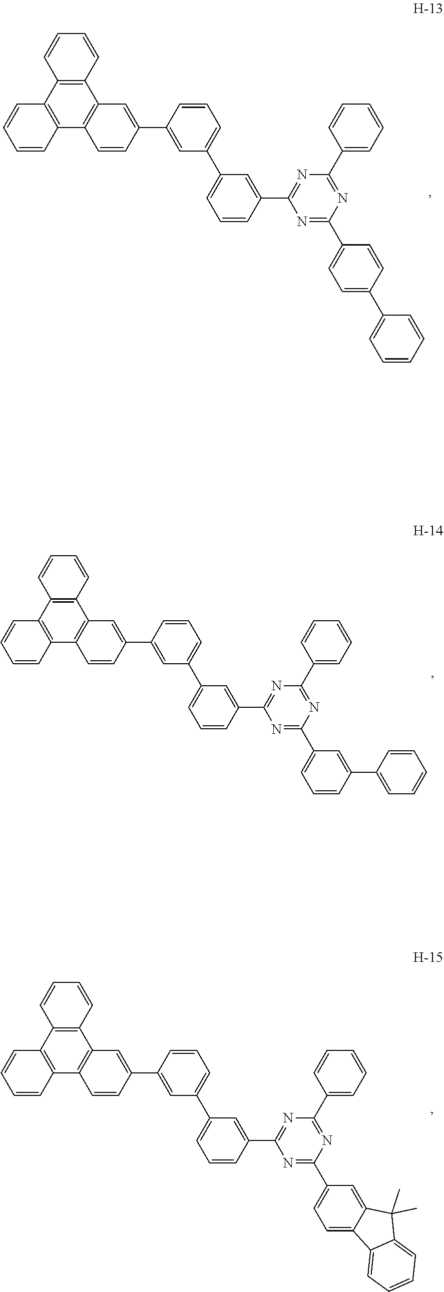 [SMILES: c1ccc(-c2ccc(-c3nc(-c4ccccc4)nc(-c4cccc(-c5cccc(-c6ccc7c8ccccc8c8ccccc8c7c6)c5)c4)n3)cc2)cc1 ; c1ccc(-c2cccc(-c3nc(-c4ccccc4)nc(-c4cccc(-c5cccc(-c6ccc7c8ccccc8c8ccccc8c7c6)c5)c4)n3)c2)cc1 ; CC1(C)c2ccccc2-c2ccc(-c3nc(-c4ccccc4)nc(-c4cccc(-c5cccc(-c6ccc7c8ccccc8c8ccccc8c7c6)c5)c4)n3)cc21]

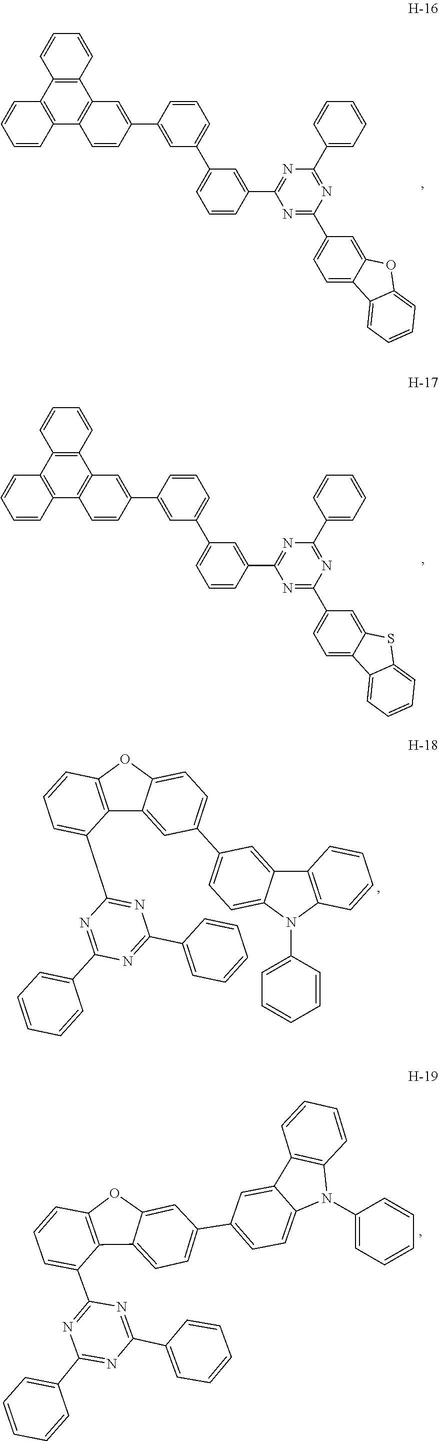 [SMILES: c1ccc(-c2nc(-c3cccc(-c4cccc(-c5ccc6c7ccccc7c7ccccc7c6c5)c4)c3)nc(-c3ccc4c(c3)oc3ccccc34)n2)cc1 ; c1ccc(-c2nc(-c3cccc(-c4cccc(-c5ccc6c7ccccc7c7ccccc7c6c5)c4)c3)nc(-c3ccc4c(c3)sc3ccccc34)n2)cc1 ; c1ccc(-c2nc(-c3ccccc3)nc(-c3cccc4oc5ccc(-c6ccc7c(c6)c6ccccc6n7-c6ccccc6)cc5c34)n2)cc1 ; c1ccc(-c2nc(-c3ccccc3)nc(-c3cccc4oc5cc(-c6ccc7c(c6)c6ccccc6n7-c6ccccc6)ccc5c34)n2)cc1]

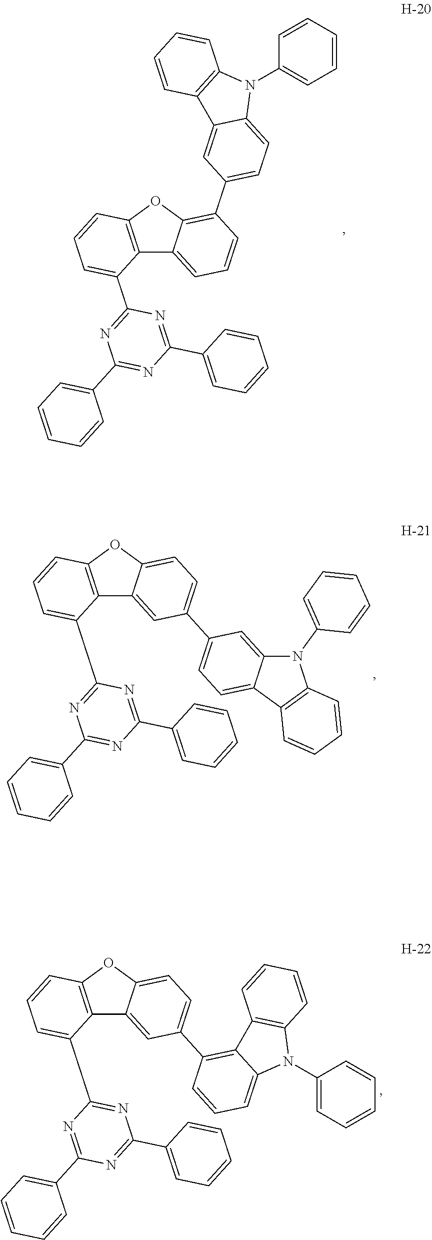 [SMILES: c1ccc(-c2nc(-c3ccccc3)nc(-c3cccc4oc5c(-c6ccc7c(c6)c6ccccc6n7-c6ccccc6)cccc5c34)n2)cc1 ; c1ccc(-c2nc(-c3ccccc3)nc(-c3cccc4oc5ccc(-c6ccc7c8ccccc8n(-c8ccccc8)c7c6)cc5c34)n2)cc1 ; c1ccc(-c2nc(-c3ccccc3)nc(-c3cccc4oc5ccc(-c6cccc7c6c6ccccc6n7-c6ccccc6)cc5c34)n2)cc1]

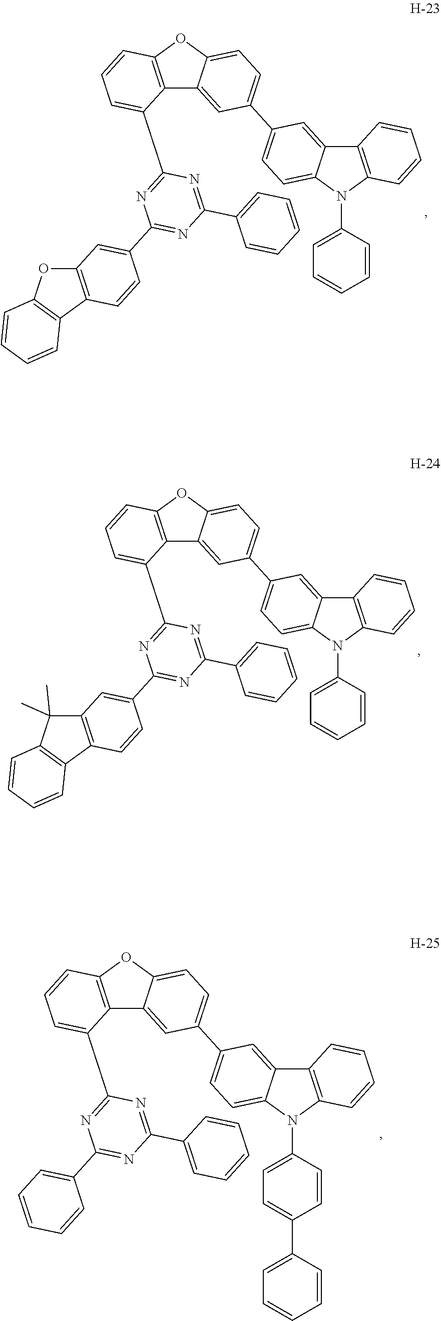 [SMILES: c1ccc(-c2nc(-c3ccc4c(c3)oc3ccccc34)nc(-c3cccc4oc5ccc(-c6ccc7c(c6)c6ccccc6n7-c6ccccc6)cc5c34)n2)cc1 ; CC1(C)c2ccccc2-c2ccc(-c3nc(-c4ccccc4)nc(-c4cccc5oc6ccc(-c7ccc8c(c7)c7ccccc7n8-c7ccccc7)cc6c45)n3)cc21 ; c1ccc(-c2ccc(-n3c4ccccc4c4cc(-c5ccc6oc7cccc(-c8nc(-c9ccccc9)nc(-c9ccccc9)n8)c7c6c5)ccc43)cc2)cc1]

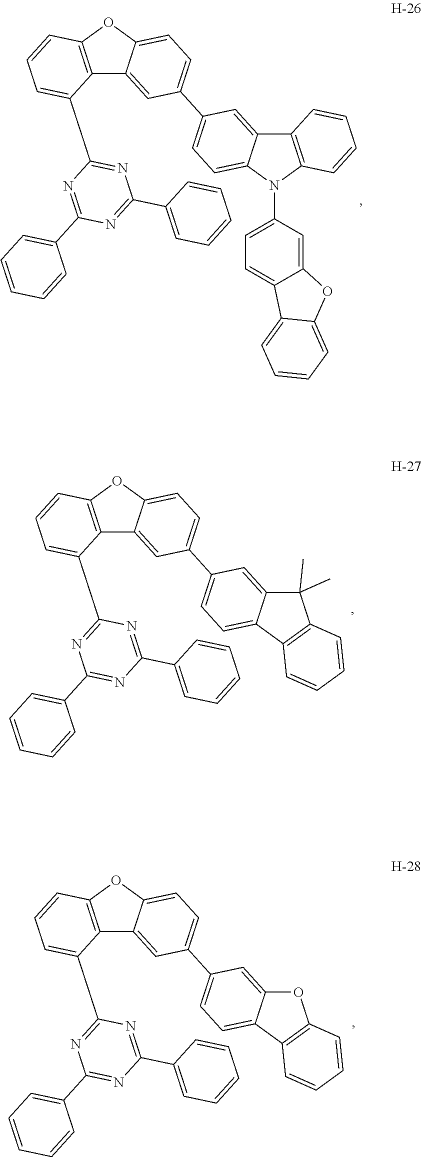 [SMILES: c1ccc(-c2nc(-c3ccccc3)nc(-c3cccc4oc5ccc(-c6ccc7c(c6)c6ccccc6n7-c6ccc7c(c6)oc6ccccc67)cc5c34)n2)cc1 ; CC1(C)c2ccccc2-c2ccc(-c3ccc4oc5cccc(-c6nc(-c7ccccc7)nc(-c7ccccc7)n6)c5c4c3)cc21 ; c1ccc(-c2nc(-c3ccccc3)nc(-c3cccc4oc5ccc(-c6ccc7c(c6)oc6ccccc67)cc5c34)n2)cc1]

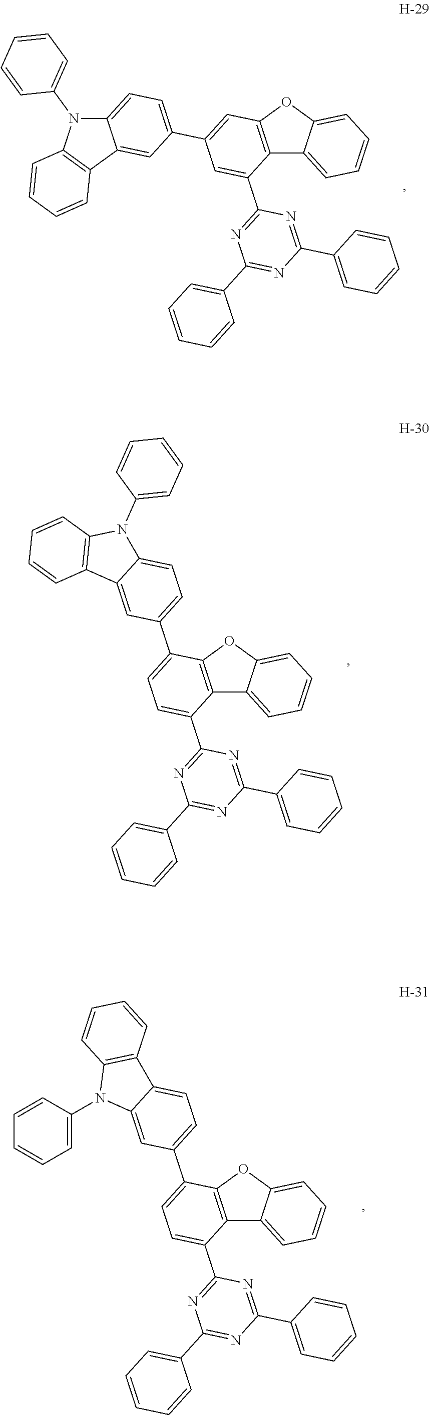 [SMILES: c1ccc(-c2nc(-c3ccccc3)nc(-c3cc(-c4ccc5c(c4)c4ccccc4n5-c4ccccc4)cc4oc5ccccc5c34)n2)cc1 ; c1ccc(-c2nc(-c3ccccc3)nc(-c3ccc(-c4ccc5c(c4)c4ccccc4n5-c4ccccc4)c4oc5ccccc5c34)n2)cc1 ; c1ccc(-c2nc(-c3ccccc3)nc(-c3ccc(-c4ccc5c6ccccc6n(-c6ccccc6)c5c4)c4oc5ccccc5c34)n2)cc1]

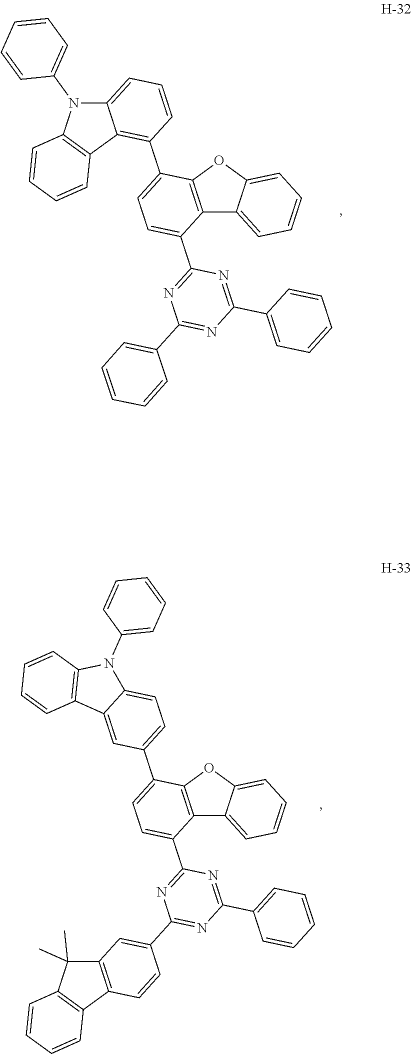 [SMILES: c1ccc(-c2nc(-c3ccccc3)nc(-c3ccc(-c4cccc5c4c4ccccc4n5-c4ccccc4)c4oc5ccccc5c34)n2)cc1 ; CC1(C)c2ccccc2-c2ccc(-c3nc(-c4ccccc4)nc(-c4ccc(-c5ccc6c(c5)c5ccccc5n6-c5ccccc5)c5oc6ccccc6c45)n3)cc21]

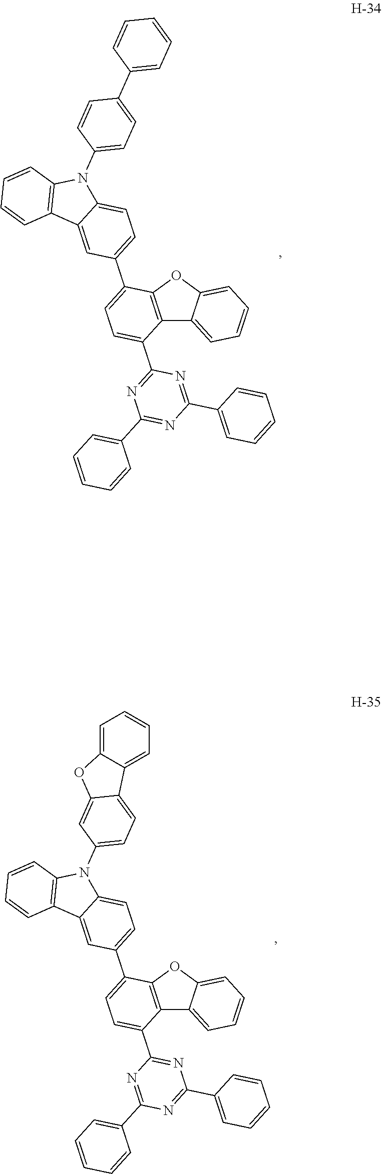 [SMILES: c1ccc(-c2ccc(-n3c4ccccc4c4cc(-c5ccc(-c6nc(-c7ccccc7)nc(-c7ccccc7)n6)c6c5oc5ccccc56)ccc43)cc2)cc1 ; c1ccc(-c2nc(-c3ccccc3)nc(-c3ccc(-c4ccc5c(c4)c4ccccc4n5-c4ccc5c(c4)oc4ccccc45)c4oc5ccccc5c34)n2)cc1]

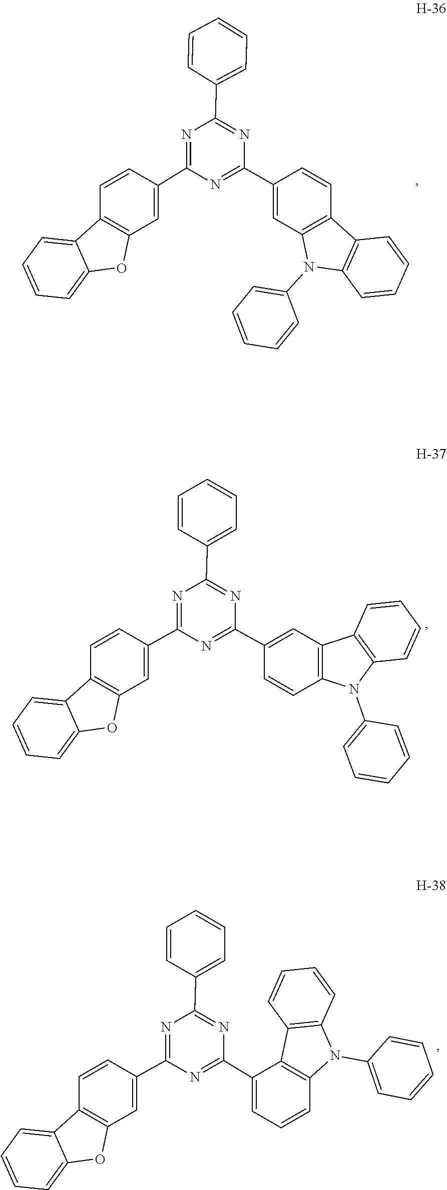 [SMILES: c1ccc(-c2nc(-c3ccc4c(c3)oc3ccccc34)nc(-c3ccc4c5ccccc5n(-c5ccccc5)c4c3)n2)cc1 ; c1ccc(-c2nc(-c3ccc4c(c3)oc3ccccc34)nc(-c3ccc4c(c3)c3ccccc3n4-c3ccccc3)n2)cc1 ; c1ccc(-c2nc(-c3ccc4c(c3)oc3ccccc34)nc(-c3cccc4c3c3ccccc3n4-c3ccccc3)n2)cc1]

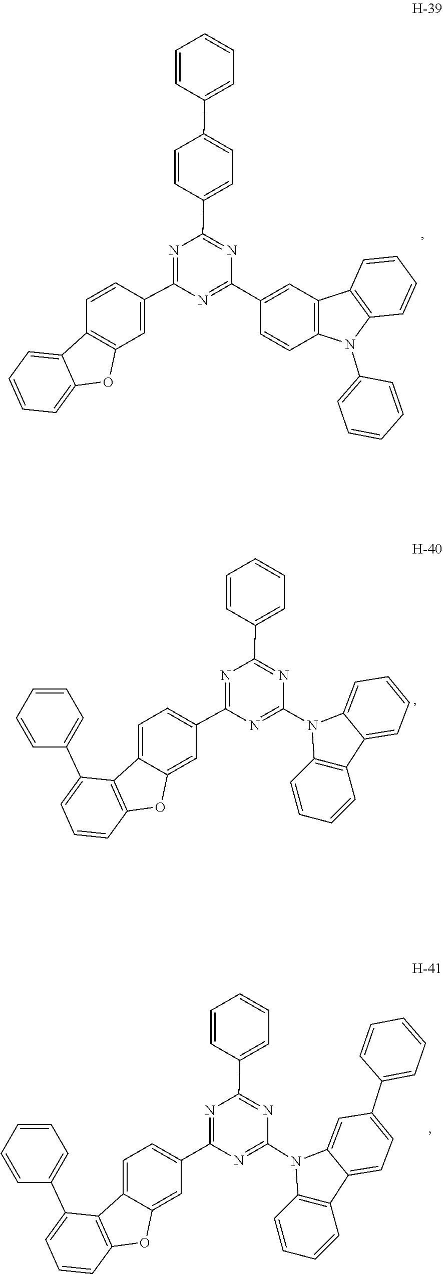 [SMILES: c1ccc(-c2ccc(-c3nc(-c4ccc5c(c4)oc4ccccc45)nc(-c4ccc5c(c4)c4ccccc4n5-c4ccccc4)n3)cc2)cc1 ; c1ccc(-c2nc(-c3ccc4c(c3)oc3cccc(-c5ccccc5)c34)nc(-n3c4ccccc4c4ccccc43)n2)cc1 ; c1ccc(-c2ccc3c4ccccc4n(-c4nc(-c5ccccc5)nc(-c5ccc6c(c5)oc5cccc(-c7ccccc7)c56)n4)c3c2)cc1]

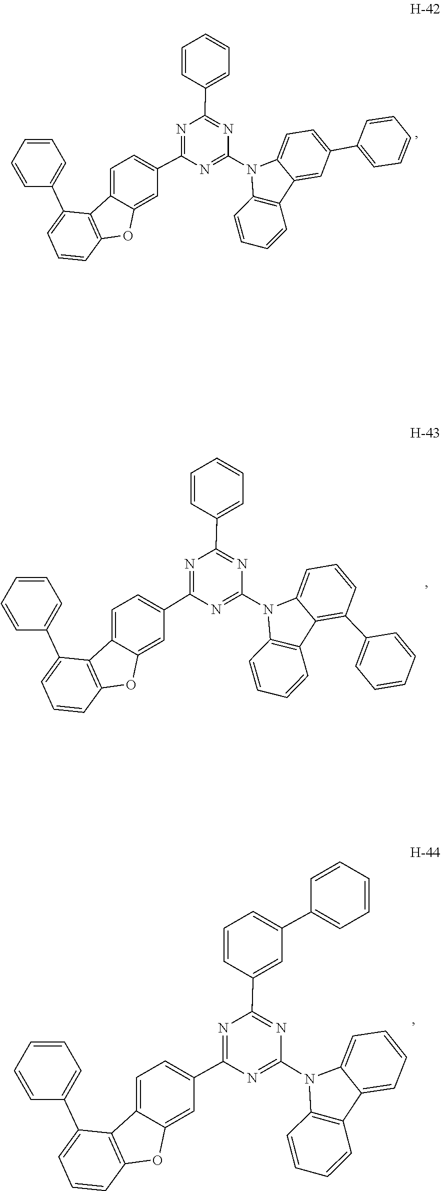 [SMILES: c1ccc(-c2ccc3c(c2)c2ccccc2n3-c2nc(-c3ccccc3)nc(-c3ccc4c(c3)oc3cccc(-c5ccccc5)c34)n2)cc1 ; c1ccc(-c2nc(-c3ccc4c(c3)oc3cccc(-c5ccccc5)c34)nc(-n3c4ccccc4c4c(-c5ccccc5)cccc43)n2)cc1 ; c1ccc(-c2cccc(-c3nc(-c4ccc5c(c4)oc4cccc(-c6ccccc6)c45)nc(-n4c5ccccc5c5ccccc54)n3)c2)cc1]

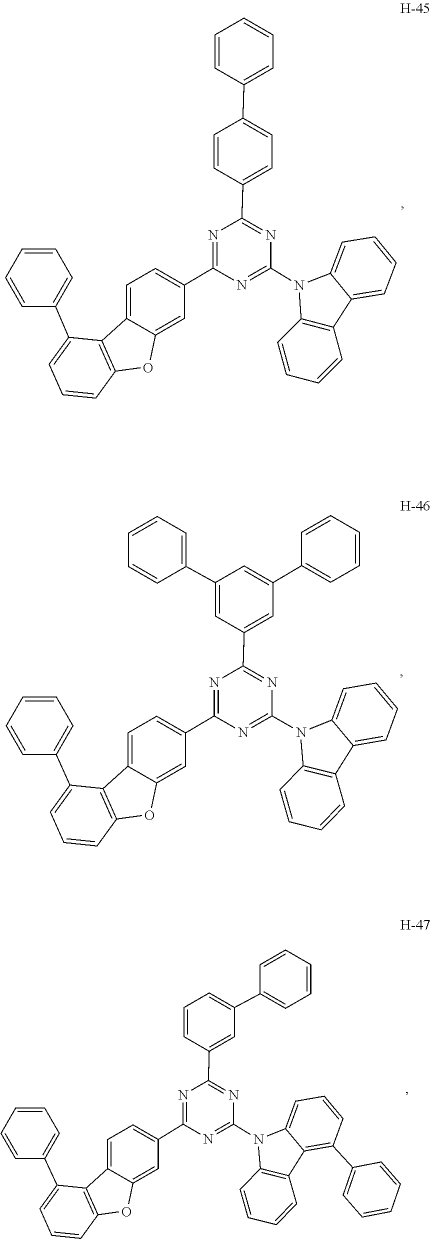 [SMILES: c1ccc(-c2ccc(-c3nc(-c4ccc5c(c4)oc4cccc(-c6ccccc6)c45)nc(-n4c5ccccc5c5ccccc54)n3)cc2)cc1 ; c1ccc(-c2cc(-c3ccccc3)cc(-c3nc(-c4ccc5c(c4)oc4cccc(-c6ccccc6)c45)nc(-n4c5ccccc5c5ccccc54)n3)c2)cc1 ; c1ccc(-c2cccc(-c3nc(-c4ccc5c(c4)oc4cccc(-c6ccccc6)c45)nc(-n4c5ccccc5c5c(-c6ccccc6)cccc54)n3)c2)cc1]

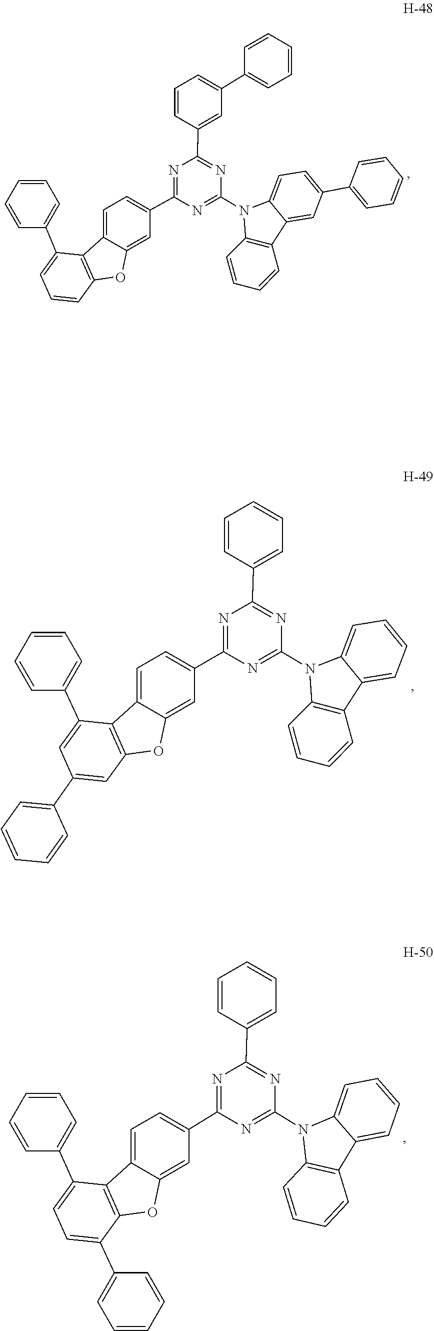 [SMILES: c1ccc(-c2cccc(-c3nc(-c4ccc5c(c4)oc4cccc(-c6ccccc6)c45)nc(-n4c5ccccc5c5cc(-c6ccccc6)ccc54)n3)c2)cc1 ; c1ccc(-c2cc(-c3ccccc3)c3c(c2)oc2cc(-c4nc(-c5ccccc5)nc(-n5c6ccccc6c6ccccc65)n4)ccc23)cc1 ; c1ccc(-c2nc(-c3ccc4c(c3)oc3c(-c5ccccc5)ccc(-c5ccccc5)c34)nc(-n3c4ccccc4c4ccccc43)n2)cc1]

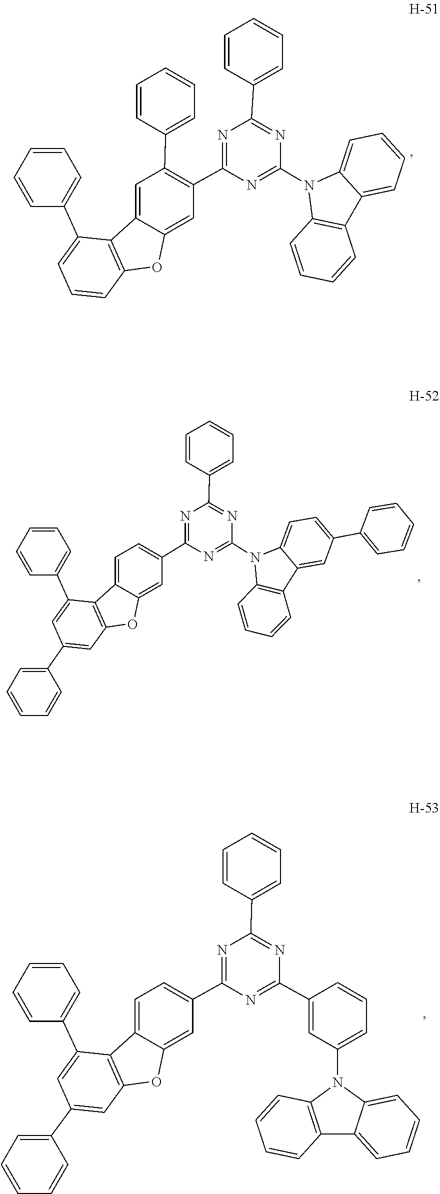 [SMILES: c1ccc(-c2nc(-c3cc4oc5cccc(-c6ccccc6)c5c4cc3-c3ccccc3)nc(-n3c4ccccc4c4ccccc43)n2)cc1 ; c1ccc(-c2cc(-c3ccccc3)c3c(c2)oc2cc(-c4nc(-c5ccccc5)nc(-n5c6ccccc6c6cc(-c7ccccc7)ccc65)n4)ccc23)cc1 ; c1ccc(-c2cc(-c3ccccc3)c3c(c2)oc2cc(-c4nc(-c5ccccc5)nc(-c5cccc(-n6c7ccccc7c7ccccc76)c5)n4)ccc23)cc1]

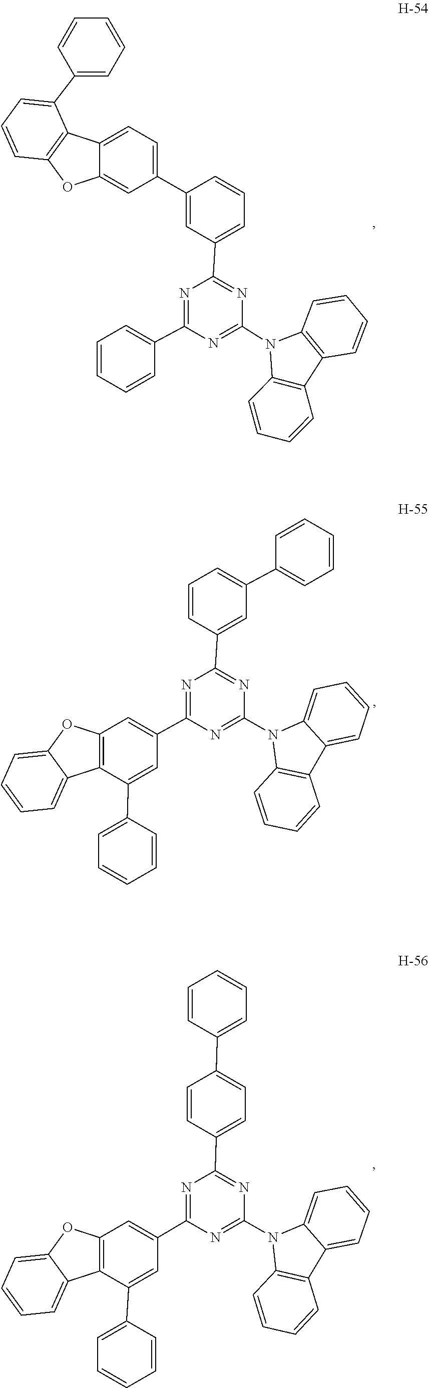 [SMILES: c1ccc(-c2nc(-c3cccc(-c4ccc5c(c4)oc4cccc(-c6ccccc6)c45)c3)nc(-n3c4ccccc4c4ccccc43)n2)cc1 ; c1ccc(-c2cccc(-c3nc(-c4cc(-c5ccccc5)c5c(c4)oc4ccccc45)nc(-n4c5ccccc5c5ccccc54)n3)c2)cc1 ; c1ccc(-c2ccc(-c3nc(-c4cc(-c5ccccc5)c5c(c4)oc4ccccc45)nc(-n4c5ccccc5c5ccccc54)n3)cc2)cc1]

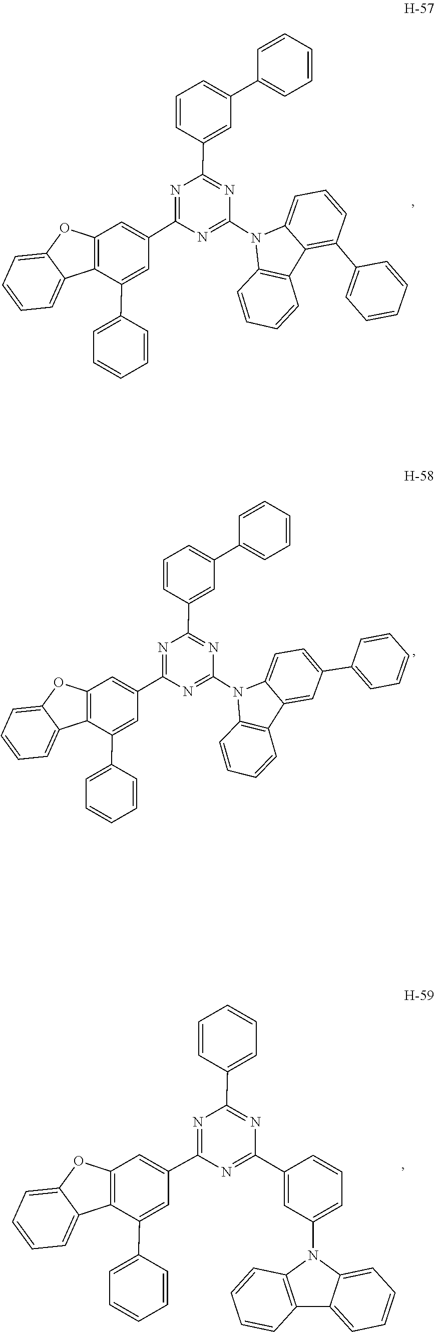 [SMILES: c1ccc(-c2cccc(-c3nc(-c4cc(-c5ccccc5)c5c(c4)oc4ccccc45)nc(-n4c5ccccc5c5c(-c6ccccc6)cccc54)n3)c2)cc1 ; c1ccc(-c2cccc(-c3nc(-c4cc(-c5ccccc5)c5c(c4)oc4ccccc45)nc(-n4c5ccccc5c5cc(-c6ccccc6)ccc54)n3)c2)cc1 ; c1ccc(-c2nc(-c3cccc(-n4c5ccccc5c5ccccc54)c3)nc(-c3cc(-c4ccccc4)c4c(c3)oc3ccccc34)n2)cc1]

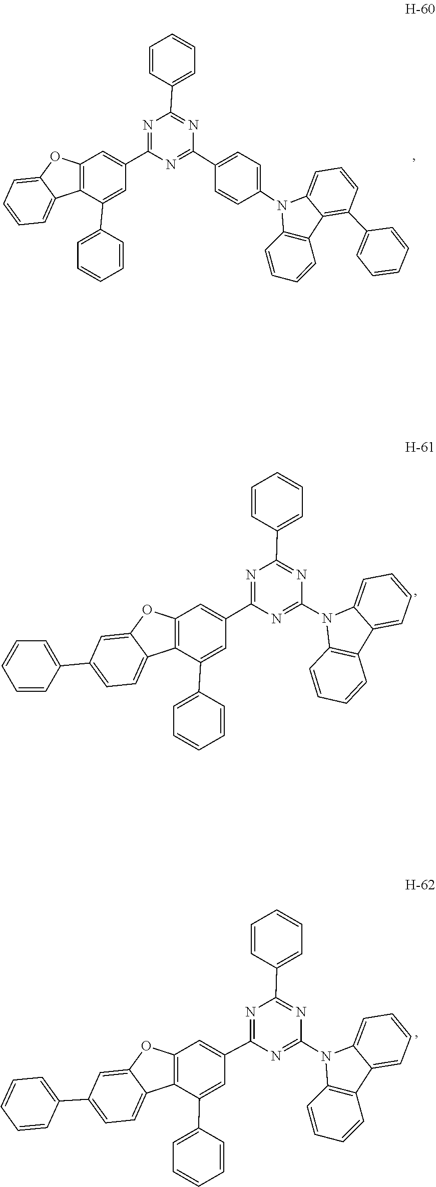 [SMILES: c1ccc(-c2nc(-c3ccc(-n4c5ccccc5c5c(-c6ccccc6)cccc54)cc3)nc(-c3cc(-c4ccccc4)c4c(c3)oc3ccccc34)n2)cc1 ; c1ccc(-c2ccc3c(c2)oc2cc(-c4nc(-c5ccccc5)nc(-n5c6ccccc6c6ccccc65)n4)cc(-c4ccccc4)c23)cc1 ; c1ccc(-c2ccc3c(c2)oc2cc(-c4nc(-c5ccccc5)nc(-n5c6ccccc6c6ccccc65)n4)cc(-c4ccccc4)c23)cc1]

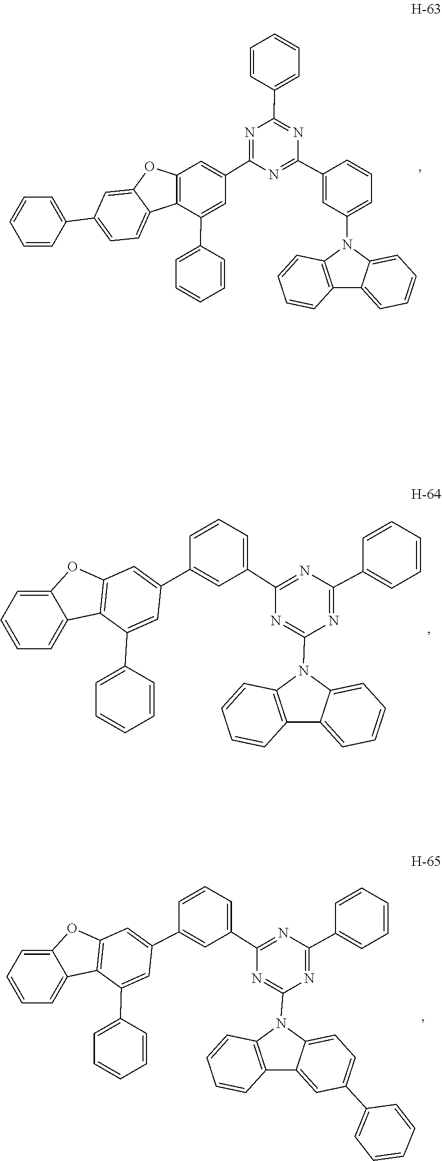 [SMILES: c1ccc(-c2ccc3c(c2)oc2cc(-c4nc(-c5ccccc5)nc(-c5cccc(-n6c7ccccc7c7ccccc76)c5)n4)cc(-c4ccccc4)c23)cc1 ; c1ccc(-c2nc(-c3cccc(-c4cc(-c5ccccc5)c5c(c4)oc4ccccc45)c3)nc(-n3c4ccccc4c4ccccc43)n2)cc1 ; c1ccc(-c2ccc3c(c2)c2ccccc2n3-c2nc(-c3ccccc3)nc(-c3cccc(-c4cc(-c5ccccc5)c5c(c4)oc4ccccc45)c3)n2)cc1]

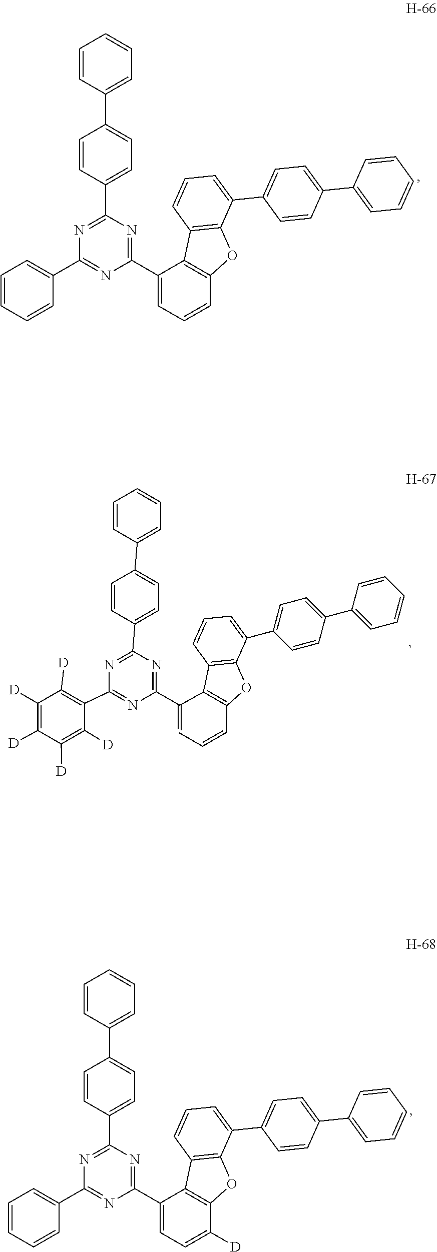 [SMILES: c1ccc(-c2ccc(-c3nc(-c4ccccc4)nc(-c4cccc5oc6c(-c7ccc(-c8ccccc8)cc7)cccc6c45)n3)cc2)cc1 ; [2H]c1c([2H])c([2H])c(-c2nc(C(=C)c3c(/C=C\C)oc4c(-c5ccc(-c6ccccc6)cc5)cccc34)nc(-c3ccc(-c4ccccc4)cc3)n2)c([2H])c1[2H] ; [2H]c1ccc(-c2nc(-c3ccccc3)nc(-c3ccc(-c4ccccc4)cc3)n2)c2c1oc1c(-c3ccc(-c4ccccc4)cc3)cccc12]

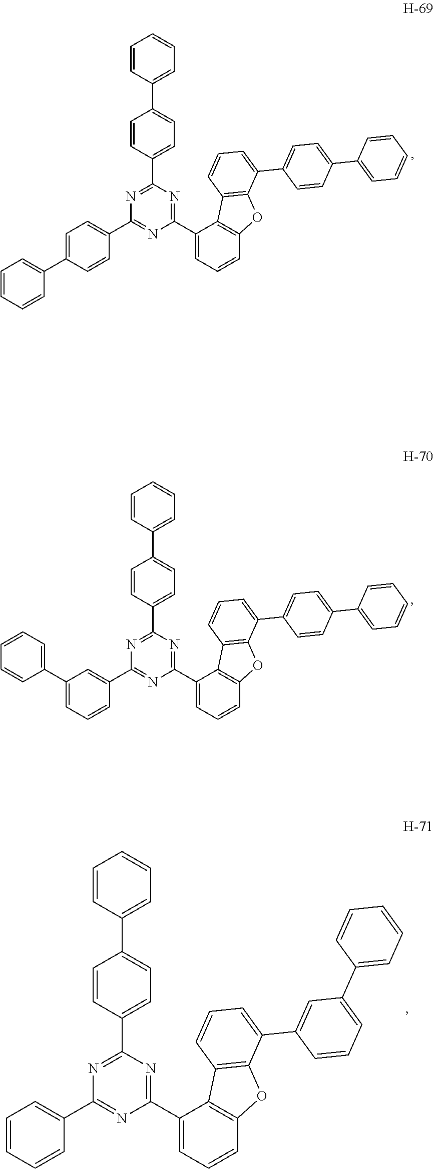 [SMILES: c1ccc(-c2ccc(-c3nc(-c4ccc(-c5ccccc5)cc4)nc(-c4cccc5oc6c(-c7ccc(-c8ccccc8)cc7)cccc6c45)n3)cc2)cc1 ; c1ccc(-c2ccc(-c3nc(-c4cccc(-c5ccccc5)c4)nc(-c4cccc5oc6c(-c7ccc(-c8ccccc8)cc7)cccc6c45)n3)cc2)cc1 ; c1ccc(-c2ccc(-c3nc(-c4ccccc4)nc(-c4cccc5oc6c(-c7cccc(-c8ccccc8)c7)cccc6c45)n3)cc2)cc1]

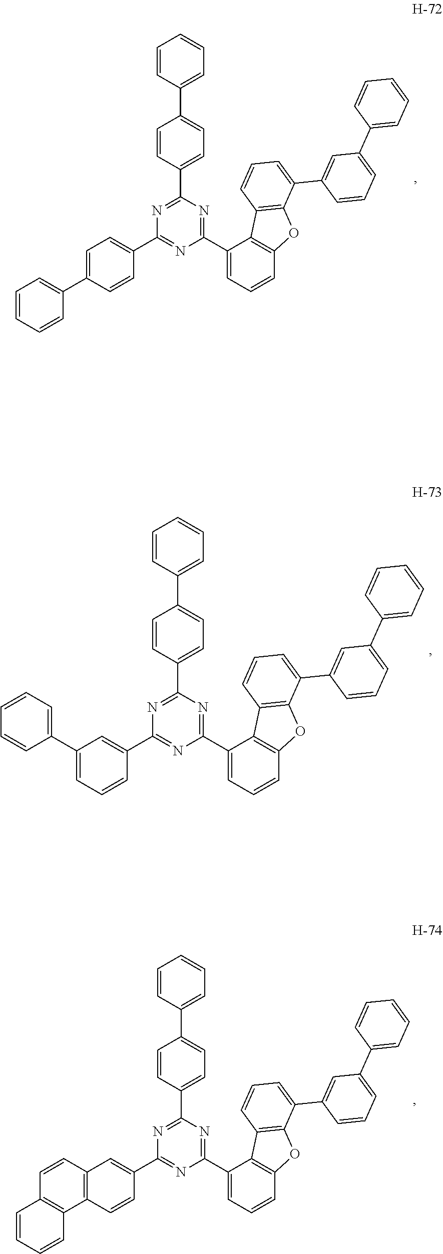 [SMILES: c1ccc(-c2ccc(-c3nc(-c4ccc(-c5ccccc5)cc4)nc(-c4cccc5oc6c(-c7cccc(-c8ccccc8)c7)cccc6c45)n3)cc2)cc1 ; c1ccc(-c2ccc(-c3nc(-c4cccc(-c5ccccc5)c4)nc(-c4cccc5oc6c(-c7cccc(-c8ccccc8)c7)cccc6c45)n3)cc2)cc1 ; c1ccc(-c2ccc(-c3nc(-c4ccc5c(ccc6ccccc65)c4)nc(-c4cccc5oc6c(-c7cccc(-c8ccccc8)c7)cccc6c45)n3)cc2)cc1]

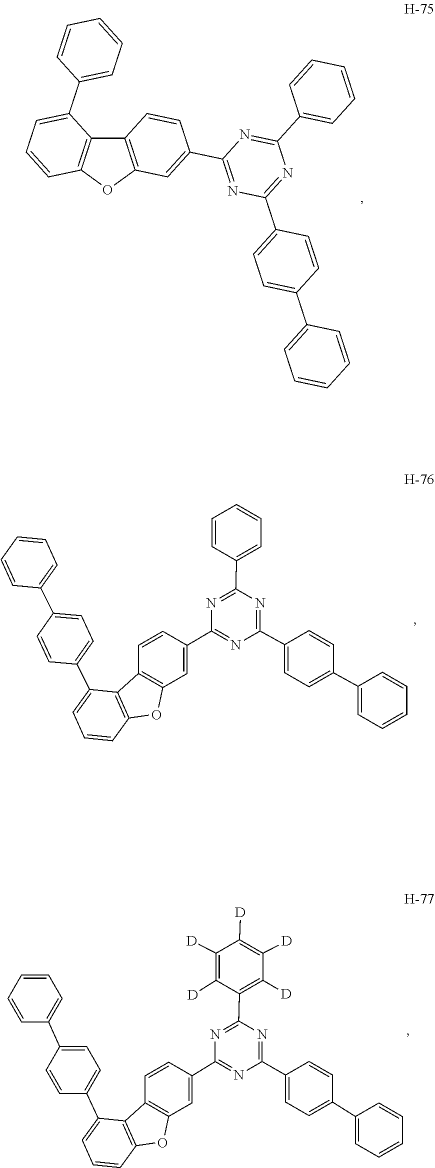 [SMILES: c1ccc(-c2ccc(-c3nc(-c4ccccc4)nc(-c4ccc5c(c4)oc4cccc(-c6ccccc6)c45)n3)cc2)cc1 ; c1ccc(-c2ccc(-c3nc(-c4ccccc4)nc(-c4ccc5c(c4)oc4cccc(-c6ccc(-c7ccccc7)cc6)c45)n3)cc2)cc1 ; [2H]c1c([2H])c([2H])c(-c2nc(-c3ccc(-c4ccccc4)cc3)nc(-c3ccc4c(c3)oc3cccc(-c5ccc(-c6ccccc6)cc5)c34)n2)c([2H])c1[2H]]

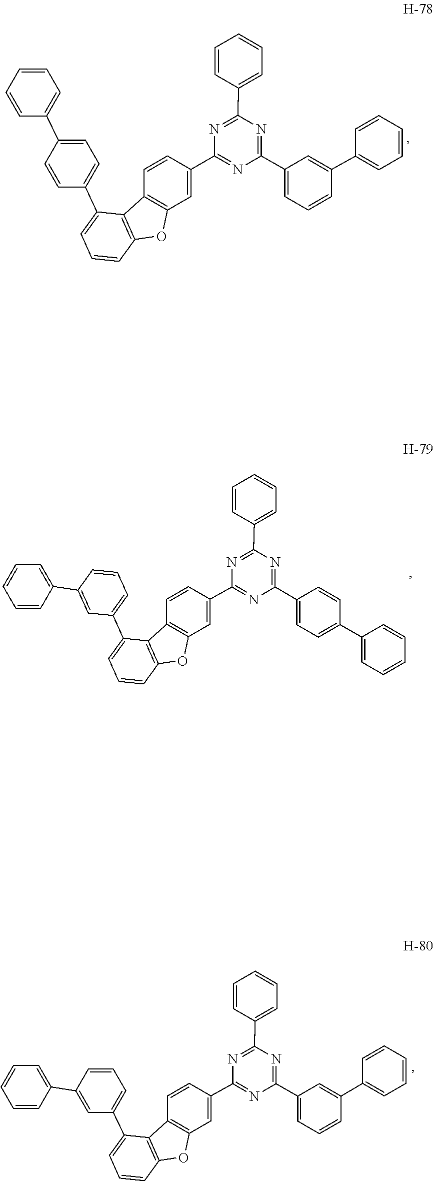 [SMILES: c1ccc(-c2ccc(-c3cccc4oc5cc(-c6nc(-c7ccccc7)nc(-c7cccc(-c8ccccc8)c7)n6)ccc5c34)cc2)cc1 ; c1ccc(-c2ccc(-c3nc(-c4ccccc4)nc(-c4ccc5c(c4)oc4cccc(-c6cccc(-c7ccccc7)c6)c45)n3)cc2)cc1 ; c1ccc(-c2cccc(-c3nc(-c4ccccc4)nc(-c4ccc5c(c4)oc4cccc(-c6cccc(-c7ccccc7)c6)c45)n3)c2)cc1]

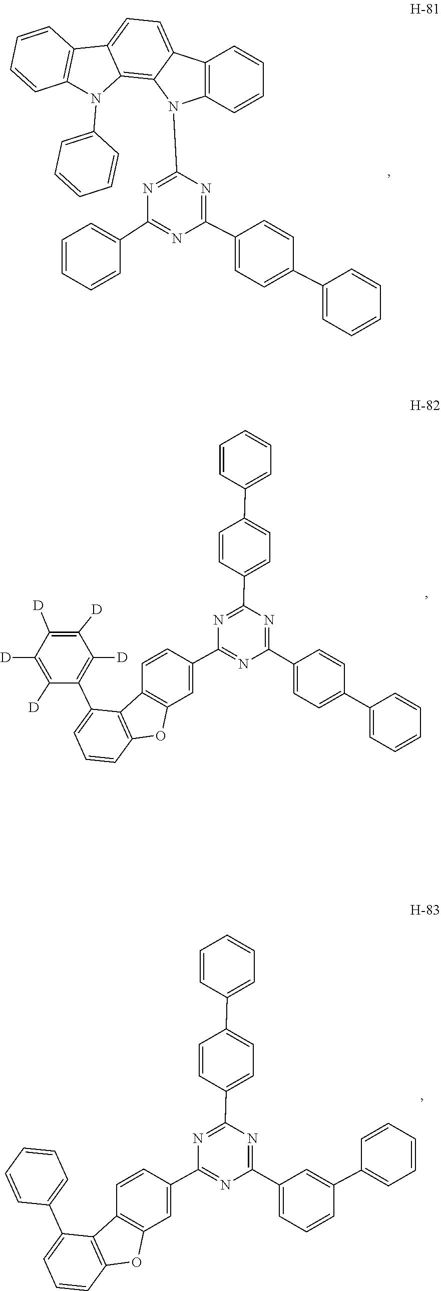 [SMILES: c1ccc(-c2ccc(-c3nc(-c4ccccc4)nc(-n4c5ccccc5c5ccc6c7ccccc7n(-c7ccccc7)c6c54)n3)cc2)cc1 ; [2H]c1c([2H])c([2H])c(-c2cccc3oc4cc(-c5nc(-c6ccc(-c7ccccc7)cc6)nc(-c6ccc(-c7ccccc7)cc6)n5)ccc4c23)c([2H])c1[2H] ; c1ccc(-c2ccc(-c3nc(-c4cccc(-c5ccccc5)c4)nc(-c4ccc5c(c4)oc4cccc(-c6ccccc6)c45)n3)cc2)cc1]

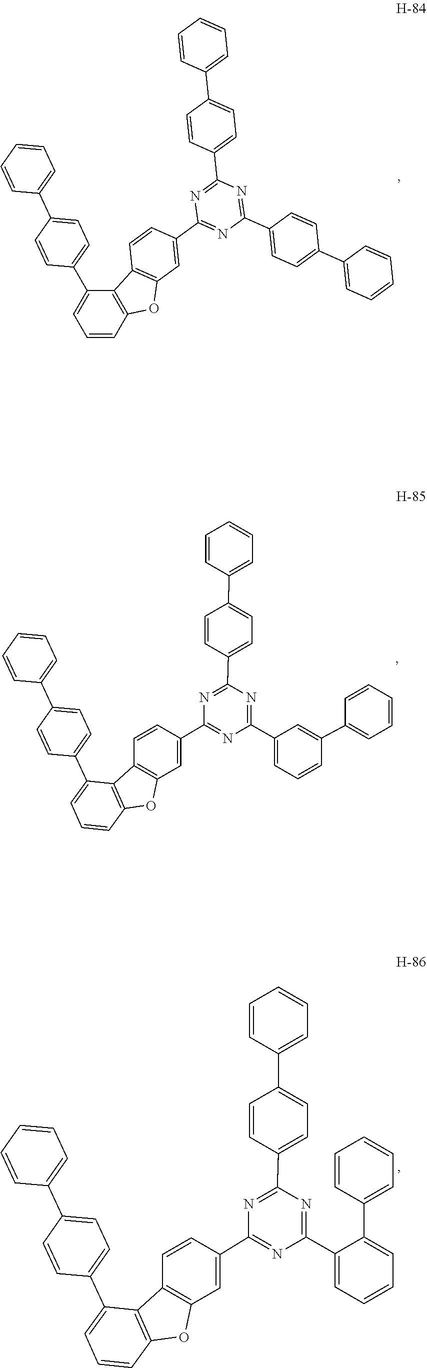 [SMILES: c1ccc(-c2ccc(-c3nc(-c4ccc(-c5ccccc5)cc4)nc(-c4ccc5c(c4)oc4cccc(-c6ccc(-c7ccccc7)cc6)c45)n3)cc2)cc1 ; c1ccc(-c2ccc(-c3nc(-c4cccc(-c5ccccc5)c4)nc(-c4ccc5c(c4)oc4cccc(-c6ccc(-c7ccccc7)cc6)c45)n3)cc2)cc1 ; c1ccc(-c2ccc(-c3nc(-c4ccc5c(c4)oc4cccc(-c6ccc(-c7ccccc7)cc6)c45)nc(-c4ccccc4-c4ccccc4)n3)cc2)cc1]

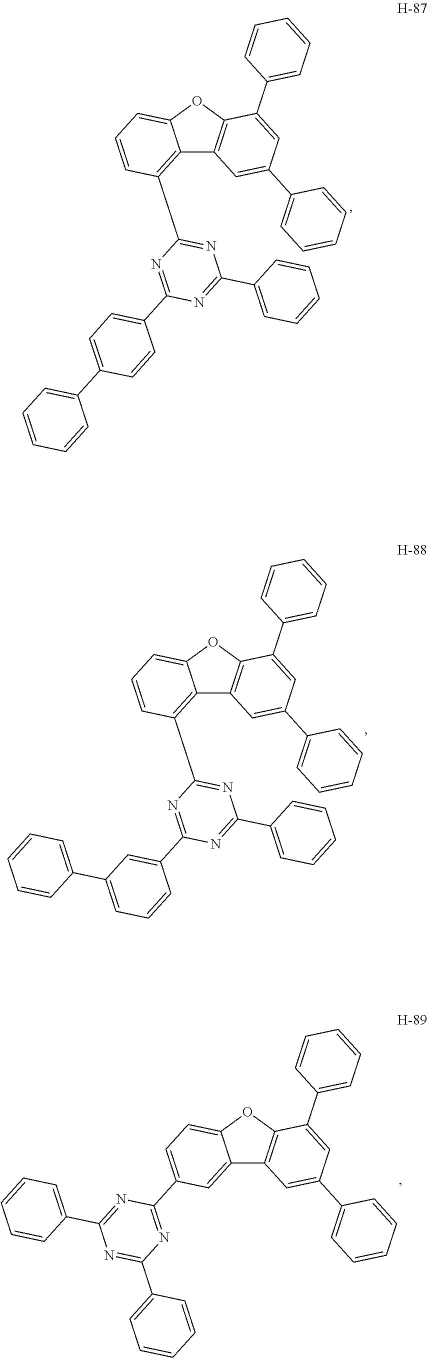 [SMILES: c1ccc(-c2ccc(-c3nc(-c4ccccc4)nc(-c4cccc5oc6c(-c7ccccc7)cc(-c7ccccc7)cc6c45)n3)cc2)cc1 ; c1ccc(-c2cccc(-c3nc(-c4ccccc4)nc(-c4cccc5oc6c(-c7ccccc7)cc(-c7ccccc7)cc6c45)n3)c2)cc1 ; c1ccc(-c2cc(-c3ccccc3)c3oc4ccc(-c5nc(-c6ccccc6)nc(-c6ccccc6)n5)cc4c3c2)cc1]

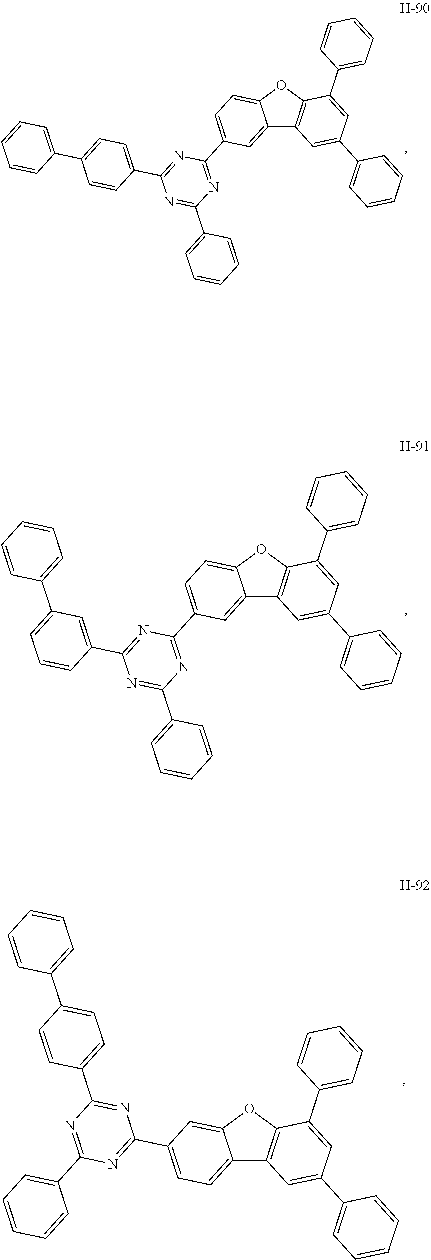 [SMILES: c1ccc(-c2ccc(-c3nc(-c4ccccc4)nc(-c4ccc5oc6c(-c7ccccc7)cc(-c7ccccc7)cc6c5c4)n3)cc2)cc1 ; c1ccc(-c2cccc(-c3nc(-c4ccccc4)nc(-c4ccc5oc6c(-c7ccccc7)cc(-c7ccccc7)cc6c5c4)n3)c2)cc1 ; c1ccc(-c2ccc(-c3nc(-c4ccccc4)nc(-c4ccc5c(c4)oc4c(-c6ccccc6)cc(-c6ccccc6)cc45)n3)cc2)cc1]

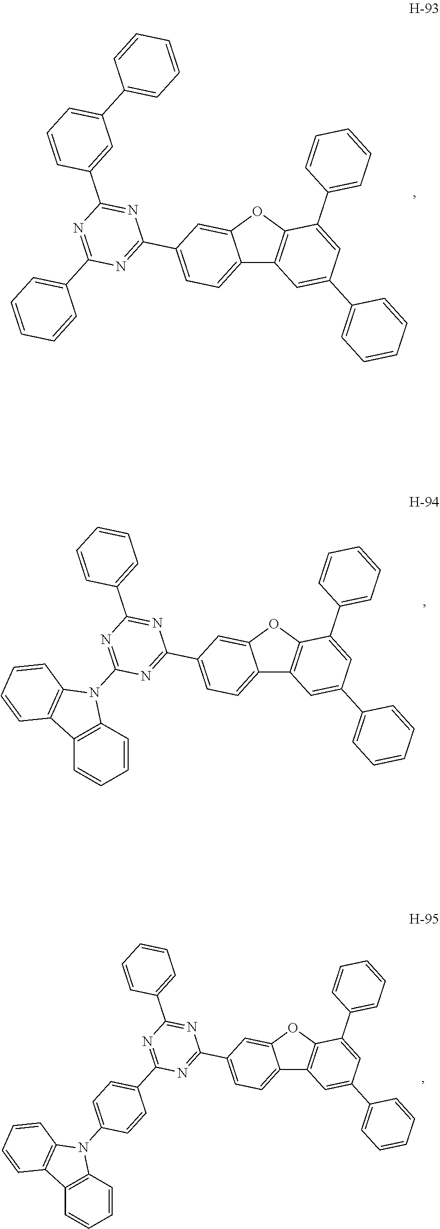 [SMILES: c1ccc(-c2cccc(-c3nc(-c4ccccc4)nc(-c4ccc5c(c4)oc4c(-c6ccccc6)cc(-c6ccccc6)cc45)n3)c2)cc1 ; c1ccc(-c2cc(-c3ccccc3)c3oc4cc(-c5nc(-c6ccccc6)nc(-n6c7ccccc7c7ccccc76)n5)ccc4c3c2)cc1 ; c1ccc(-c2cc(-c3ccccc3)c3oc4cc(-c5nc(-c6ccccc6)nc(-c6ccc(-n7c8ccccc8c8ccccc87)cc6)n5)ccc4c3c2)cc1]

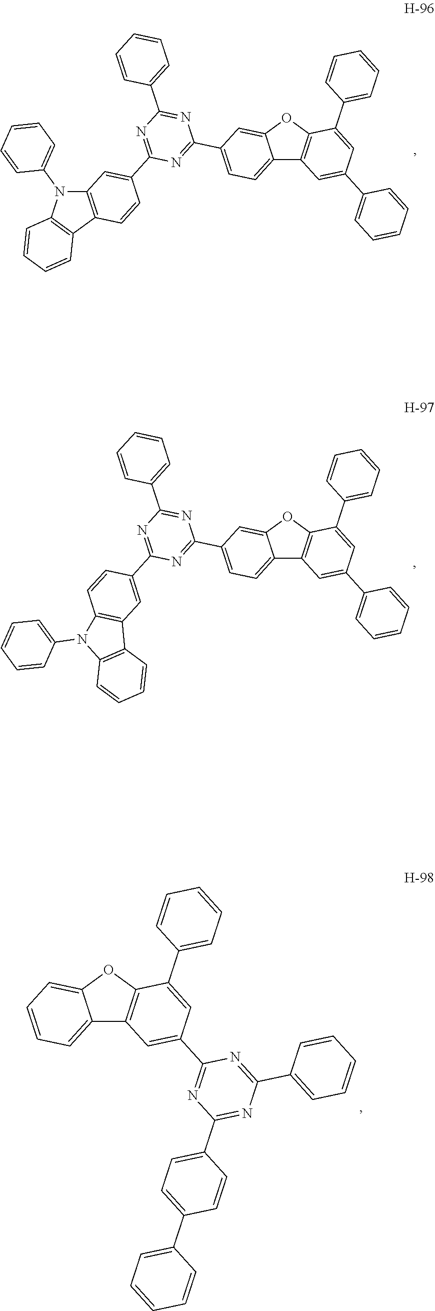 [SMILES: c1ccc(-c2cc(-c3ccccc3)c3oc4cc(-c5nc(-c6ccccc6)nc(-c6ccc7c8ccccc8n(-c8ccccc8)c7c6)n5)ccc4c3c2)cc1 ; c1ccc(-c2cc(-c3ccccc3)c3oc4cc(-c5nc(-c6ccccc6)nc(-c6ccc7c(c6)c6ccccc6n7-c6ccccc6)n5)ccc4c3c2)cc1 ; c1ccc(-c2ccc(-c3nc(-c4ccccc4)nc(-c4cc(-c5ccccc5)c5oc6ccccc6c5c4)n3)cc2)cc1]

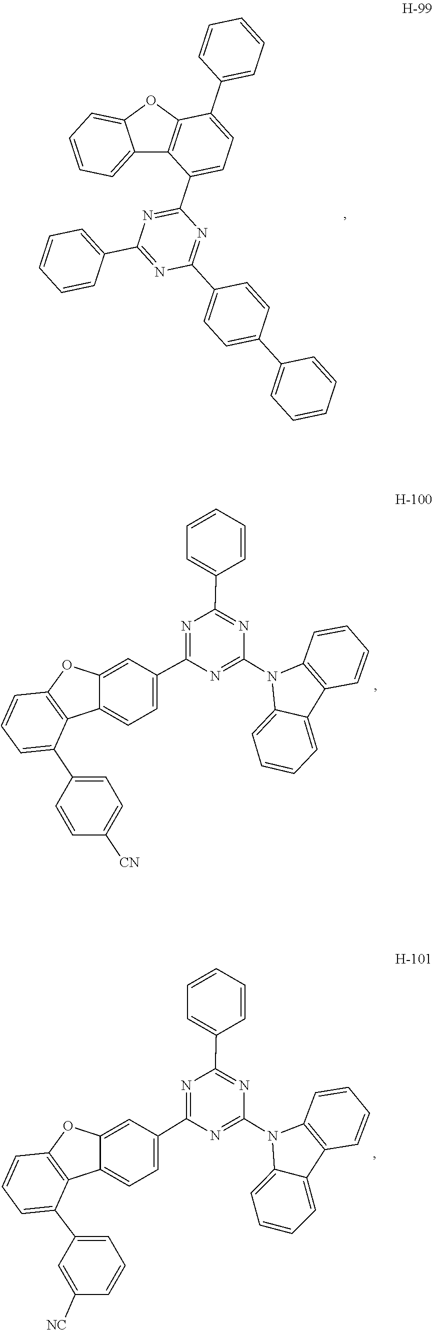 [SMILES: c1ccc(-c2ccc(-c3nc(-c4ccccc4)nc(-c4ccc(-c5ccccc5)c5oc6ccccc6c45)n3)cc2)cc1 ; N#Cc1ccc(-c2cccc3oc4cc(-c5nc(-c6ccccc6)nc(-n6c7ccccc7c7ccccc76)n5)ccc4c23)cc1 ; N#Cc1cccc(-c2cccc3oc4cc(-c5nc(-c6ccccc6)nc(-n6c7ccccc7c7ccccc76)n5)ccc4c23)c1]

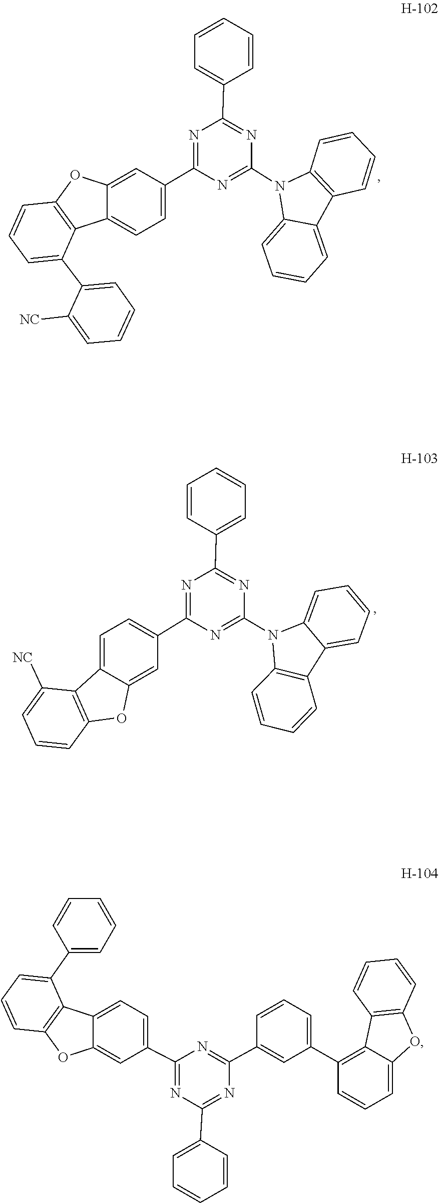 [SMILES: N#Cc1ccccc1-c1cccc2oc3cc(-c4nc(-c5ccccc5)nc(-n5c6ccccc6c6ccccc65)n4)ccc3c12 ; N#Cc1cccc2oc3cc(-c4nc(-c5ccccc5)nc(-n5c6ccccc6c6ccccc65)n4)ccc3c12 ; c1ccc(-c2nc(-c3cccc(-c4cccc5oc6ccccc6c45)c3)nc(-c3ccc4c(c3)oc3cccc(-c5ccccc5)c34)n2)cc1]

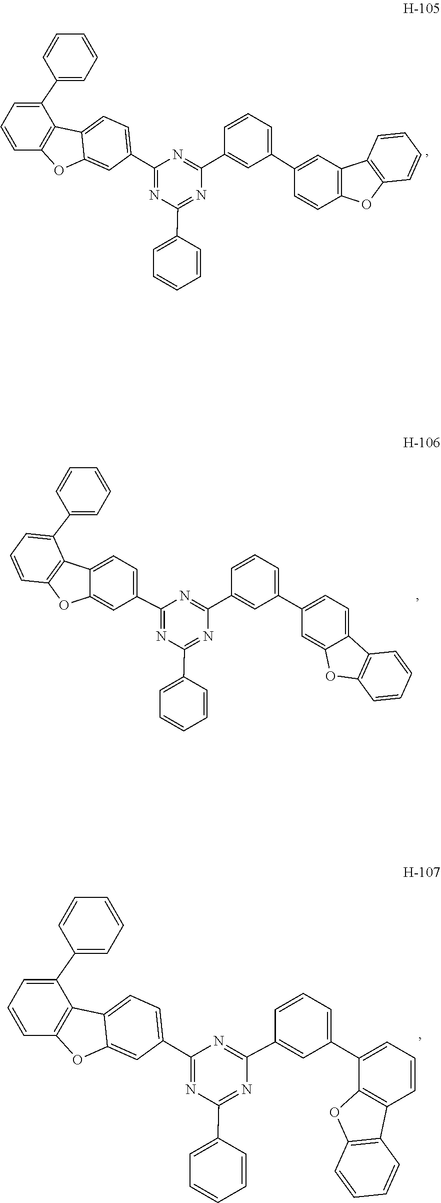 [SMILES: c1ccc(-c2nc(-c3cccc(-c4ccc5oc6ccccc6c5c4)c3)nc(-c3ccc4c(c3)oc3cccc(-c5ccccc5)c34)n2)cc1 ; c1ccc(-c2nc(-c3cccc(-c4ccc5c(c4)oc4ccccc45)c3)nc(-c3ccc4c(c3)oc3cccc(-c5ccccc5)c34)n2)cc1 ; c1ccc(-c2nc(-c3cccc(-c4cccc5c4oc4ccccc45)c3)nc(-c3ccc4c(c3)oc3cccc(-c5ccccc5)c34)n2)cc1]

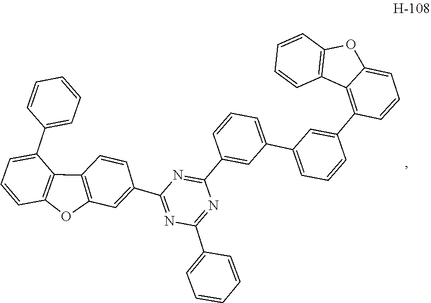 [SMILES: c1ccc(-c2nc(-c3cccc(-c4cccc(-c5cccc6oc7ccccc7c56)c4)c3)nc(-c3ccc4c(c3)oc3cccc(-c5ccccc5)c34)n2)cc1]

According to an embodiment of the present disclosure, the second compound has a structure represented by Formula X-1 or Formula X-2:

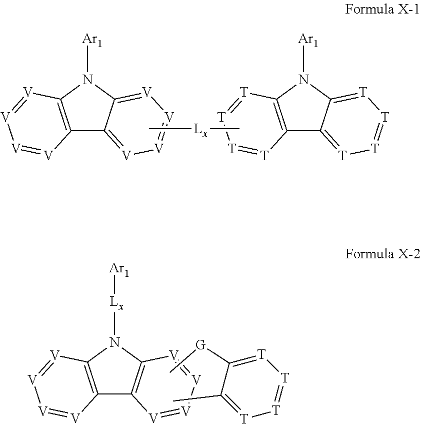

wherein
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof;
G is, at each occurrence identically or differently, selected from C(R_{g})₂, NR_{g}, O, or S;
V is, at each occurrence identically or differently, selected from C, CR_{V}, or N;
in Formula X-1, T is, at each occurrence identically or differently, selected from C, CRₜ, or N;
in Formula X-2, T is, at each occurrence identically or differently, selected from CRₜ or N;
R_{g}, Rᵥ, and Rₜ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfanyl group, a sulfonyl group, a phosphino group, and combinations thereof;
Arₜ is, at each occurrence identically or differently, selected from substituted or unsubstituted aryl having 6 to 30 carbon atoms, substituted or unsubstituted heteroaryl having 3 to 30 carbon atoms, or a combination thereof; and
adjacent substituents R_{g}, Rᵥ, and Rₜ can be optionally joined to form a ring.

In this embodiment, the expression that “adjacent substituents R_{g}, Rᵥ, and Rₜ can be optionally joined to form a ring” is intended to mean that any one or more of groups of adjacent substituents, such as two substituents Rᵥ, two substituents Rₜ, two substituents R_{g}, substituents Rᵥ and Rₜ, substituents Rᵥ and R_{g}, and substituents R_{g} and Rₜ, can be joined to form a ring. Obviously, it is also possible that none of these substituents are joined to form a ring.

According to an embodiment of the present disclosure, the second compound has a structure represented by one of Formula X-a to Formula X-p:

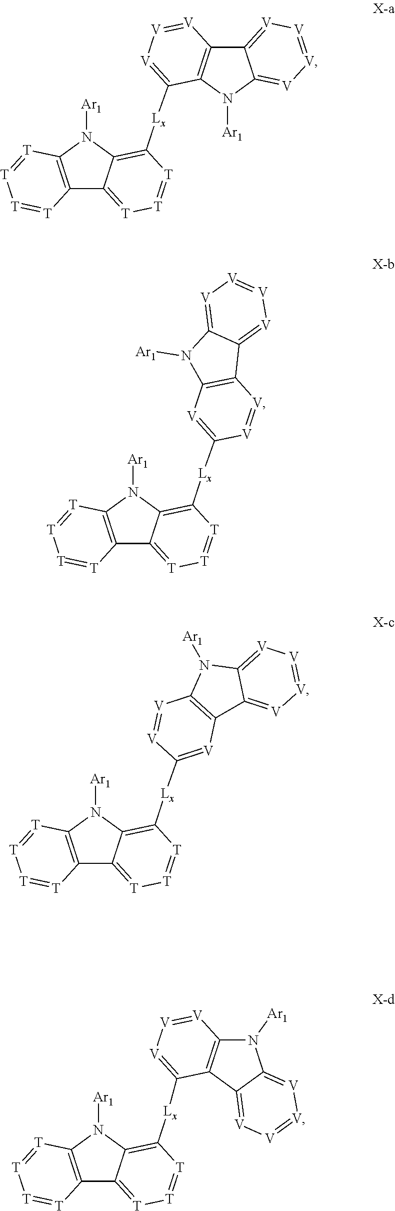

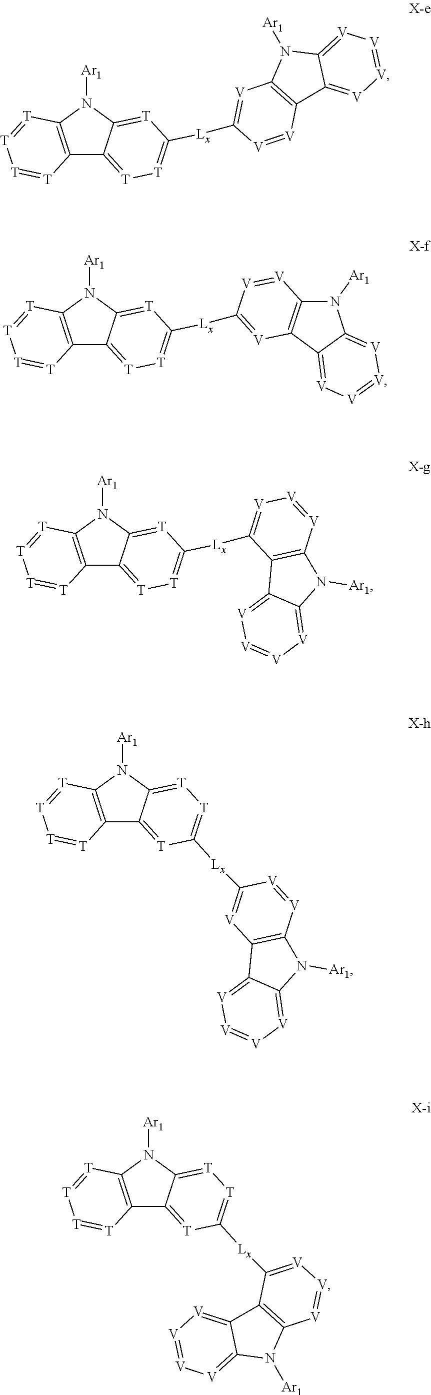

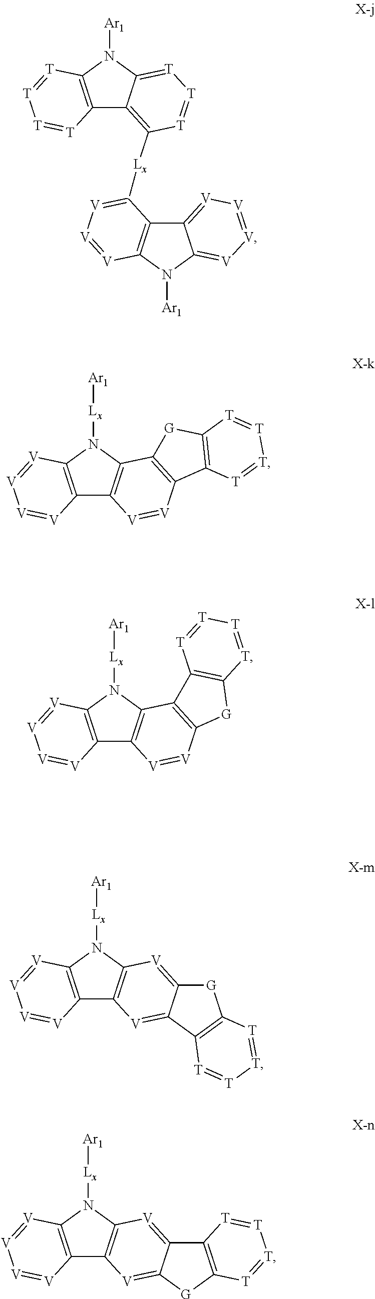

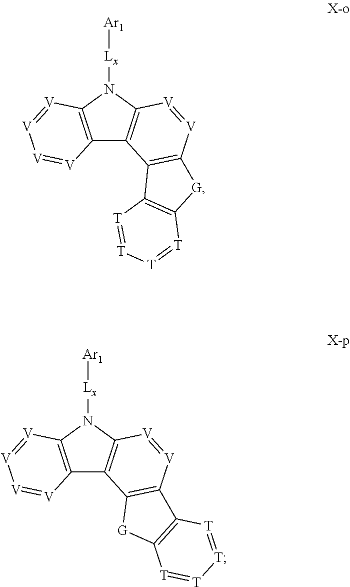

wherein
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof;
G is, at each occurrence identically or differently, selected from C(R_{g})₂, NR_{g}, O, or S;
V is, at each occurrence identically or differently, selected from CRᵥ or N;
T is, at each occurrence identically or differently, selected from CRₜ or N;

R_{g}, Rᵥ, and Rₜ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfanyl group, a sulfonyl group, a phosphino group, and combinations thereof;

Arₜ is, at each occurrence identically or differently, selected from substituted or unsubstituted aryl having 6 to 30 carbon atoms, substituted or unsubstituted heteroaryl having 3 to 30 carbon atoms, or a combination thereof; and
adjacent substituents R_{g}, Rᵥ, and Rₜ can be optionally joined to form a ring.

According to an embodiment of the present disclosure, the second compound is selected from the group consisting of the following compounds:

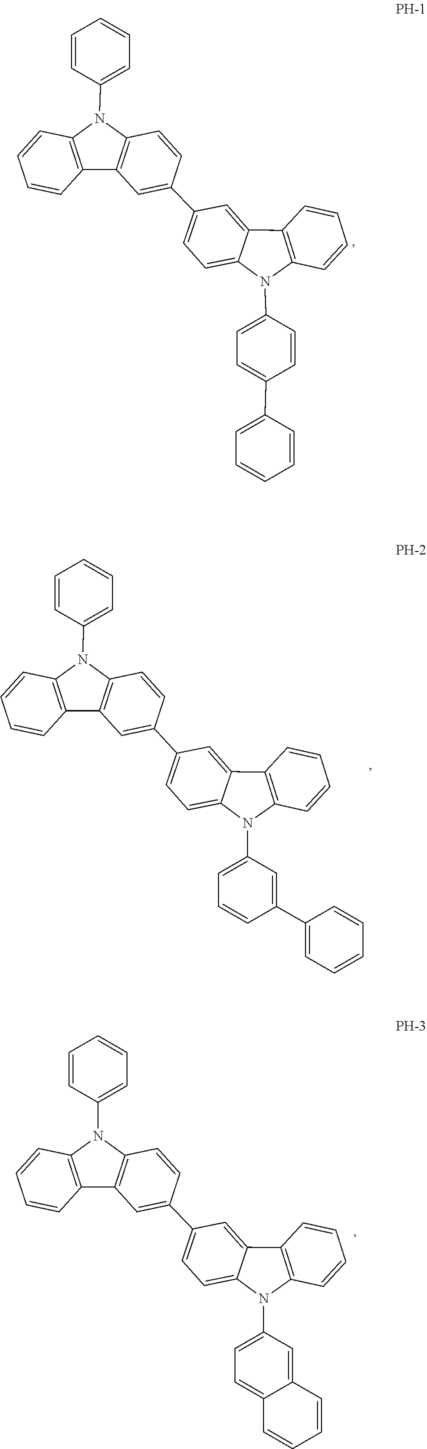 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cccc(-n3c4ccccc4c4cc(-c5ccc6c(c5)c5ccccc5n6-c5ccccc5)ccc43)c2)cc1 ; c1ccc(-n2c3ccccc3c3cc(-c4ccc5c(c4)c4ccccc4n5-c4ccc5ccccc5c4)ccc32)cc1]

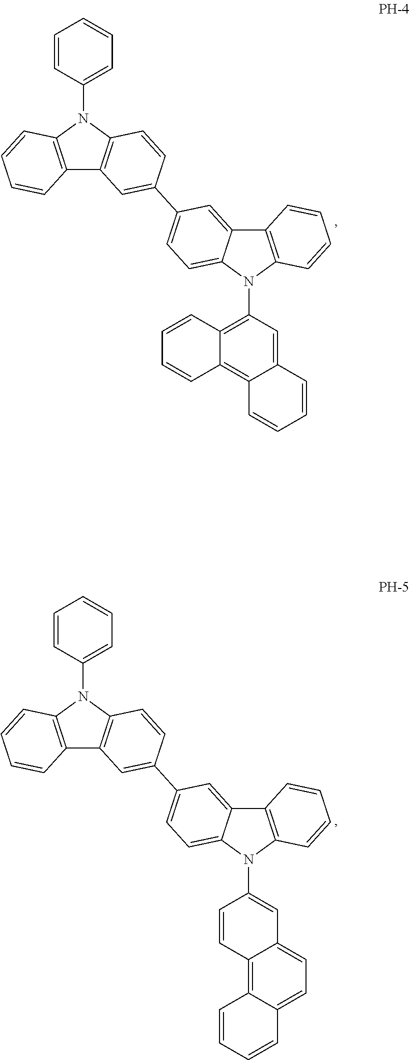 [SMILES: c1ccc(-n2c3ccccc3c3cc(-c4ccc5c(c4)c4ccccc4n5-c4cc5ccccc5c5ccccc45)ccc32)cc1 ; c1ccc(-n2c3ccccc3c3cc(-c4ccc5c(c4)c4ccccc4n5-c4ccc5c(ccc6ccccc65)c4)ccc32)cc1]

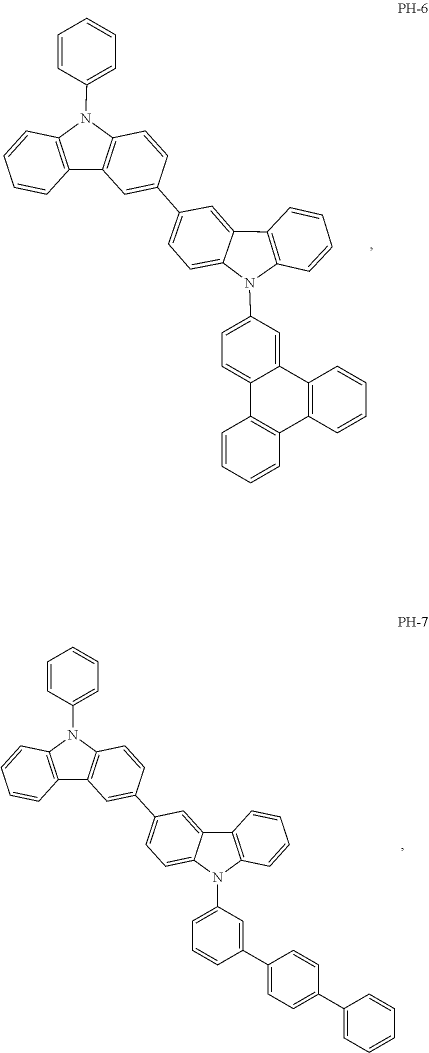 [SMILES: c1ccc(-n2c3ccccc3c3cc(-c4ccc5c(c4)c4ccccc4n5-c4ccc5c6ccccc6c6ccccc6c5c4)ccc32)cc1 ; c1ccc(-c2ccc(-c3cccc(-n4c5ccccc5c5cc(-c6ccc7c(c6)c6ccccc6n7-c6ccccc6)ccc54)c3)cc2)cc1]

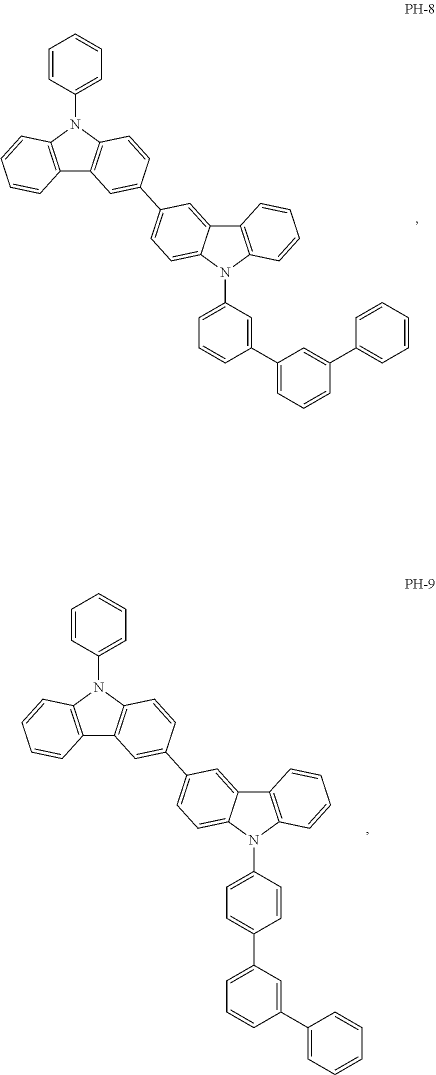 [SMILES: c1ccc(-c2cccc(-c3cccc(-n4c5ccccc5c5cc(-c6ccc7c(c6)c6ccccc6n7-c6ccccc6)ccc54)c3)c2)cc1 ; c1ccc(-c2cccc(-c3ccc(-n4c5ccccc5c5cc(-c6ccc7c(c6)c6ccccc6n7-c6ccccc6)ccc54)cc3)c2)cc1]

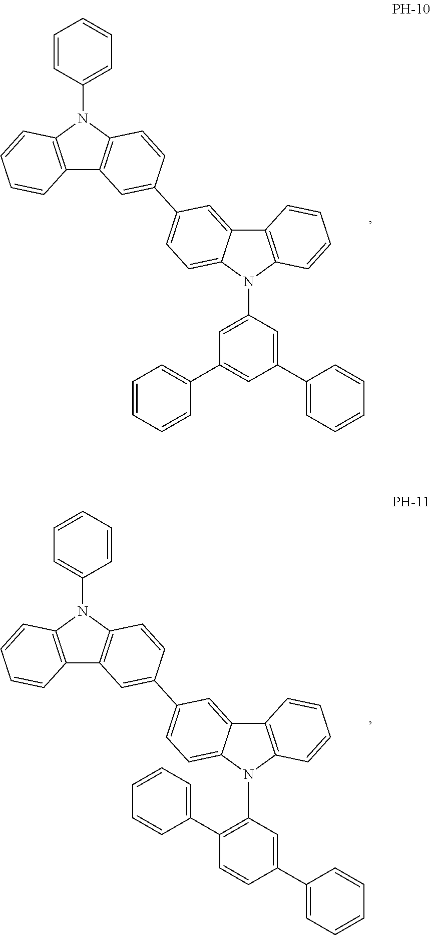 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2ccc(-c3ccccc3)c(-n3c4ccccc4c4cc(-c5ccc6c(c5)c5ccccc5n6-c5ccccc5)ccc43)c2)cc1]

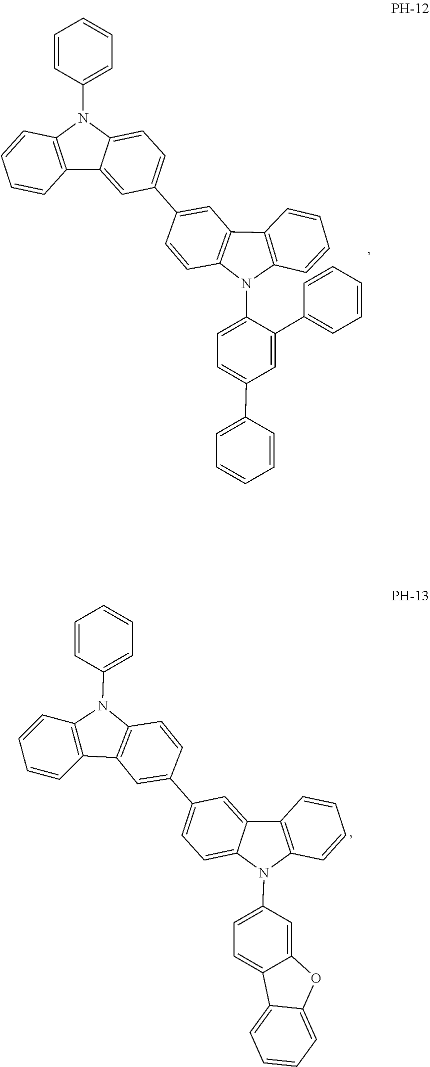 [SMILES: c1ccc(-c2ccc(-n3c4ccccc4c4cc(-c5ccc6c(c5)c5ccccc5n6-c5ccccc5)ccc43)c(-c3ccccc3)c2)cc1 ; c1ccc(-n2c3ccccc3c3cc(-c4ccc5c(c4)c4ccccc4n5-c4ccc5c(c4)oc4ccccc45)ccc32)cc1]

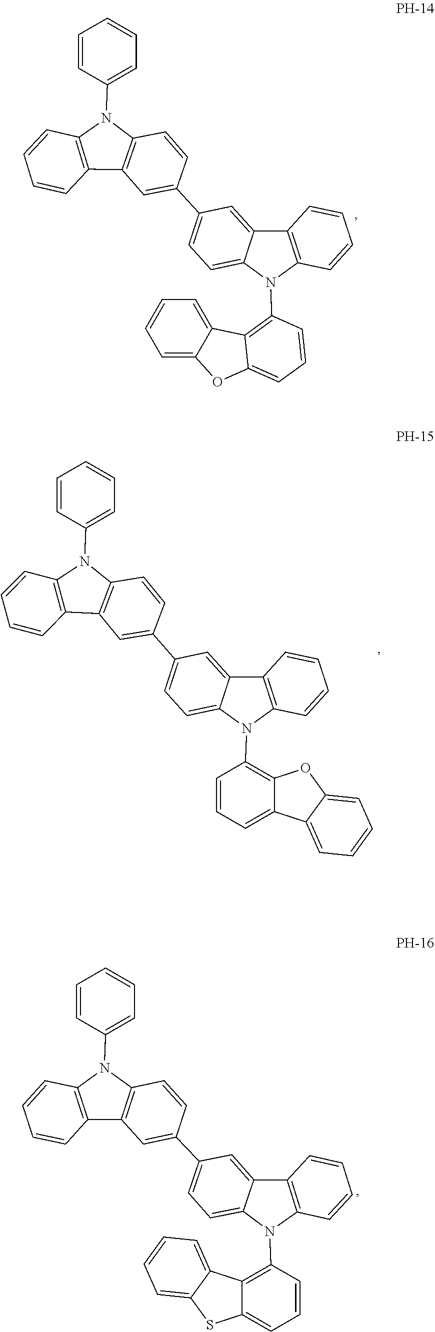 [SMILES: c1ccc(-n2c3ccccc3c3cc(-c4ccc5c(c4)c4ccccc4n5-c4cccc5oc6ccccc6c45)ccc32)cc1 ; c1ccc(-n2c3ccccc3c3cc(-c4ccc5c(c4)c4ccccc4n5-c4cccc5c4oc4ccccc45)ccc32)cc1 ; c1ccc(-n2c3ccccc3c3cc(-c4ccc5c(c4)c4ccccc4n5-c4cccc5sc6ccccc6c45)ccc32)cc1]

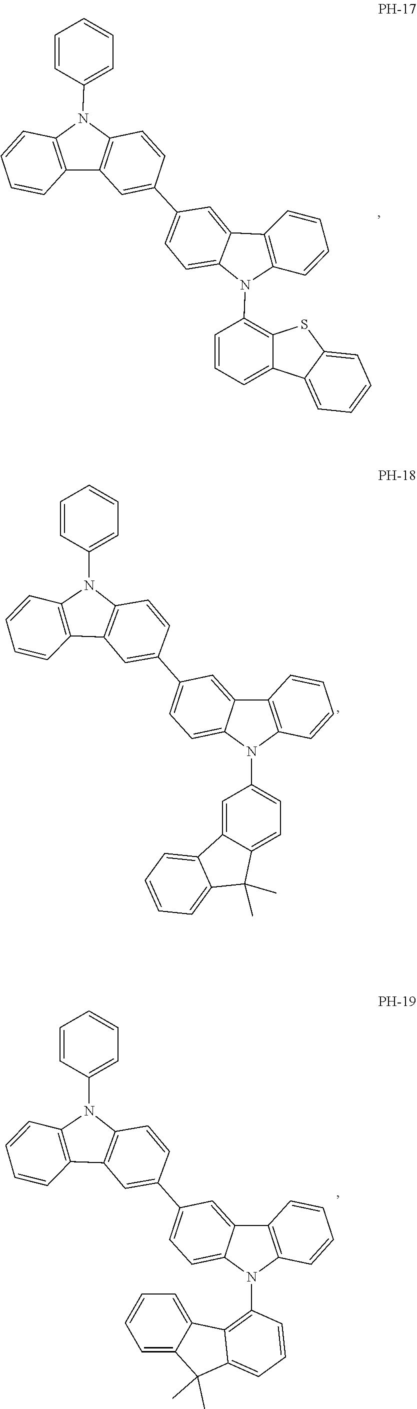 [SMILES: c1ccc(-n2c3ccccc3c3cc(-c4ccc5c(c4)c4ccccc4n5-c4cccc5c4sc4ccccc45)ccc32)cc1 ; CC1(C)c2ccccc2-c2cc(-n3c4ccccc4c4cc(-c5ccc6c(c5)c5ccccc5n6-c5ccccc5)ccc43)ccc21 ; CC1(C)c2ccccc2-c2c(-n3c4ccccc4c4cc(-c5ccc6c(c5)c5ccccc5n6-c5ccccc5)ccc43)cccc21]

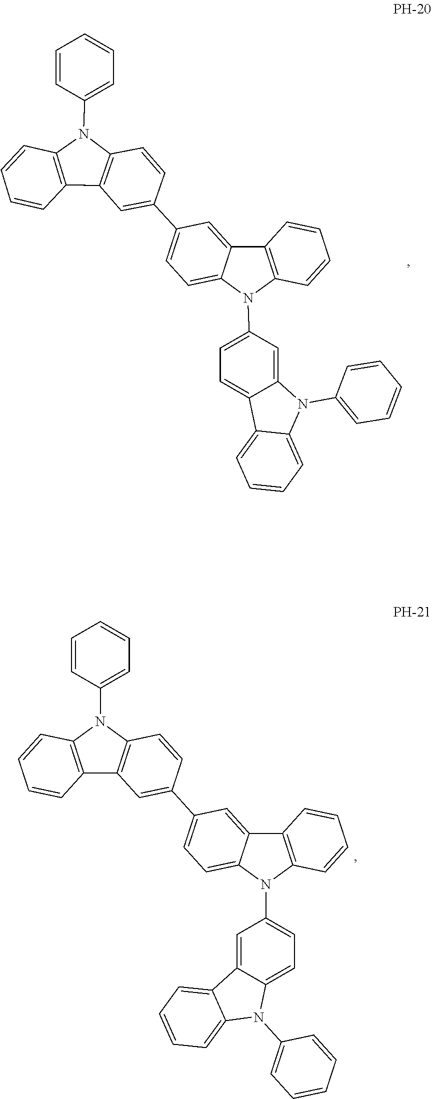 [SMILES: c1ccc(-n2c3ccccc3c3cc(-c4ccc5c(c4)c4ccccc4n5-c4ccc5c6ccccc6n(-c6ccccc6)c5c4)ccc32)cc1 ; c1ccc(-n2c3ccccc3c3cc(-c4ccc5c(c4)c4ccccc4n5-c4ccc5c(c4)c4ccccc4n5-c4ccccc4)ccc32)cc1]

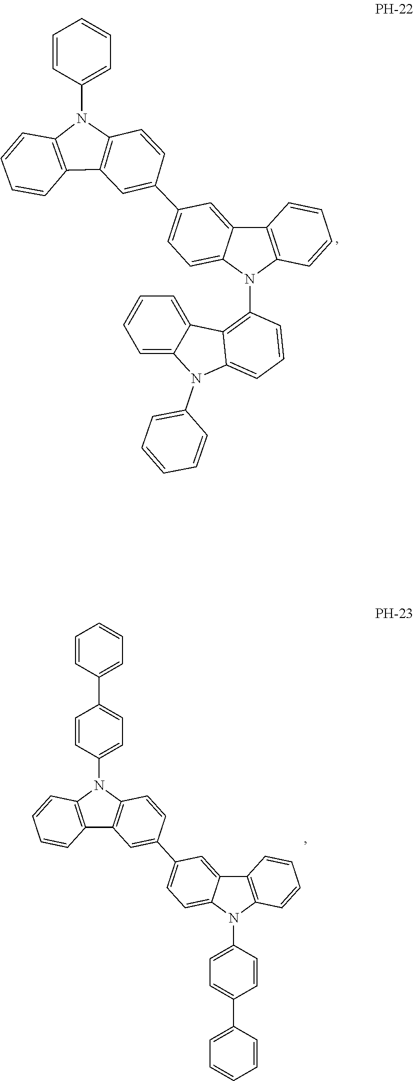 [SMILES: c1ccc(-n2c3ccccc3c3cc(-c4ccc5c(c4)c4ccccc4n5-c4cccc5c4c4ccccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

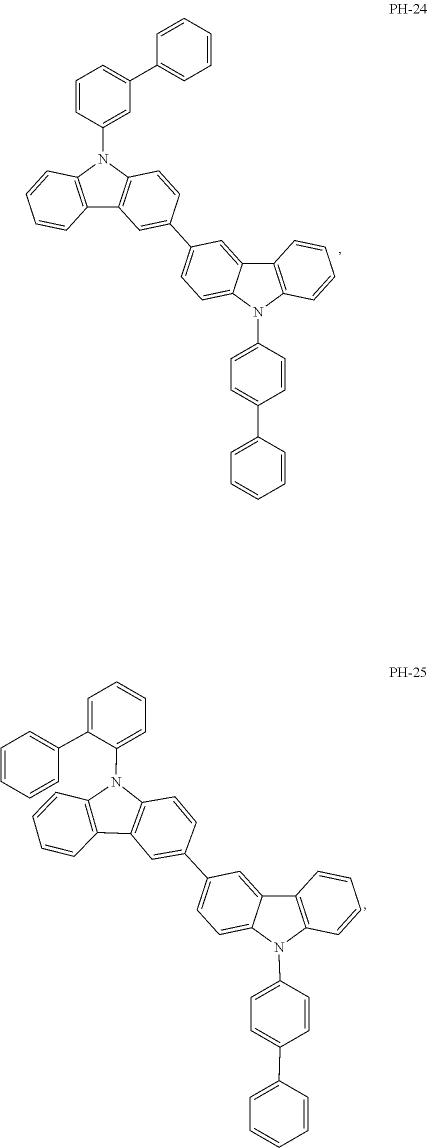 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5-c5ccccc5)ccc43)cc2)cc1]

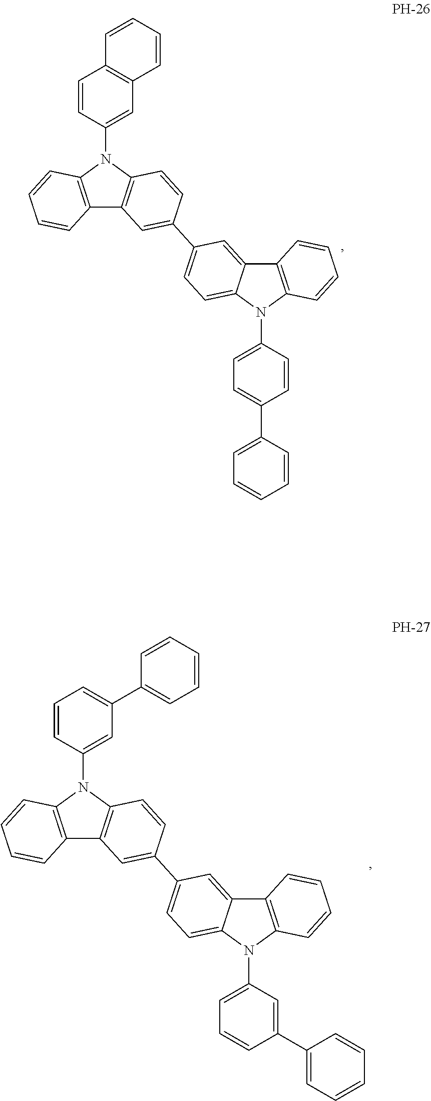 [SMILES: c1ccc(-c2ccc(-n3c4ccccc4c4cc(-c5ccc6c(c5)c5ccccc5n6-c5ccc6ccccc6c5)ccc43)cc2)cc1 ; c1ccc(-c2cccc(-n3c4ccccc4c4cc(-c5ccc6c(c5)c5ccccc5n6-c5cccc(-c6ccccc6)c5)ccc43)c2)cc1]

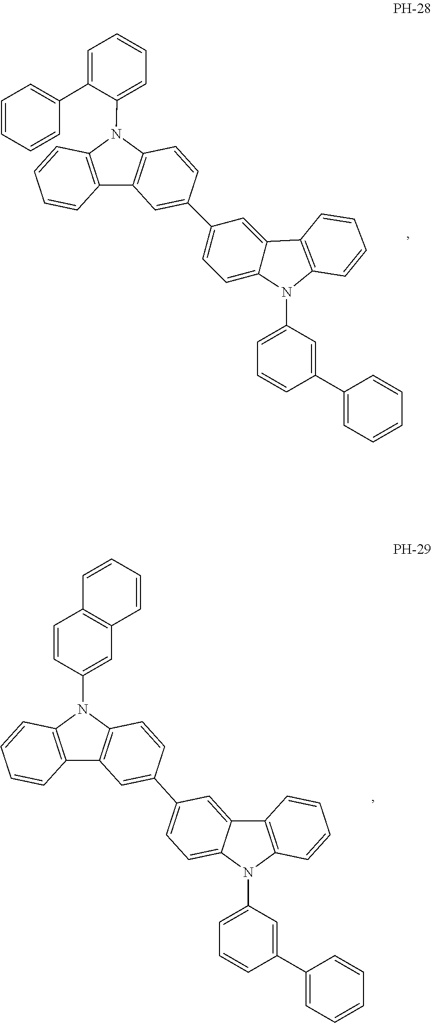 [SMILES: c1ccc(-c2cccc(-n3c4ccccc4c4cc(-c5ccc6c(c5)c5ccccc5n6-c5ccccc5-c5ccccc5)ccc43)c2)cc1 ; c1ccc(-c2cccc(-n3c4ccccc4c4cc(-c5ccc6c(c5)c5ccccc5n6-c5ccc6ccccc6c5)ccc43)c2)cc1]

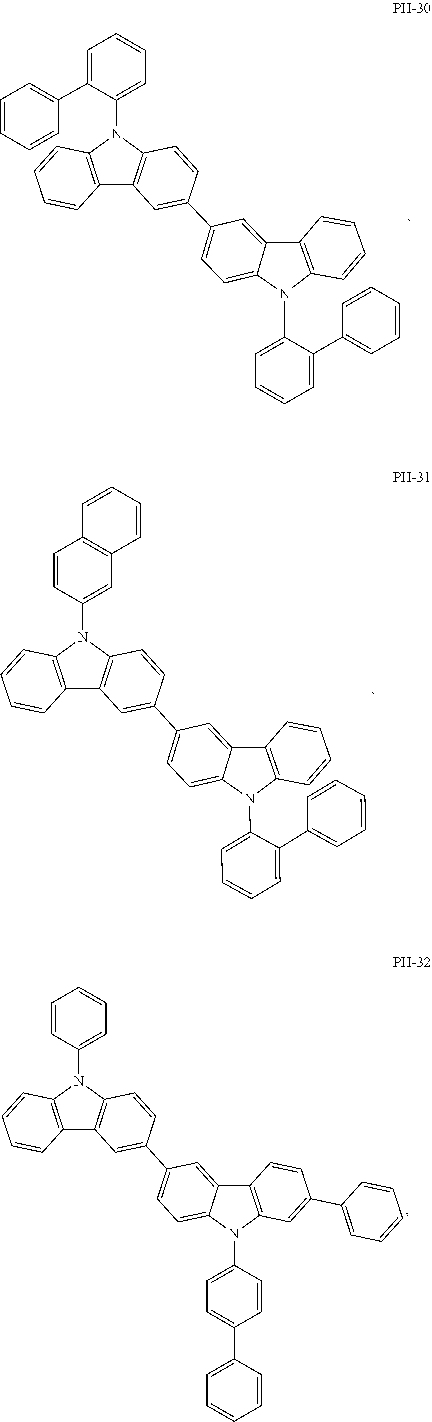 [SMILES: c1ccc(-c2ccccc2-n2c3ccccc3c3cc(-c4ccc5c(c4)c4ccccc4n5-c4ccccc4-c4ccccc4)ccc32)cc1 ; c1ccc(-c2ccccc2-n2c3ccccc3c3cc(-c4ccc5c(c4)c4ccccc4n5-c4ccc5ccccc5c4)ccc32)cc1 ; c1ccc(-c2ccc(-n3c4ccc(-c5ccc6c(c5)c5ccccc5n6-c5ccccc5)cc4c4ccc(-c5ccccc5)cc43)cc2)cc1]

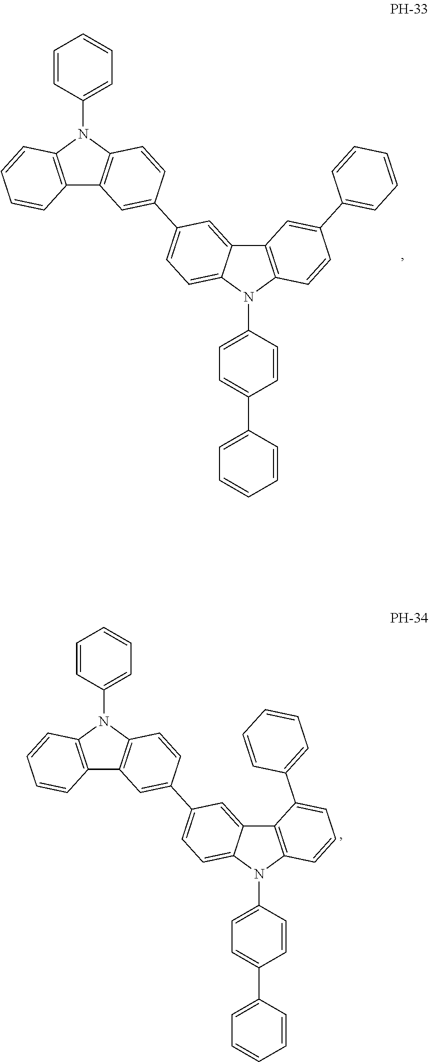 [SMILES: c1ccc(-c2ccc(-n3c4ccc(-c5ccccc5)cc4c4cc(-c5ccc6c(c5)c5ccccc5n6-c5ccccc5)ccc43)cc2)cc1 ; c1ccc(-c2ccc(-n3c4ccc(-c5ccc6c(c5)c5ccccc5n6-c5ccccc5)cc4c4c(-c5ccccc5)cccc43)cc2)cc1]

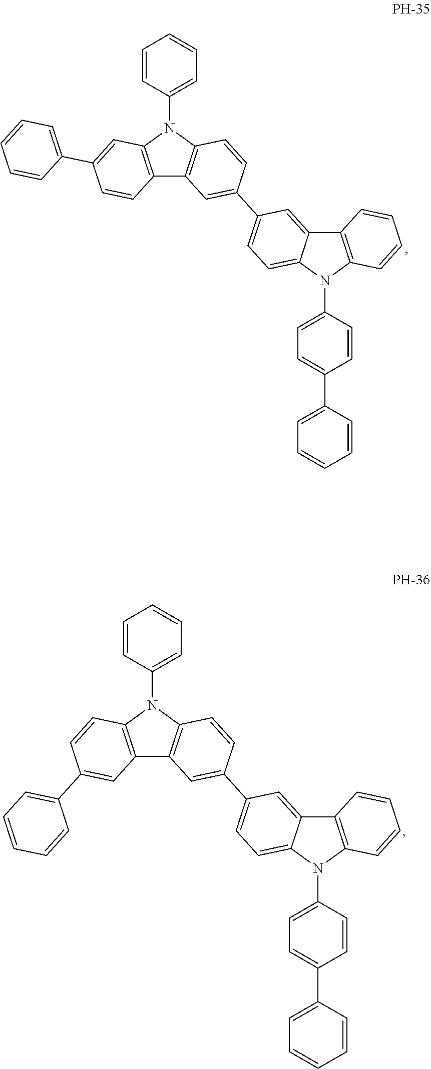 [SMILES: c1ccc(-c2ccc(-n3c4ccccc4c4cc(-c5ccc6c(c5)c5ccc(-c7ccccc7)cc5n6-c5ccccc5)ccc43)cc2)cc1 ; c1ccc(-c2ccc(-n3c4ccccc4c4cc(-c5ccc6c(c5)c5cc(-c7ccccc7)ccc5n6-c5ccccc5)ccc43)cc2)cc1]

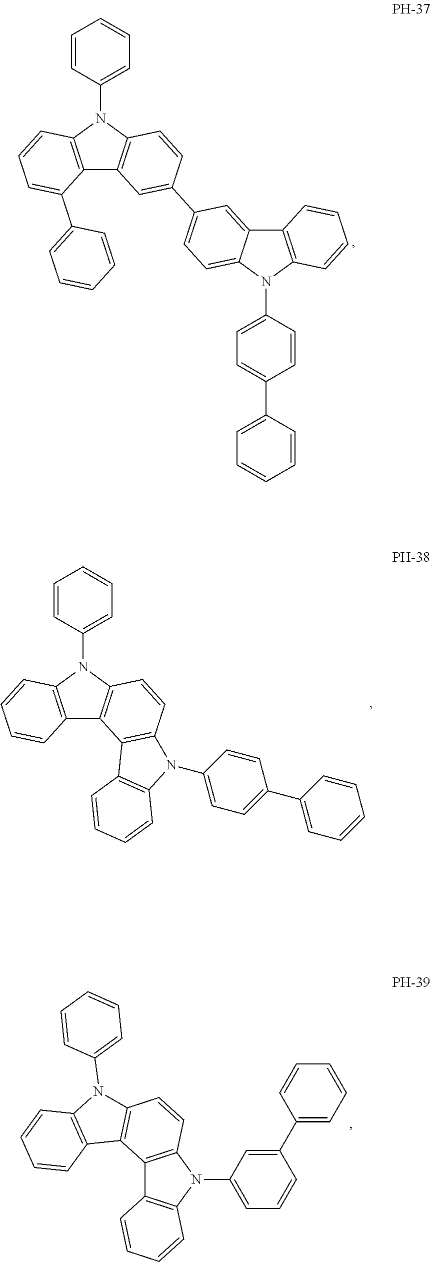 [SMILES: c1ccc(-c2ccc(-n3c4ccccc4c4cc(-c5ccc6c(c5)c5c(-c7ccccc7)cccc5n6-c5ccccc5)ccc43)cc2)cc1 ; c1ccc(-c2ccc(-n3c4ccccc4c4c5c6ccccc6n(-c6ccccc6)c5ccc43)cc2)cc1 ; c1ccc(-c2cccc(-n3c4ccccc4c4c5c6ccccc6n(-c6ccccc6)c5ccc43)c2)cc1]

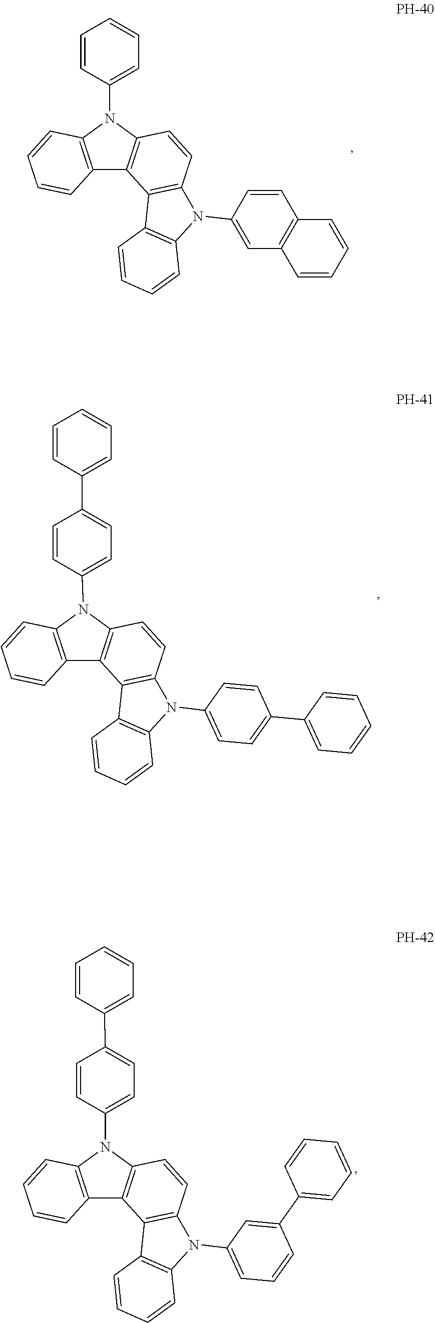 [SMILES: c1ccc(-n2c3ccccc3c3c4c5ccccc5n(-c5ccc6ccccc6c5)c4ccc32)cc1 ; c1ccc(-c2ccc(-n3c4ccccc4c4c5c6ccccc6n(-c6ccc(-c7ccccc7)cc6)c5ccc43)cc2)cc1 ; c1ccc(-c2ccc(-n3c4ccccc4c4c5c6ccccc6n(-c6cccc(-c7ccccc7)c6)c5ccc43)cc2)cc1]

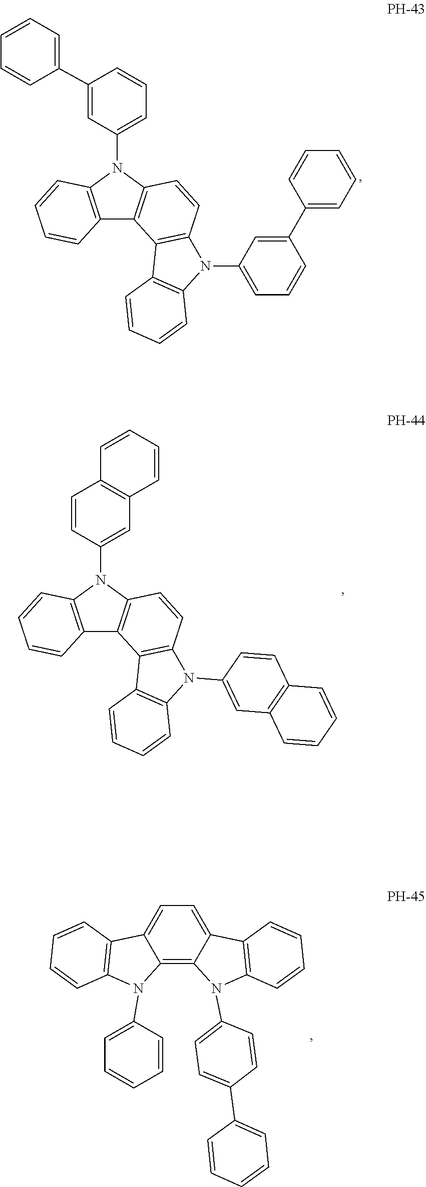 [SMILES: c1ccc(-c2cccc(-n3c4ccccc4c4c5c6ccccc6n(-c6cccc(-c7ccccc7)c6)c5ccc43)c2)cc1 ; c1ccc2cc(-n3c4ccccc4c4c5c6ccccc6n(-c6ccc7ccccc7c6)c5ccc43)ccc2c1 ; c1ccc(-c2ccc(-n3c4ccccc4c4ccc5c6ccccc6n(-c6ccccc6)c5c43)cc2)cc1]

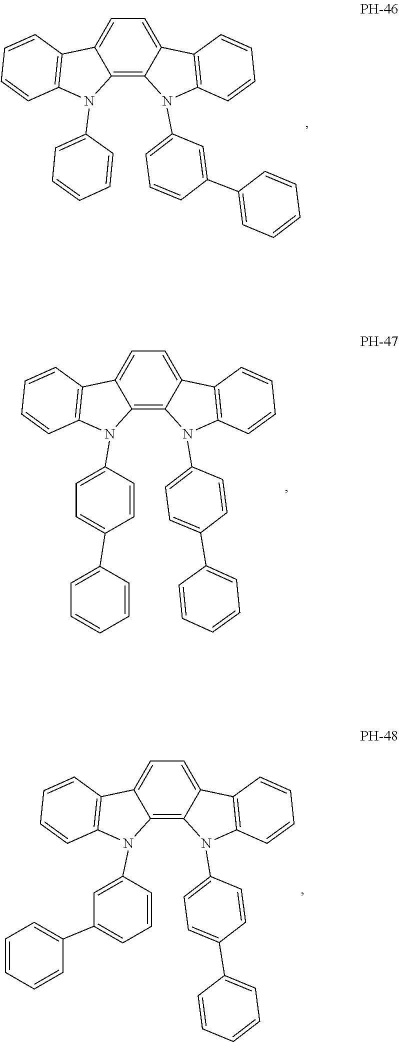 [SMILES: c1ccc(-c2cccc(-n3c4ccccc4c4ccc5c6ccccc6n(-c6ccccc6)c5c43)c2)cc1 ; c1ccc(-c2ccc(-n3c4ccccc4c4ccc5c6ccccc6n(-c6ccc(-c7ccccc7)cc6)c5c43)cc2)cc1 ; c1ccc(-c2ccc(-n3c4ccccc4c4ccc5c6ccccc6n(-c6cccc(-c7ccccc7)c6)c5c43)cc2)cc1]

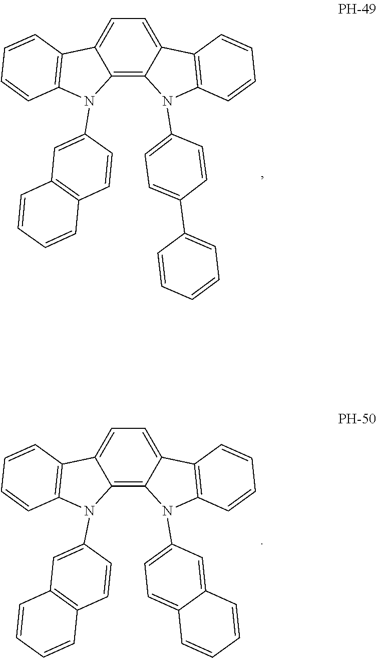 [SMILES: c1ccc(-c2ccc(-n3c4ccccc4c4ccc5c6ccccc6n(-c6ccc7ccccc7c6)c5c43)cc2)cc1 ; c1ccc2cc(-n3c4ccccc4c4ccc5c6ccccc6n(-c6ccc7ccccc7c6)c5c43)ccc2c1]

According to an embodiment of the present disclosure, in the electroluminescent device, the metal complex is doped in the first compound and the second compound, and the weight of the metal complex accounts for 1% to 30% of the total weight of the light-emitting layer.

According to an embodiment of the present disclosure, in the electroluminescent device, the metal complex is doped in the first compound and the second compound, and the weight of the metal complex accounts for 3% to 13% of the total weight of the light-emitting layer.

According to an embodiment of the present disclosure, the organic electroluminescent device further comprises a hole injection layer. The hole injection layer may be a functional layer comprising a single material or a functional layer comprising multiple materials, wherein the comprised multiple materials are most commonly used as hole transporting materials doped with a certain proportion of p-type conductive doping material. Common p-type doping materials are:

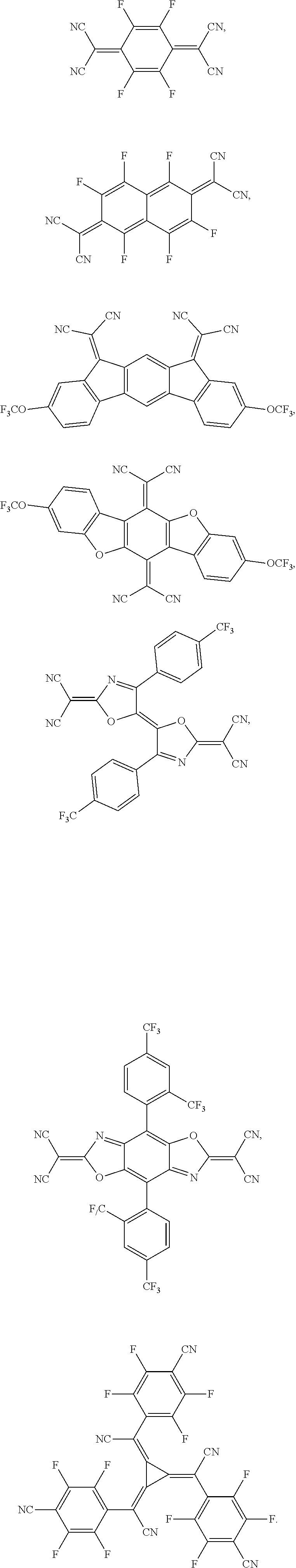

According to an embodiment of the present disclosure, a display assembly is disclosed. The display assembly comprises the organic electroluminescent device in any one of the preceding embodiments.

### Combination with Other Materials

The materials described in the present disclosure for a particular layer in an organic light-emitting device can be used in combination with various other materials present in the device. The combinations of these materials are described in more detail in U.S. Pat. App. Pub. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light-emitting device may be used in combination with a variety of other materials present in the device. For example, dopants disclosed herein may be used in combination with a wide variety of hosts, transport layers, blocking layers, injection layers, electrodes and other layers that may be present. The combination of these materials is described in detail in paragraphs 0080-0101 of U.S. Pat. App. Pub. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FATAR, life testing system produced by SUZHOU FATAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

In the present disclosure, an area ratio of an emission spectrum is calculated by the method below.

The photoluminescence (PL) spectrum data of a compound to be tested were measured using a fluorescence spectrophotometer F98 produced by SHANGHAI LENGGUANG TECHNOLOGY CO., LTD. The compound to be tested was prepared into a solution with a concentration of 1×10⁻⁶ mol/L with HPLC-grade toluene and then excited at room temperature (298 K) by light with any wavelength within ±30 nm of the absorption peak with a maximum wavelength, and the emission spectrum was measured. The emission spectrum has a maximum emission wavelength λₘₐₓ.

Then, the emission spectrum data were normalized (the normalization is to divide all emission intensity data by a maximum value of an emission intensity), and the luminescence area ratio was calculated by the method below.

When the maximum emission wavelength was λₘₐₓ and 490 nm<λₘₐₓ<580 nm, the calculation range was 500 nm to 650 nm. After the normalization of the spectrum, the area with an emission brightness of greater than 0.02 under the spectrum curve was integrated to obtain Area 1-1. The length between 500 nm and 650 nm was multiplied by the height between 0.02 and 1.00 to obtain that Area 1-2 was 147. The area ratio of the emission spectrum=[Area 1-1]/[Area 1-2]=[Area 1-1]/147=AR.

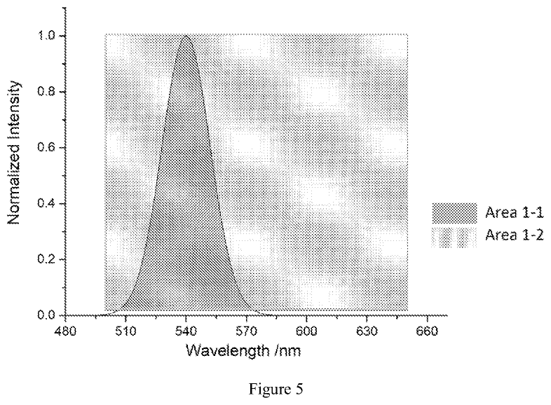

For the calculation of the area ratio of the emission spectrum, reference may be made to FIG. 5. FIG. 5 is a schematic diagram for calculating the area ratio of the emission spectrum, where the emission spectrum is a normalized photoluminescence spectrum, and its maximum emission wavelength is within a wavelength range where λₘₐₓ is located. The luminescence area ratio was calculated by the preceding method, the area of the dark part under the curve was Area 1-1, the area of the square covered by short black lines was Area 1-2, and AR was [Area 1-1]/[Area 1-2].

Metal Complex 17 of the present disclosure was used as an example, and the maximum emission wavelength of Metal Complex 17 was measured to be 520 nm. After the normalization of the spectrum, the area with an emission brightness of greater than 0.02 under the spectrum curve was integrated to obtain that Area 1-1 was 47.222. The length between 500 nm and 650 nm was multiplied by the height between 0.02 and 1.00 to obtain that Area 1-2 was 147. The area ratio of the emission spectrum A=[Area 1-1]/[Area 1-2]=47.222/147=0.321.

The calculated data of the maximum emission wavelengths of the photoluminescence spectra and the area ratios of the emission spectra of some metal complexes of the present application and comparative compounds are shown in Table 1.

TABLE 1
Maximum emission wavelengths of the photoluminescence spectra and
the area ratios of the emission spectra of the metal complexes

| | λₘₐₓ | | | λₘₐₓ | |
|---|---|---|---|---|---|
| Compound No. | (nm) | AR | Compound No. | (nm) | AR |
| Metal Complex 17 | 520 | 0.321 | GD3 | 529 | 0.384 |
| Metal Complex 23 | 522 | 0.330 | GD4 | 525 | 0.375 |
| Metal Complex 32 | 522 | 0.331 | GD5 | 526 | 0.405 |
| GD1 | 528 | 0.337 | GD6 | 529 | 0.381 |
| GD2 | 529 | 0.332 | GD7 | 529 | 0.378 |

The metal complexes involved above are shown as follows:

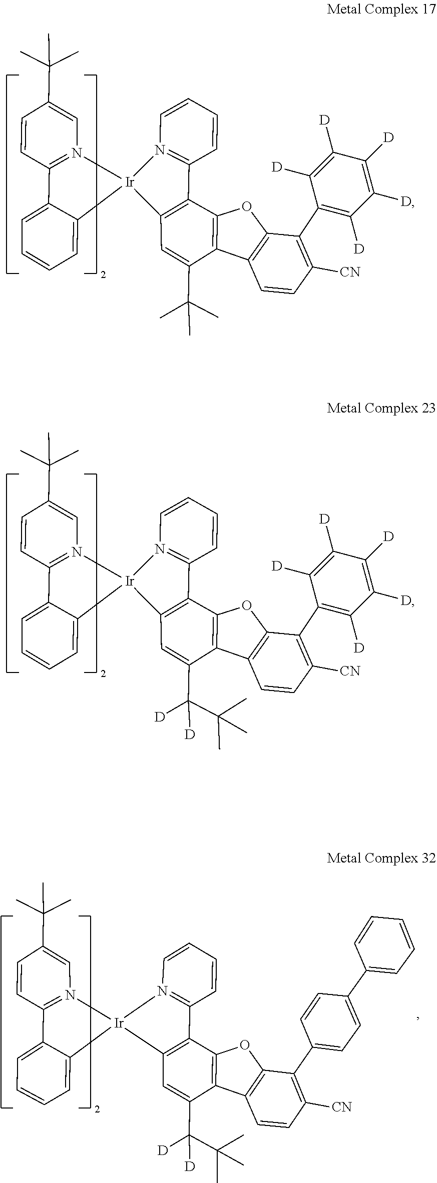

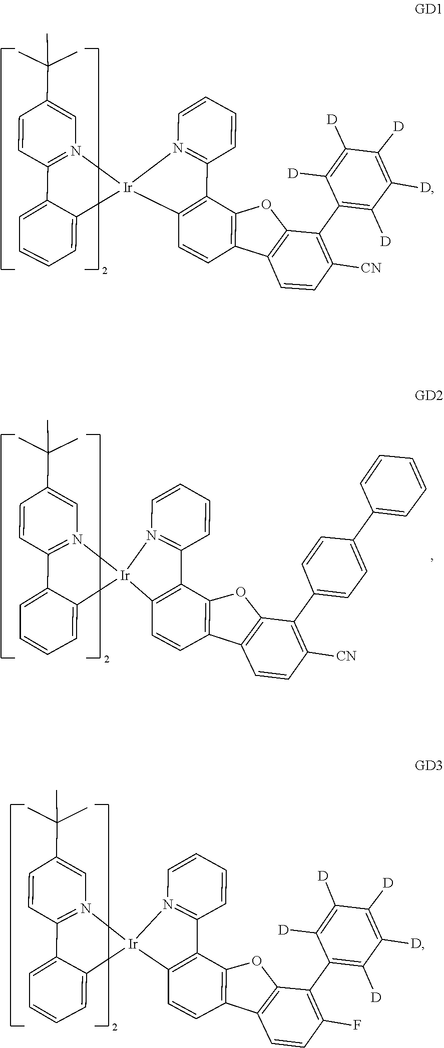

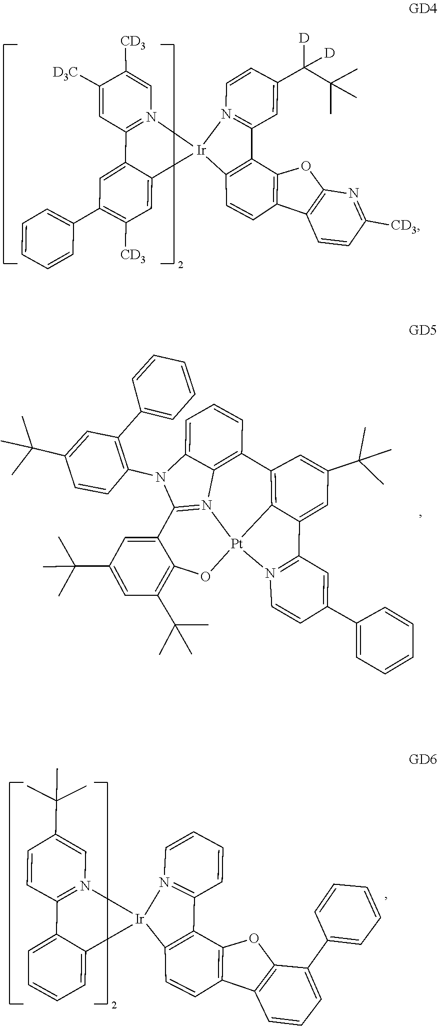

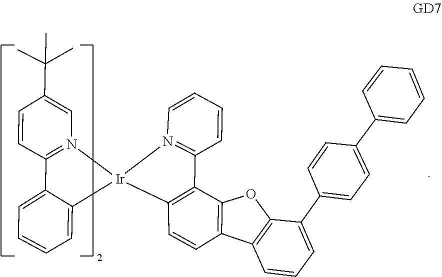

The electrochemical properties of a compound, a highest occupied molecular orbital energy level and a lowest unoccupied molecular orbital energy level, were measured by cyclic voltammetry (CV). The test used an electrochemical workstation CorrTest CS120 produced by Wuhan Corrtest Instruments Corp., Ltd and used a three-electrode working system where a platinum disk electrode served as a working electrode, a Ag/AgNO₃ electrode served as a reference electrode, and a platinum wire electrode served as an auxiliary electrode; anhydrous DMF was used as a solvent, 0.1 mol/L tetrabutylammonium hexafluorophosphate was used as a supporting electrolyte, the compound to be tested was prepared into a solution of 10⁻³ mol/L, and nitrogen was introduced into the solution for 10 min for oxygen removal before the test. The parameters of the instrument were set as follows: a scan rate was 100 mV/s, a potential interval was 0.5 mV, a test window of an oxidation potential was 0 V to 1 V, and a test window of a reduction potential was −1 V to −2.9 V. The energy levels of metal complexes and some compounds used in the present application are shown in the table below.

| Compound | HOMO | LUMO |
|---|---|---|
| Metal Complex 17 | −5.193 | −2.371 |
| Metal Complex 23 | −5.193 | −2.367 |
| Metal Complex 32 | −5.189 | −2.439 |
| GD1 | −5.199 | −2.396 |
| GD2 | −5.205 | −2.474 |
| GD3 | −5.142 | −2.144 |
| GD4 | −5.051 | −2.117 |
| GD5 | −5.155 | −2.577 |
| GD6 | −5.154 | −2.174 |
| GD7 | −5.144 | −2.211 |
| PH-23 | −5.45 | / |
| PH-1 | −5.46 | / |
| H-40 | / | −2.89 |

Test of the electroluminescence spectra of metal complexes

### Example 1

Firstly, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. Organic layers specified below were sequentially deposited through vacuum thermal evaporation on the ITO anode at a rate of 0.01 to 10 Å/s and a vacuum degree of about 10⁻⁶ Torr. Compound HI was used as a hole injection layer (HIL). Compound HT was used as a hole transporting layer (HTL). Compound PH-23 was used as an electron blocking layer (EBL). Metal Complex 17, Compound PH-23, and Compound H-40 of the present disclosure were co-deposited as an emissive layer (EML). On the EML, Compound H-2 was used as a hole blocking layer (HBL). On the HBL, Compound ET and 8-hydroxyquinolinolato-lithium (Liq) were co-deposited for use as an electron transporting layer (ETL). Finally, 8-hydroxyquinolinolato-lithium (Liq) was deposited for use as an electron injection layer with a thickness of 1 nm and Al was deposited for use as a cathode with a thickness of 120 nm. The device was transferred back to the glovebox and encapsulated with a glass lid to complete the device.

### Example 2

The implementation manner of Example 2 was the same as that of Example 1 except that in the EML, Metal Complex 17 of the present disclosure was replaced with Metal Complex 32 of the present disclosure.

### Example 3

The implementation manner of Example 3 was the same as that of Example 1 except that in the EML, Metal Complex 17 of the present disclosure was replaced with Metal Complex 23 of the present disclosure.

### Comparative Example 1

The implementation manner of Comparative Example 1 was the same as that of Example 1 except that in the EML, Metal Complex 17 of the present disclosure was replaced with GD1.

### Comparative Example 2

The implementation manner of Comparative Example 2 was the same as that of Example 1 except that in the EML, Metal Complex 17 of the present disclosure was replaced with GD2.

### Comparative Example 3

The implementation manner of Comparative Example 3 was the same as that of Example 1 except that in the EML, Metal Complex 17 of the present disclosure was replaced with GD3.

### Comparative Example 4

The implementation manner of Comparative Example 4 was the same as that of Example 1 except that in the EML, Metal Complex 17 of the present disclosure was replaced with GD4.

### Comparative Example 5

The implementation manner of Comparative Example 5 was the same as that of Example 1 except that in the EML, Metal Complex 17 of the present disclosure was replaced with GDS.

### Comparative Example 6

The implementation manner of Comparative Example 6 was the same as that of Example 1 except that in the EML, Metal Complex 17 of the present disclosure was replaced with GD6.

### Comparative Example 7

The implementation manner of Comparative Example 7 was the same as that of Example 1 except that in the EML, Metal Complex 17 of the present disclosure was replaced with GD7.

Detailed structures and thicknesses of layers of the devices are shown in the following table. A layer using more than one material is obtained by doping different compounds at their weight ratio as recorded.

TABLE 2
Device structures of Examples 1 to 3 and Comparative Examples 1 to 7

| Device ID | HIL | HTL | EBL | EML | HBL | ETL |
|---|---|---|---|---|---|---|
| Example 1 | Compound | Compound | Compound | Compound | Compound | Compound |
| | HI (100 Å) | HT (350 | PH-23 (50 | PH-23:Compound | H-2 (50 Å) | ET:Liq |
| | | Å) | Å) | H-40:Metal | | (40:60) |
| | | | | Complex 17 | | (350 Å) |
| | | | | (56:38:6)(400 Å) | | |
| Example 2 | Compound | Compound | Compound | Compound | Compound | Compound |
| | HI (100 Å) | HT (350 | PH-23 (50 | PH-23:Compound | H-2 (50 Å) | ET:Liq |
| | | Å) | Å) | H-40:Metal | | (40:60) |
| | | | | Complex 32 | | (350 Å) |
| | | | | (56:38:6)(400 Å) | | |
| Example 3 | Compound | Compound | Compound | Compound | Compound | Compound |
| | HI (100 Å) | HT (350 | PH-23 (50 | PH-23:Compound | H-2 (50 Å) | ET:Liq |
| | | Å) | Å) | H-40:Metal | | (40:60) |
| | | | | Complex 23 | | (350 Å) |
| | | | | (56:38:6)(400 Å) | | |
| Comparative | Compound | Compound | Compound | Compound | Compound | Compound |
| Example 1 | HI (100 Å) | HT (350 | PH-23 (50 | PH-23:Compound | H-2 (50 Å) | ET:Liq |
| | | Å) | Å) | H-40:GD1 | | (40:60) |
| | | | | (56:38:6) (400 Å) | | (350 Å) |
| Comparative | Compound | Compound | Compound | Compound | Compound | Compound |
| Example 2 | HI (100 Å) | HT (350 | PH-23 (50 | PH-23:Compound | H-2 (50 Å) | ET:Liq |
| | | Å) | Å) | H-40:GD2 | | (40:60) |
| | | | | (56:38:6) (400 Å) | | (350 Å) |
| Comparative | Compound | Compound | Compound | Compound | Compound | Compound |
| Example 3 | HI (100 Å) | HT (350 | PH-23 (50 | PH-23:Compound | H-2 (50 Å) | ET:Liq |
| | | Å) | Å) | H-40:GD3 | | (40:60) |
| | | | | (56:38:6) (400 Å) | | (350 Å) |
| Comparative | Compound | Compound | Compound | Compound | Compound | Compound |
| Example 4 | HI (100 Å) | HT (350 | PH-23 (50 | PH-23:Compound | H-2 (50 Å) | ET:Liq |
| | | Å) | Å) | H-40:GD4 | | (40:60) |
| | | | | (56:38:6) (400 Å) | | (350 Å) |
| Comparative | Compound | Compound | Compound | Compound | Compound | Compound |
| Example 5 | HI (100 Å) | HT (350 | PH-23 (50 | PH-23:Compound | H-2 (50 Å) | ET:Liq |
| | | Å) | Å) | H-40:GD5 | | (40:60) |
| | | | | (56:38:6) (400 Å) | | (350 Å) |
| Comparative | Compound | Compound | Compound | Compound | Compound | Compound |
| Example 6 | HI (100 Å) | HT (350 | PH-23 (50 | PH-23:Compound | H-2 (50 Å) | ET:Liq |
| | | Å) | Å) | H-40:GD6 | | (40:60) |
| | | | | (56:38:6) (400 Å) | | (350 Å) |
| Comparative | Compound | Compound | Compound | Compound | Compound | Compound |
| Example 7 | HI (100 Å) | HT (350 | PH-23 (50 | PH-23:Compound | H-2 (50 Å) | ET:Liq |
| | | Å) | Å) | H-40:GD7 | | (40:60) |
| | | | | (56:38:6) (400 Å) | | (350 Å) |

The materials used in the devices have the following structures:

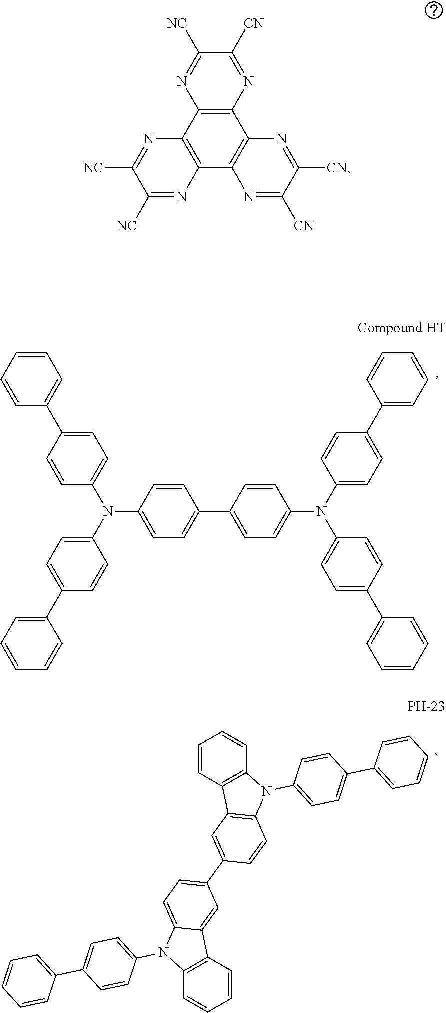 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

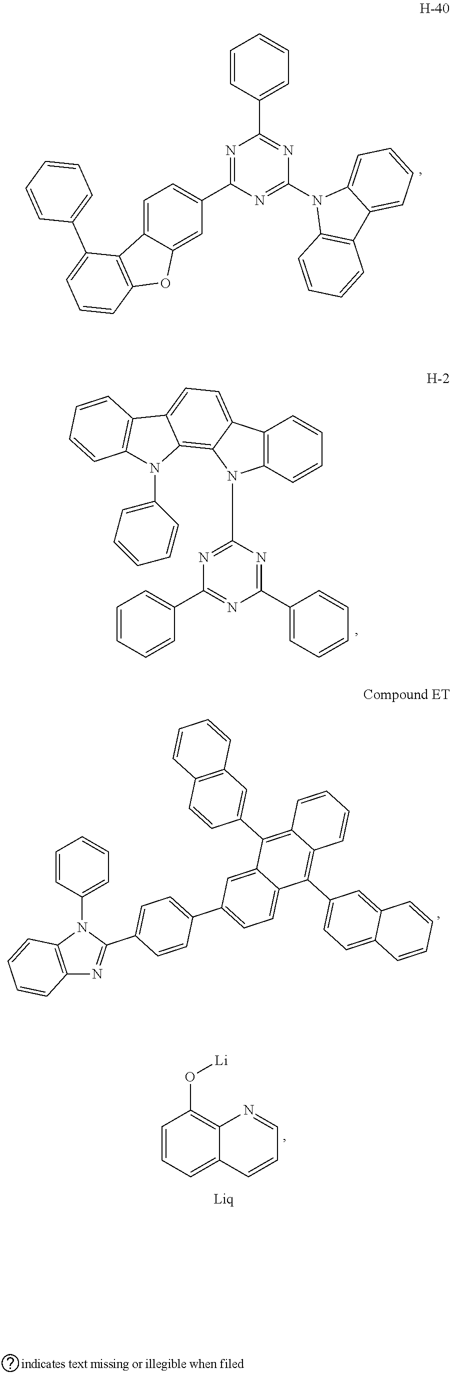

The current-voltage-luminance (IVL) characteristics of the devices were measured. The CIE data, maximum emission wavelength λ_{MAX}, and full width at half maxima (FWHM) of the device were measured at 1000 cd/m 2. The data are recorded and shown in Table 3.

TABLE 3
Device data of Examples 1 to 3 and Comparative Examples 1 to 7

| Device ID | CIE (x, y) | λ_{MAX} (nm) | FWHM (nm) |
|---|---|---|---|
| Example 1 | (0.293, 0.663) | 522 | 30.1 |
| Example 2 | (0.296, 0.661) | 522 | 31.0 |
| Example 3 | (0.299, 0.659) | 522 | 32.3 |
| Comparative Example 1 | (0.344, 0.634) | 532 | 35.8 |
| Comparative Example 2 | (0.343, 0.635) | 531 | 34.7 |
| Comparative Example 3 | (0.351, 0.624) | 531 | 57.6 |
| Comparative Example 4 | (0.340, 0.630) | 525 | 58.7 |
| Comparative Example 5 | (0.326, 0.634) | 525 | 59.4 |
| Comparative Example 6 | (0.351, 0.624) | 531 | 58.0 |
| Comparative Example 7 | (0.353, 0.623) | 531 | 59.0 |

Discussion:

As can be seen from Table 3, for the devices in Examples 1 to 3, λ_{MAX} (that is, the maximum emission wavelength of the electroluminescence spectrum of the metal complex) each was 522 nm, which was less than 524 nm; and the FWHMs were 30.1 nm, 31.0 nm, and 32.3 nm, respectively, which were all significantly less than 34.7 nm. The metal complexes used in Comparative Examples 1 to 3 and Examples 1 to 3 had similar skeletons, and in Comparative Examples 1 to 3, λ_{MAX} was 532 nm, 531 nm, and 531 nm, respectively, and the FWHMs were 35.8 nm, 34.7 nm, and 57.6 nm, respectively. Compared with Examples 1 to 3, Comparative Examples 1 to 3 all showed different degrees of red shifts and wider FWHMs, and particularly, the FWHM of Comparative Example 3 was 20 nm wider. Although λₘₐₓ in Comparative Examples 4 and 5 both reached 525 nm, which indicates more saturated green light emission, the FWHMs of Comparative Examples 4 and 5 were both very wide, which were 58.7 nm and 59.4 nm, respectively. The metal complexes used in Comparative Examples 6 to 7 and Examples 1 to 3 had similar skeletons, λ_{MAX} in Comparative Examples 6 to 7 was both 531 nm, and the FWHMs of Comparative Examples 6 to 7 were 58.0 nm and 59.0 nm, respectively. Compared with Examples 1 to 3, Comparative Examples 6 to 7 showed different degrees of red shifts and more than 23 nm wider FWHMs.

Meanwhile, the peak area ratios (AR) of the metal complexes used in Examples 1 to 3 were 0.321, 0.330, and 0.331, respectively, all of which were less than or equal to 0.331. The peak area ratios of the metal complexes used in the comparative examples were all greater than 0.331. Even if the metal complex GD2 used in Comparative Example 2 had a peak area ratio AR of 0.332 and had the same skeleton as the metal complexes used in the examples, the luminescence performance of Examples 1 to 3 was significantly better than that of Comparative Example 2.

As can be seen from the above, λ_{MAX} in Examples 1 to 3 had obvious blue shifts relative to Comparative Examples 1 to 7, the FWHMs of Examples 1 to 3 were narrowed, CIEx in Examples 1 to 3 was all less than 0.300, and CIEy in Examples 1 to 3 was all greater than 0.650. Comparative Examples 1 to 7 had the contrary data, indicating that Examples 1 to 3 have more saturated luminescence.

Examples of top-emitting devices: To study the device performance of the metal complex most approaching the BT.2020 luminescence requirement, the microcavities of the following top-emitting devices were all adjusted to CIEx=0.170, and the device performance at this time was recorded; meanwhile, to investigate whether the device performance of the device approaching the BT.2020 luminescence requirement has reached the best performance of the device and a gap with the best performance of the device, the microcavities of the following top-emitting devices were adjusted until the devices reach maximum current efficiency, and the device performance at this time was recorded. As mentioned above about the top-emitting device, due to different refractive indexes of different metal complexes, the top-emitting devices comprising these different metal complexes may have slightly different microcavity lengths, that is, the HTLs have slightly different thicknesses.

Example 4: Metal Complex 17 was applied to a top-emitting device, as described specifically below.

Firstly, a 0.7 mm thick glass substrate was pre-patterned with ITO 75 Å/Ag 1500 Å/ITO 150 Å as an anode, where 150 Å ITO deposited on Ag had a hole injection function. Then, the substrate was dried in a glovebox to remove moisture, mounted on a holder, and transferred into a vacuum chamber. Organic layers specified below were sequentially deposited through vacuum thermal evaporation on the anode at a rate of 0.01 to 10 Å/s and a vacuum degree of about 10⁻⁶ Torr. Compound HT and Compound PD were co-deposited as a hole injection layer (HIL, 97:3, 100 Å). On the HIL, Compound HT was deposited as a hole transporting layer (HTL) (where the HTL also served as a microcavity adjustment layer, and the microcavity was adjusted within a range of 1000 to 1500 Å). On the HTL, Compound PH-23 was deposited as an electron blocking layer (EBL, 50 Å). Then, Metal Complex 17, Compound PH-1, and Compound H-40 of the present disclosure were co-deposited as an emissive layer (EML, 4:48:48, 400 Å). Compound H-2 was deposited as a hole blocking layer (HBL, 50 Å). Compound ET and Liq were co-deposited as an electron transporting layer (ETL, 40:60, 350 Å). A metal Yb was deposited as an electron injection layer (EIL, 10 Å). Metals Ag and Mg were co-deposited at a ratio of 9:1 as a cathode (140 Å). Compound CP (a material with a refractive index of about 2.01 at 530 nm) was deposited as a capping layer with a thickness of 800 Å. The device was transferred back to the glovebox and encapsulated with a glass lid in a nitrogen atmosphere to complete the device. The CEₘₐₓ of the device was obtained by adjusting the microcavity to about 1410 Å (that is, the thickness of the HTL was about 1410 Å), and then the CEₘₐₓ₂ at CIEx 0.170 of the device was obtained by adjusting microcavity to about 1370 Å.

### Example 5

The implementation manner of Example 5 was the same as that of Example 4 except that in the EML, Metal Complex 17 of the present disclosure was replaced with Metal Complex 32 of the present disclosure. The CEₘₐₓ of the device was obtained by adjusting the microcavity to about 1340 Å, and then the CEₘₐₓ₂ at CIEx 0.170 of the device was obtained by adjusting microcavity to about 1340 Å.

### Comparative Example 8

The implementation manner of Comparative Example 8 was the same as that of Example 4 except that in the EML, Metal Complex 17 of the present disclosure was replaced with GD2. The CEₘₐₓ of the device was obtained by adjusting the microcavity to about 1370 Å, and then the CEₘₐₓ₂ at CIEx 0.170 of the device was obtained by adjusting microcavity to about 1410 Å.

The structures and thicknesses of some layers of the devices are shown in the following table. A layer using more than one material is obtained by doping different compounds at their weight ratio as recorded.

TABLE 4
Part of device structures of Examples 4 to 5 and Comparative Example 8

| Device ID | HIL | HTL | EBL | EML | HBL | ETL |
|---|---|---|---|---|---|---|
| Example 4 | Compound | Compound | Compound | Compound | Compound | Compound |
| | HT:Compound | HT | PH-23 | PH-1:Compound | H-2 (50 | ET:Liq |
| | PD (97:3) | | (50 Å) | H-40:Metal | Å) | (40:60) |
| | (100 Å) | | | Complex 17 | | (350 Å) |
| | | | | (48:48:4) (400 | | |
| | | | | Å) | | |
| Example 5 | Compound | Compound | Compound | Compound | Compound | Compound |
| | HT:Compound | HT | PH-23 | PH-1:Compound | H-2 (50 | ET:Liq |
| | PD (97:3) | | (50 Å) | H-40:Metal | Å) | (40:60) |
| | (100 Å) | | | Complex 32 | | (350 Å) |
| | | | | (48:48:4) (400 | | |
| | | | | Å) | | |
| Comparative | Compound | Compound | Compound | Compound | Compound | Compound |
| Example 8 | HT:Compound | HT | PH-23 | PH-1:Compound | H-2 (50 | ET:Liq |
| | PD (97:3) | | (50 Å) | H-40:GD2 | Å) | (40:60) |
| | (100 Å) | | | (48:48:4) (400 | | (350 Å) |
| | | | | Å) | | |

The new materials used in the devices have the following structures:

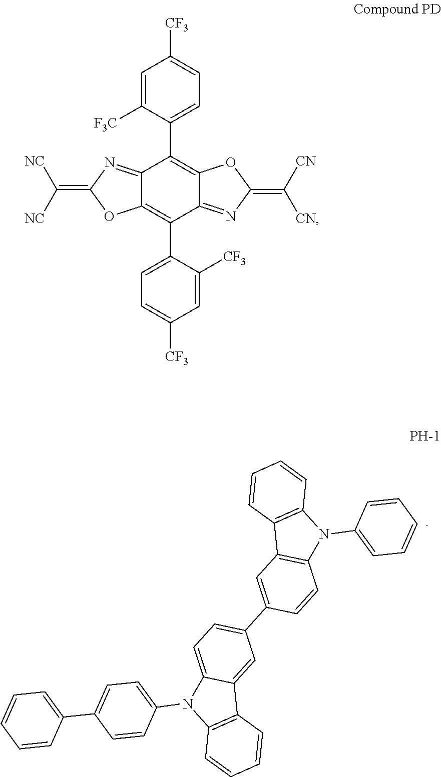 [SMILES: N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; c1ccc(-c2ccc(-n3c4ccccc4c4cc(-c5ccc6c(c5)c5ccccc5n6-c5ccccc5)ccc43)cc2)cc1]

The IVL characteristics of the devices were measured. At a constant current of 10 mA/cm², the external quantum efficiency (EQEₘₐₓ) and CIE (x, y) of the top-emitting device at the maximum current efficiency (CEₘₐₓ) were recorded, and the distance D was calculated; and at a constant current of 10 mA/cm², the corresponding CEₘₐₓ₂, the external quantum efficiency (EQEₘₐₓ₂), and the ratio of CEₘₐₓ₂ to CEₘₐₓ of the device were recorded when CIEx in the color coordinates CIE (x, y) was 0.170. The data are recorded and shown in Table 5.

TABLE 5
Data of Examples 4 to 5 and Comparative Example 8

| | | | CEₘₐₓ | EQEₘₐₓ | CEₘₐₓ₂ | EQEₘₐₓ₂ | CEₘₐₓ₂/ |
|---|---|---|---|---|---|---|---|
| Device ID | D | CIE (x, y) | (cd/A) | (%) | (cd/A) | (%) | CEₘₐₓ |
| Example 4 | 0.0219 | (0.172, | 160 | 38.7 | 156 | 38.00 | 97.50% |
| | | 0.775) | | | | | |
| Example 5 | 0.0178 | (0.164, | 173 | 42.27 | 171 | 41.29 | 98.84% |
| | | 0.780) | | | | | |
| Comparative | 0.0614 | (0.215, | 194 | 43.77 | 147 | 35.45 | 75.77% |
| Example 8 | | 0.755) | | | | | |

Discussion:

As can be seen from Table 1, the light-emitting materials used in Examples 4 to 5 were Metal Complexes 17 and 32 of the present disclosure, and the area ratios of the emission spectra of Metal Complexes 17 and 32 were 0.321 and 0.331, respectively, which were both less than or equal to 0.331; the light-emitting material used in Comparative Example 8 was GD2 with the same skeleton as the light-emitting materials of the present disclosure, and the area ratio of the emission spectrum of GD2 was 0.332.

As can be seen from the test of the electroluminescence spectra of the metal complexes in Table 3, λ_{MAX} of the EL spectra of the light-emitting materials of the present disclosure used in Examples 4 to 5 was both 522 nm, which was less than 524 nm, and the FWHMs were 30.1 nm and 31.0 nm respectively, which were both less than 34.7 nm; λ_{MAX} of the EL spectrum of the light-emitting material used in Comparative Example 2, which had the same skeleton as the light-emitting materials of the present disclosure, was 531 nm, and the FWHM was 34.7 nm. Compared with Examples 4 to 5, Comparative Example 2 showed obviously red-shifted λ_{MAX} and wider FWHM.

As can be seen from Table 5, in Examples 4 and 5, the distance D between the color coordinates CIE (x, y) of the top-emitting device of the light-emitting material of the present disclosure at CEₘₐₓ and the color coordinates CIE (0.170, 0.797) of green light in BT.2020 was 0.0219 and 0.0178 respectively, which were both less than 0.0300; and the distance D for the light-emitting material used in Comparative Example 8 having the same skeleton as the light-emitting materials of the present disclosure was 0.0614. It indicates that Examples 4 and 5 have a significantly shorter distance from the color coordinates CIE (0.170, 0.797) of green light in BT.2020 than Comparative Example 8 and have more saturated green light emission and wider BT.2020 coverage.

As can also be seen from Table 5, CEₘₐₓ in Comparative Example 8 was as high as 194 cd/A, which was 21.3% and 12.1% higher than those (160 cd/A, 173 cd/A) in Examples 4 and 5, respectively; and EQEₘₐₓ in Comparative Example 8 reached 43.77%, which was 13.1% and 3.5% higher than those in Examples 4 and 5, respectively. However, at CIEx=0.170, CEₘₐₓ₂ in Comparative Example 8 was only 147 cd/A, which was 24.22% lower than CEₘₐₓ, and was 9 cd/A and 24 cd/A, i.e., 5.8% and 14.0%, lower than CEₘₐₓ₂ (156 cd/A, 171 cd/A) in Examples 4 and 5, respectively; EQEₘₐₓ₂ in Comparative Example 8 was only 35.45%, which was 8.32% lower than EQEₘₐₓ and was 2.55% and 5.84% lower than EQEₘₐₓ₂ in Examples 4 and 5, respectively.

Meanwhile, in Examples 4 and 5, CEₘₐₓ differed from CEₘₐₓ₂ obtained at x=0.170, which is required in the color coordinates CIE (0.170, 0.797) of green light in BT.2020, by only 4 cd/A and 2 cd/A, respectively, and CEₘₐₓ₂ even reached 97.50% and 98.84% of CEₘₐₓ, respectively. The small difference between CEₘₐₓ₂ and CEₘₐₓ is more conducive to the use of BT.2020 green phosphorescent materials in devices and not only satisfies more saturated green light emission but also satisfies maximum CE of BT.2020 green light emission, which is commendable. Although CEₘₐₓ and EQEmax in Comparative Example 8 were very high, CEₘₐₓ₂ and EQEₘₐₓ₂ decreased very obviously when applied to a BT.2020 device (that is, when CIEx is 0.170), further indicating that the metal complex of the present disclosure has better performance of saturated green light emission and high efficiency in BT.2020 green light-emitting devices.

To conclude, when applied to devices, the metal complex of the present disclosure has higher device efficiency and more saturated green light emission, better approaches the commercially expected BT.2020 requirements, and has a broader commercial application prospect than a metal complex that does not satisfy the emission distance D and the area ratio AR of the spectrum.

### SIMULATION EXAMPLES OF TOP-EMITTING DEVICES

In conjunction with the device structure shown in FIG. 4, simulation was performed using Setfos 5.0 semiconductor thin-film optical simulation software developed by FLUXiM in the present disclosure.

### Simulation Example 1

A device structure the same as Example 4 was designed and the PL spectrum data of Metal Complex 17 of the present disclosure were inputted into the Setfos 5.0 semiconductor thin-film optical simulation software developed by FLUXiM for simulation and calculation.

### Simulation Example 2

A device structure the same as Example 5 was designed and the PL spectrum data of Metal Complex 32 of the present disclosure were inputted into the Setfos 5.0 semiconductor thin-film optical simulation software developed by FLUXiM for simulation and calculation.

### Simulation Comparative Example 1

A device structure the same as Comparative Example 8 was designed and the PL spectrum data of GD2 were inputted into the Setfos 5.0 semiconductor thin-film optical simulation software developed by FLUXiM for simulation and calculation.

Through the tests of the above simulation examples and comparative example, a set of correspondences between current efficiency (CE) and color coordinates CIE (x, y) can be obtained. The corresponding color coordinates CIE (x, y) at CEₘₐₓ were obtained, and the distance D from the color coordinates CIE (0.170, 0.797) of green light in BT.2020 were recorded; and when CIEx in the color coordinates CIE (x, y) was 0.170, the corresponding current efficiency CEₘₐₓ₂ of the simulated device and the ratio of CEₘₐₓ₂ to CEₘₐₓ were recorded.

The data are recorded and shown in Table 6.

TABLE 6
Data of Simulation Examples 1 and 2
and Simulation Comparative Example 1

| | | | CEₘₐₓ | CEₘₐₓ₂ | CEₘₐₓ₂/ |
|---|---|---|---|---|---|
| Device ID | D | CIE (x, y) | (cd/A) | (cd/A) | CEₘₐₓ |
| Simulation | 0.0262 | (0.173, 0.771) | 169 | 169 | 100.00% |
| Example 1 | | | | | |
| Simulation | 0.0217 | (0.171, 0.775) | 169 | 169 | 100.00% |
| Example 2 | | | | | |
| Simulation | 0.0714 | (0.222, 0.748) | 178 | 140 | 78.65% |
| Comparative | | | | | |
| Example 1 | | | | | |

Discussion:

As can be seen from Table 6, when Simulation Examples 1 and 2 and Simulation Comparative Example 1 reached CEₘₐₓ, the D values and CEₘₐₓ₂/CEₘₐₓ exhibited the same laws as the measured values recorded in Table 5. That is, in the measured top-emitting device examples, D in Comparative Example 8>D in Example 4>D in Example 5; similarly, in the simulation device examples, D in Simulation Comparative Example 1>D in Simulation Example 1>D in Simulation Example 2. Meanwhile, CEₘₐₓ₂/CEₘₐₓ also follows the same conclusion.

To conclude, it indicates that the device data results obtained by the method of simulating the device examples in the present application have the same laws as the data results obtained by measuring the structures. Therefore, the data results of the devices simulated by the method have a great guidance effect on further researches.

The following devices were further simulated.

### Simulation Example 3

The simulation manner of Simulation Example 3 is the same as that of Simulation Example 1 except that the PL spectrum data of Metal Complex 17 of the present disclosure were replaced with the PL spectrum data of Metal Complex 23 of the present disclosure and inputted into the simulation software for simulation and calculation.

### Simulation Comparative Example 2

The simulation manner of Simulation Comparative Example 2 is the same as that of Simulation Example 1 except that the PL spectrum data of Metal Complex 17 of the present disclosure were replaced with the PL spectrum data of GD1 and inputted into the simulation software for simulation and calculation.

### Simulation Comparative Example 3

The simulation manner of Simulation Comparative Example 3 is the same as that of Simulation Example 1 except that the PL spectrum data of Metal Complex 17 of the present disclosure were replaced with the PL spectrum data of GD3 and inputted into the simulation software for simulation and calculation.

### Simulation Comparative Example 4

The simulation manner of Simulation Comparative Example 4 is the same as that of Simulation Example 1 except that the PL spectrum data of Metal Complex 17 of the present disclosure were replaced with the PL spectrum data of GD4 and inputted into the simulation software for simulation and calculation.

### Simulation Comparative Example 5

The simulation manner of Simulation Comparative Example 5 is the same as that of Simulation Example 1 except that the PL spectrum data of Metal Complex 17 of the present disclosure were replaced with the PL spectrum data of GD5 and inputted into the simulation software for simulation and calculation.

### Simulation Comparative Example 6

The simulation manner of Simulation Comparative Example 6 is the same as that of Simulation Example 1 except that the PL spectrum data of Metal Complex 17 of the present disclosure were replaced with the PL spectrum data of GD6 and inputted into the simulation software for simulation and calculation.

### Simulation Comparative Example 7

The simulation manner of Simulation Comparative Example 7 is the same as that of Simulation Example 1 except that the PL spectrum data of Metal Complex 17 of the present disclosure were replaced with the PL spectrum data of GD7 and inputted into the simulation software for simulation and calculation.

Table 7 shows CIE (x, y) when Simulation Examples 1 to 3 and Simulation Comparative Examples 1 to 7 reached CEₘₐₓ, the distance D from the color coordinates CIE (0.170, 0.797) of green light in BT.2020, the corresponding current efficiency CEₘₐₓ₂ of the simulated device when CIEx in the color coordinates CIE (x, y) was 0.170, and the ratio of CEₘₐₓ₂ to CEₘₐₓ The data are recorded and shown in Table 7.

TABLE 7
Data of Simulation Examples 1 to 3 and
Simulation Comparative Examples 1 to 7

| | | | CEₘₐₓ | CEₘₐₓ₂ | CEₘₐₓ₂/ |
|---|---|---|---|---|---|
| Device ID | D | CIE (x, y) | (cd/A) | (cd/A) | CEₘₐₓ |
| Simulation | 0.0262 | (0.173, 0.771) | 169 | 169 | 100.00% |
| Example 1 | | | | | |
| Simulation | 0.0217 | (0.171, 0.775) | 169 | 169 | 100.00% |
| Example 2 | | | | | |
| Simulation | 0.0314 | (0.182, 0.768) | 160 | 159 | 99.38% |
| Example 3 | | | | | |
| Simulation | 0.0714 | (0.222, 0.748) | 178 | 140 | 78.65% |
| Comparative | | | | | |
| Example 1 | | | | | |
| Simulation | 0.0707 | (0.221, 0.748) | 180 | 142 | 78.89% |
| Comparative | | | | | |
| Example 2 | | | | | |
| Simulation | 0.0942 | (0.240, 0.734) | 159 | 112 | 70.44% |
| Comparative | | | | | |
| Example 3 | | | | | |
| Simulation | 0.0686 | (0.218, 0.748) | 163 | 147 | 90.18% |
| Comparative | | | | | |
| Example 4 | | | | | |
| Simulation | 0.0792 | (0.226, 0.741) | 157 | 140 | 89.17% |
| Comparative | | | | | |
| Example 5 | | | | | |
| Simulation | 0.087 | (0.234, 0.738) | 168 | 130 | 77.38% |
| Comparative | | | | | |
| Example 6 | | | | | |
| Simulation | 0.087 | (0.234, 0.738) | 169 | 128 | 75.74% |
| Comparative | | | | | |
| Example 7 | | | | | |

Discussion:

As can be seen from Table 7, when Simulation Examples 1 to 3 reached CEmax, the D values were 0.0262, 0.0217, and 0.0314 respectively, which were all less than 0.0320, that is, close to the color coordinates CIE (0.170, 0.797) of green light in BT.2020. When Simulation Comparative Examples 1 to 7 reached CEmax, the D values were 0.0714, 0.0707, 0.0942, 0.0686, 0.0792, 0.0870, and 0.0870 respectively, which were all greater than 0.0680, that is, the corresponding CIE (x, y) were relatively far from the color coordinates CIE (0.170, 0.797) of green light in BT.2020, resulting in unsaturated green light emission and reduced efficiency.

As can be concluded from Tables 5, 6, and 7, Examples 1 to 3 comprising the metal complexes of the present disclosure have smaller distances D and better approach the color coordinates CIE (0.170, 0.797) of green light in BT.2020 so that the devices have more saturated green light emission, higher device efficiency (CE and EQE), and smaller distances from BT.2020 color coordinates; while Comparative Examples 1 to 7 each have a distance D greater than 0.0680 and deviate more from the color coordinates CIE (0.170, 0.797) of green light in BT.2020, resulting in unsaturated green light emission and lower device efficiency of the devices.

### Simulation Example 4

The simulation manner of Simulation Example 4 was the same as that of Simulation Example 1 except that, besides the original PL spectrum data of Metal Complex 17 of the present disclosure, the FWHM of was additionally adjusted to 18 nm with the maximum emission wavelength λ_{MAX} unchanged to obtain new simulated PL spectrum data, with a peak area ratio of 0.170. The simulated PL spectrum data were inputted into the simulation software to form new Simulation Example 4.

A device structure the same as Simulation Example 1 was designed and simulated through the Setfos 5.0 semiconductor thin-film optical simulation software developed by FLUXiM. Table 8 shows the corresponding color coordinates CIE (x, y) when Simulation Example 4 has CEₘₐₓ. The data are recorded in Table 8.

TABLE 8
Data of Simulation Example 4

| Device ID | CIE (x, y) | CEₘₐₓ (cd/A) |
|---|---|---|
| Simulation Example 4 | (0.117, 0.802) | 231 |

Discussion:

As can be seen from Table 8, Simulation Example 4 had CIEy greater than 0.797 and wider BT.2020 coverage and can achieve a wider color gamut range, and the CEₘₐₓ reached a high level of 230 cd/A and was improved a lot relative to the simulation comparative examples. It indicates that CIEy greater than 0.797 is theoretically feasible and good device performance can be achieved.

To conclude, compared with the use of a metal complex that does not satisfy the requirements on D and AR in an organic electroluminescent device, the use of the metal complex of the present disclosure satisfying the requirements on D and AR in the device can make the obtained organic electroluminescent device have higher device efficiency and more saturated green light emission, able to satisfy the BT.2020 luminescence requirement of the market, and have high device efficiency under the BT.2020 luminescence requirement.

It should be understood that various embodiments described herein are merely examples and not intended to limit the scope of the present disclosure. Therefore, it is apparent to the persons skilled in the art that the present disclosure as claimed may include variations from specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. An organic electroluminescent device, comprising a cathode, an anode, and an organic layer disposed between the cathode and the anode; wherein
the organic layer comprises a metal complex comprising a metal M and at least one C\hat{ }N bidentate ligand Lₐ coordinated to the metal M;
the metal M is selected from a metal with a relative atomic mass greater than 40;
an area ratio of a photoluminescence spectrum of the metal complex at room temperature is AR, wherein AR≤0.331; and
in a top-emitting device comprising the metal complex, when the top-emitting device reaches maximum current efficiency, the corresponding color coordinates are measured as CIE (x, y); and a distance between the CIE (x, y) and color coordinates CIE (0.170, 0.797) is calculated as D; wherein CIEy≥0.797 or D≤0.0320.

2. The organic electroluminescent device according to claim 1, wherein a maximum emission wavelength and a full width at half maximum of an electroluminescence (EL) spectrum of the metal complex are λₘₐₓ and FWHM, wherein 490 nm≤λₘₐₓ≤524 nm and FWHM≤35 nm;
preferably, 500 nm≤λₘₐₓ≤524 nm and FWHM≤34 nm.

3. The organic electroluminescent device according to claim 1, wherein D≤0.0280.

4. The organic electroluminescent device according to claim 1, wherein a highest occupied molecular orbital energy level (ETlomo) of the metal complex is less than or equal to −5.05 eV;
preferably, the highest occupied molecular orbital energy level (Eilomo) of the metal complex is less than or equal to −5.10 eV.

5. The organic electroluminescent device according to claim 1, wherein a lowest unoccupied molecular orbital energy level (E_{LUMO}) of the metal complex is less than or equal to −2.1 eV;
preferably, the lowest unoccupied molecular orbital energy level (E_{LUMO}) of the metal complex is less than or equal to −2.3 eV.

6. The organic electroluminescent device according to claim 1, wherein the organic layer further comprises a first compound, and a lowest unoccupied molecular orbital energy level (E_{LUMO-H1}) of the first compound is less than or equal to −2.70 eV;
preferably, the lowest unoccupied molecular orbital energy level (ELuMo-xi) of the first compound is less than or equal to −2.80 eV.

7. The organic electroluminescent device according to claim 6, wherein the organic layer further comprises a second compound, and a highest occupied molecular orbital energy level (E_{HOMO-H2}) of the second compound is greater than or equal to −5.60 eV;
preferably, the highest occupied molecular orbital energy level (E_{HOMO-H2}) of the second compound is greater than or equal to −5.50 eV.

8. The organic electroluminescent device according to claim 7, wherein the first compound and/or the second compound comprise at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof

9. The organic electroluminescent device according to claim 7, wherein the metal complex is doped in the first compound and the second compound, and the weight of the metal complex accounts for 1% to 30% of the total weight of the organic layer;
preferably, the weight of the metal complex accounts for 3% to 13% of the total weight of the organic layer.

10. The organic electroluminescent device according to claim 1, wherein the metal complex has a general formula of M(Lₐ)ₘ(L_{b})ₙ(L_{c})_{q}; wherein Lₐ, L_{b}, and L_{c} are a first ligand, a second ligand, and a third ligand coordinated to the metal M, respectively, and Lₐ, L_{b}, and L_{c} are the same or different; wherein Lₐ, L_{b}, and L_{c} can be optionally joined to form a tetradentate ligand or a multidentate ligand;
the metal M is, at each occurrence identically or differently, selected from the group consisting of Cu, Ag, Au, Ru, Rh, Pd, Os, Ir, and Pt;
m is selected from 1, 2, or 3, n is selected from 0, 1, or 2, q is selected from 0, 1, or 2, and m+n+q equals the oxidation state of M; when m is 2 or 3, multiple Lₐ may be the same or different; when n is 2, two L_{b} may be the same or different; when q is 2, two L_{c} may be the same or different;
Lₐ has a structure of A-E, wherein
A is, at each occurrence identically or differently, selected from a substituted or unsubstituted heteroaromatic ring having 5 to 6 ring atoms, wherein the heteroaromatic ring comprises at least one nitrogen atom, and A attaches to the metal via the nitrogen atom in the heteroaromatic ring to form a metal-nitrogen bond or a metal-G-nitrogen bond;
E is, at each occurrence identically or differently, selected from a substituted or unsubstituted aromatic ring having 13 to 30 ring atoms or a substituted or unsubstituted heteroaromatic ring having 13 to 30 ring atoms, wherein the aromatic ring or the heteroaromatic ring is a fused structure having at least three rings, and the at least three rings at least comprise two six-membered rings and one five-membered ring; and E attaches to the metal through a carbon atom in the aromatic ring or the heteroaromatic ring to form a metal-carbon bond or a metal-G-carbon bond;
L_{b} and L_{c} have, at each occurrence identically or differently, a structure of C-L-D, wherein C and D are, at each occurrence identically or differently, selected from a substituted or unsubstituted aromatic ring having 6 to 30 ring atoms, a substituted or unsubstituted heteroaromatic ring having 5 to 30 ring atoms, or a combination thereof, and C and D are, at each occurrence identically or differently, attaches to the metal via a carbon atom or a nitrogen atom in the aromatic ring or the heteroaromatic ring to form a metal-carbon bond, a metal-nitrogen bond, a metal-G-carbon bond, or a metal-G-nitrogen bond;
L is, at each occurrence identically or differently, selected from the group consisting of: a single bond, BR_{L}, CR_{L} R_{L}, NR_{L}, SiR_{L} R_{L}, PR_{L}, GeR_{L} R_{L}, O, S, Se, substituted or unsubstituted vinylene, ethynylene, substituted or unsubstituted arylene having 5 to 30 carbon atoms, substituted or unsubstituted heteroarylene having 5 to 30 carbon atoms, and combinations thereof; when two R_{L} are present at the same time, the two R_{L} are the same or different;
R_{L} represents, at each occurrence identically or differently, hydrogen or a substituent;
G is, at each occurrence identically or differently, selected from a single bond, O, or S; and
adjacent substituents can be optionally joined to form a ring.

11. The organic electroluminescent device according to claim 1, wherein the metal M is, at each occurrence identically or differently, selected from Pt or Ir.

12. The organic electroluminescent device according to claim 1, wherein the organic layer comprising the metal complex is a light-emitting layer.

13. A display assembly, comprising the organic electroluminescent device according to claim 1.

14. A metal complex having a general formula of M(Lₐ)ₘ(L_{b})ₙ(L_{c})_{q}; wherein Lₐ, L_{b}, and L_{c} are a first ligand, a second ligand, and a third ligand coordinated to the metal M, respectively, and Lₐ, L_{b}, and L_{c} are the same or different; wherein Lₐ, L_{b}, and L_{c} can be optionally joined to form a tetradentate ligand or a multidentate ligand;
m is selected from 1, 2, or 3, n is selected from 0, 1, or 2, q is selected from 0, 1, or 2, and m+n+q equals the oxidation state of M; when m is 2 or 3, multiple Lₐ may be the same or different; when n is 2, two L_{b} may be the same or different; when q is 2, two L_{c} may be the same or different;
the metal complex comprises the metal M and at least one C\hat{ }N bidentate ligand La coordinated to the metal M;
the metal M is selected from a metal with a relative atomic mass greater than 40;
L_{b} and L_{c} are, at each occurrence identically or differently, selected from a monoanionic bidentate ligand;
an area ratio of a photoluminescence spectrum of the metal complex at room temperature is AR, wherein AR≤0.331; and
in a top-emitting device comprising the metal complex, when the top-emitting device reaches maximum current efficiency, the corresponding color coordinates are measured as CIE (x, y); and a distance between the CIE (x, y) and color coordinates CIE (0.170, 0.797) is calculated as D; wherein CIEy≥0.797 or D≤0.0320.

15. The metal complex according to claim 14, wherein the metal complex has a structure represented by Formula 1 or Formula 2: 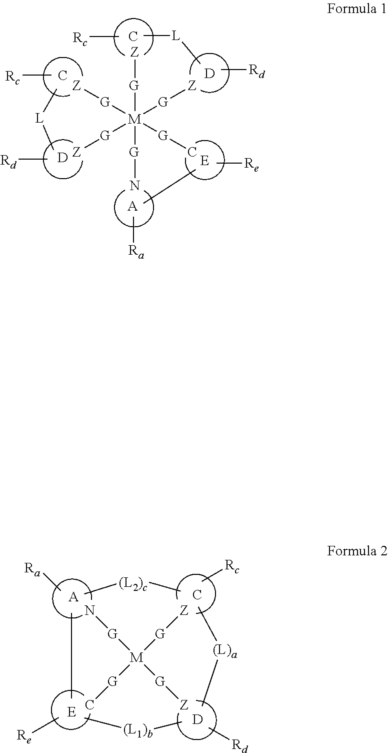
wherein
the metal M is selected from a metal with a relative atomic mass greater than 40;
the ring A is, at each occurrence identically or differently, selected from a nitrogen-containing heteroaromatic ring having 5 to 6 ring atoms;
the ring E is, at each occurrence identically or differently, selected from an aromatic ring or a heteroaromatic ring having 13 to 30 ring atoms and being a fused structure having at least three rings, wherein the at least three rings at least comprise two six-membered rings and one five-membered ring;
the ring C and the ring D are, at each occurrence identically or differently, selected from an aromatic ring having 6 to 30 carbon atoms, a heteroaromatic ring having 3 to 30 carbon atoms, or a combination thereof;
Z is, at each occurrence identically or differently, selected from C or N;
G is, at each occurrence identically or differently, selected from a single bond, O, or S;
L, L₁, and L₂ are, at each occurrence identically or differently, selected from the group consisting of: a single bond, BR_{L}, CR_{L}R_{L}, NR_{L}, SiR_{L}R_{L}, PR_{L}, GeR_{L}R_{L}, O, S, Se, substituted or unsubstituted vinylene, ethynylene, substituted or unsubstituted arylene having 5 to 30 carbon atoms, substituted or unsubstituted heteroarylene having 5 to 30 carbon atoms, and combinations thereof; when two R_{L} are present at the same time, the two R_{L} are the same or different;
a, b, and c are, at each occurrence identically or differently, selected from 0 or 1;
Rₐ, Rₑ, R_{c}, and R_{d} represent, at each occurrence identically or differently, mono-substitution, multiple substitutions, or non-substitution;
Rₐ, Rₑ, R_{c}, R_{d}, and R_{L} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfanyl group, a sulfonyl group, a phosphino group, and combinations thereof; and
adjacent substituents Rₐ, Rₑ, R_{c}, R_{d}, and R_{L} can be optionally joined to form a ring.

16. The metal complex according to claim 15, wherein at least one of Rₐ, Rₑ, R_{c}, and R_{d} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfanyl group, a sulfonyl group, a phosphino group, and combinations thereof;
preferably, at least one of Rₐ, Rₑ, R_{c}, and R_{d} is selected from the group consisting of: fluorine, substituted or unsubstituted alkyl having 1 to 10 carbon atoms, substituted or unsubstituted aryl having 6 to 18 carbon atoms, substituted or unsubstituted heteroaryl having 3 to 18 carbon atoms, substituted or unsubstituted alkylsilyl having 3 to 12 carbon atoms, cyano, and combinations thereof.

17. The metal complex according to claim 15, wherein at least one Rₑ is selected from F or CN, and at least another one Rₑ is selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, and combinations thereof.
preferably, at least one Rₑ is selected from F or CN, and at least another one Rₑ is selected from the group consisting of: substituted or unsubstituted alkyl having 1 to 20 carbon atoms, substituted or unsubstituted aryl having 6 to 30 carbon atoms, and combinations thereof.
